(19) United States
(12) Patent Application Publication
(10) Pub. No.: US 2024/0105869 A1
(43) Pub. Date: Mar. 28, 2024

(54) SEMICONDUCTOR DEVICE AND METHOD OF MANUFACTURING THE SAME

(71) Applicant: ROHM CO., LTD., Kyoto (JP)

(72) Inventor: Yushi SEKIGUCHI, Kyoto (JP)

(73) Assignee: ROHM CO., LTD., Kyoto (JP)

(21) Appl. No.: 18/462,824

(22) Filed: Sep. 7, 2023

(30) Foreign Application Priority Data
Sep. 26, 2022 (JP) 2022-152406

(51) Int. Cl. H01L 31/0352; H01L 27/146; H01L 31/103; H01L 31/18

(52) U.S. Cl. CPC H01L 31/03529; H01L 27/14643; H01L 31/1037; H01L 31/1804

(57) ABSTRACT

A semiconductor device includes: a chip including a main surface; a first conductivity type first semiconductor region formed at least in a surface layer portion of the main surface; a trench structure including a trench formed in the main surface to be located within the first semiconductor region, and a second conductivity type polysilicon mechanically and electrically connected to the chip and located within the trench; and a second conductivity type second semiconductor region formed within the first semiconductor region along a wall surface of the trench structure and forming a pn junction, as a photodiode, with the first semiconductor region.

### CROSS-REFERENCE TO RELATED APPLICATION

This application is based upon and claims the benefit of priority from Japanese Patent Application No. 2022-152406, filed on Sep. 26, 2022, the entire contents of which are incorporated herein by reference.

### TECHNICAL FIELD

The present disclosure relates to a semiconductor device and a method of manufacturing the same.

### BACKGROUND

The related art discloses a technique related to the photoelectric conversion efficiency and the depth of a pn junction with respect to a semiconductor device used for an imaging element and a solar cell. The related art discloses a semiconductor device including a p-type semiconductor substrate and an n-type doping layer forming a pn junction in the surface layer portion of the semiconductor substrate.

In the case of this semiconductor device, since the pn junction is formed in a relatively shallow region in the semiconductor substrate, incident light in a wavelength band that excites electrons in a region deeper than the pn junction cannot be detected appropriately. The related art disclose a configuration for solving such a problem.

The related art discloses a semiconductor device including a p-type semiconductor substrate, a trench formed on the surface of the semiconductor substrate, and an n-type silicon layer buried in the trench. The configuration of this semiconductor device is specifically disclosed in the other related art. In the other related art, an n-type silicon layer is formed in a film shape along the wall surface of a trench to define a recess space within the trench. The n-type silicon layer is directly connected to a p-type semiconductor substrate within the trench, forming a pn junction with the semiconductor substrate.

The related art discloses a semiconductor device including a p-type semiconductor substrate, a trench formed in the surface of the semiconductor substrate, and an n-type doping layer formed in the semiconductor substrate along the surface of the semiconductor substrate and the wall surface of the trench. The n-type doping layer forms a pn junction with the p-type semiconductor substrate. This semiconductor device does not have a buried material in the trench. The trench consists of a cavity that exposes the n-type doping layer to the outside.

A method of manufacturing this semiconductor device includes a step of forming a trench in the surface of a p-type semiconductor substrate, a step of covering the surface of the semiconductor substrate and the wall surface of the trench with a thin film containing an n-type impurity, a step of diffusing the n-type impurity into the semiconductor substrate using the thin film as a solid-phase diffusion source to form an n-type doping layer along the surface of the semiconductor substrate and the wall surface of the trench, and a step of removing the thin film from the semiconductor substrate.

In the related art, a silicon oxide film is applied as the solid-phase diffusion source thin film, while a silicon film is excluded from an application object as the solid-phase diffusion source thin film. This is because when the silicon film of the same quality as the semiconductor substrate is applied as the solid-phase diffusion source thin film, the semiconductor substrate is removed simultaneously with the silicon film in the step of removing the thin film. With such technical means, a semiconductor device having a doping layer along a trench consisting of a cavity is manufactured.

### BRIEF DESCRIPTION OF DRAWINGS

The accompanying drawings, which are incorporated in and constitute a part of the specification, illustrate embodiments of the present disclosure.

FIG. 1 is a plane view showing a semiconductor device according to a first embodiment.

FIG. 2 is a plane view showing a CMIS region in FIG. 1.

FIG. 3 is a cross-sectional view taken along line III-III in FIG. 2.

FIG. 4 is a plane view showing a light receiving region in FIG. 1.

FIG. 5 is a cross-sectional view taken along line V-V in FIG. 4.

FIG. 6 is a cross-sectional view taken along line VI-VI in FIG. 4.

FIG. 7 is a cross-sectional view showing the vicinity of the upper end portion of a trench structure in FIG. 5.

FIG. 8A is a first graph showing an example of a concentration gradient along a first line L1 in FIG. 7.

FIG. 8B is a second graph showing an example of a concentration gradient along a second line L2 in FIG. 7.

FIG. 9A is a cross-sectional view showing a first modification example of the trench structure.

FIG. 9B is a cross-sectional view showing a second modification example of the trench structure.

FIG. 9C is a cross-sectional view showing a third modification example of the trench structure.

FIG. 9D is a cross-sectional view showing a fourth modification example of the trench structure.

FIG. 10 is a plane view showing a light receiving region of a semiconductor device according to a second embodiment.

FIG. 11 is a cross-sectional view taken along line XI-XI in FIG. 10.

FIG. 12 is a cross-sectional view taken along line XII-XII in FIG. 10.

FIG. 13 is a graph showing an example of a concentration gradient along a third line L3 in FIG. 12.

FIG. 14 is a cross-sectional view showing a modification example of a second semiconductor region according to the second embodiment.

FIG. 15 is a plane view showing a light receiving region of a semiconductor device according to a third embodiment.

FIG. 16 is a cross-sectional view taken along line XVI-XVI in FIG. 15.

FIG. 17 is a plane view showing a light receiving region of a semiconductor device according to a fourth embodiment.

FIG. 18 is a cross-sectional view taken along line XVIII-XVIII in FIG. 17.

FIG. 19 is a cross-sectional view taken along line XIX-XIX in FIG. 17.

FIG. 20 is a plane view showing a semiconductor device according to a fifth embodiment.

FIG. 21 is a cross-sectional view showing a main part of the semiconductor device of FIG. 20.

FIG. 22 is a cross-sectional view showing a modification example of a light receiving region according to the fifth embodiment.

FIG. 23A is a cross-sectional view showing an example of a method of manufacturing a semiconductor device.

FIG. 23B is a cross-sectional view showing a step after FIG. 23A.

FIG. 23C is a cross-sectional view showing a step after FIG. 23B.

FIG. 23D is a cross-sectional view showing a step after FIG. 23C.

FIG. 23E is a cross-sectional view showing a step after FIG. 23D.

FIG. 23F is a cross-sectional view showing a step after FIG. 23E.

FIG. 23G is a cross-sectional view showing a step after FIG. 23F.

FIG. 23H is a cross-sectional view showing a step after FIG. 23G.

FIG. 23I is a cross-sectional view showing a step after FIG. 23H.

FIG. 23J is a cross-sectional view showing a step after FIG. 23I.

FIG. 23K is a cross-sectional view showing a step after FIG. 23J.

FIG. 23L is a cross-sectional view showing a step after FIG. 23K.

FIG. 23M is a cross-sectional view showing a step after FIG. 23L.

FIG. 23N is a cross-sectional view showing a step after FIG. 23M.

FIG. 23O is a cross-sectional view showing a step after FIG. 23N.

FIG. 23P is a cross-sectional view showing a step after FIG. 23O.

FIG. 23Q is a cross-sectional view showing a step after FIG. 23P.

FIG. 23R is a cross-sectional view showing a step after FIG. 23Q.

FIG. 23S is a cross-sectional view showing a step after FIG. 23R.

FIG. 23T is a cross-sectional view showing a step after FIG. 23S.

FIG. 23U is a cross-sectional view showing a step after FIG. 23T.

FIG. 23V is a cross-sectional view showing a step after FIG. 23U.

FIG. 23W is a cross-sectional view showing a step after FIG. 23V.

FIG. 24A is a schematic cross-sectional view showing an example of a process of forming a plurality of trenches.

FIG. 24B is a schematic cross-sectional view showing a step after FIG. 23A.

FIG. 24C is a schematic cross-sectional view showing a step after FIG. 23B.

FIG. 24D is a schematic cross-sectional view showing a step after FIG. 23C.

FIG. 25 is a cross-sectional view showing a modification example of a tip.

FIG. 26 is a plane view showing a first modification example of a cathode via electrode.

FIG. 27 is a plane view showing a second modification example of the cathode via electrode.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described in detail with reference to the accompanying drawings. The accompanying drawings are schematic and are not strictly illustrated, and the scales and the like do not necessarily match. Throughout the accompanying drawings, the same or corresponding structures are denoted by the same reference numerals, and duplicate explanation thereof are omitted or simplified. The descriptions given before the omissions or simplifications apply for structures whose explanation are omitted or simplified.

When the wording “substantially equal” is used in an explanation where there is a comparison target, this wording includes not only numerical values (morphology) that are equal to the numerical value (morphology) of the comparison target, but also numerical errors (morphological errors) within a range of ±10% based on the numerical value (morphology) of the comparison target. Words such as “first,” “second,” and “third” are used in the embodiments, but these are symbols attached to the name of each structure to clarify the order of explanation, and are not attached for the purpose of limiting the name of each structure.

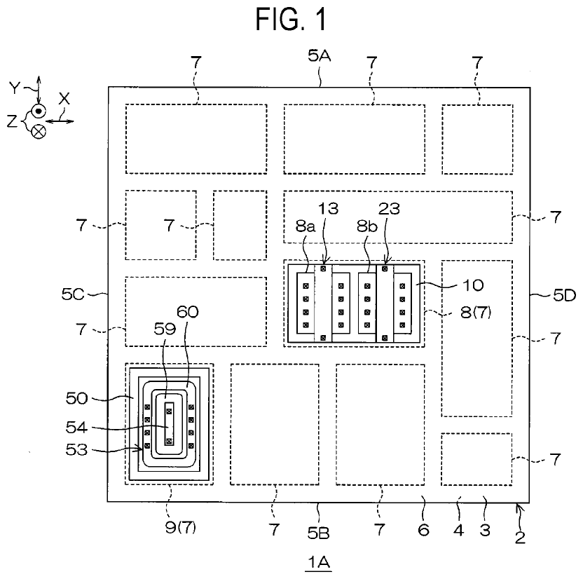

FIG. 1 is a plane view showing a semiconductor device 1A according to a first embodiment. Referring to FIG. 1, in this embodiment, the semiconductor device 1A includes a chip 2 made of Si single crystal. The chip 2 may be referred to as a “Si chip.” The chip 2 is formed in a hexahedral shape (specifically, a rectangular parallelepiped shape). The chip 2 has a first main surface 3 on one side, a second main surface 4 on the other side, and first to fourth side surfaces 5A to 5D connecting the first main surface 3 and the second main surface 4. The thickness of the chip 2 may be 200 μm or more and 500 μm or less.

The first main surface 3 and the second main surface 4 are formed in a quadrangular shape in plan view viewed from the normal direction Z thereof (hereinafter simply referred to as “plan view”). The normal direction Z is also the thickness direction of the chip 2. The first side surface 5A and the second side surface 5B extend in a first direction X along the first main surface 3 and oppose (face) a second direction Y that intersects (specifically, is perpendicular to) the first direction X along the first main surface 3. The third side surface 5C and the fourth side surface 5D extend in the second direction Y and oppose (face) the first direction X.

The semiconductor device 1A includes a p-type (first conductivity type) first semiconductor region 6 formed in the chip 2. The p-type impurity concentration of the first semiconductor region 6 may be 1×10¹⁴ cm⁻³ or more and 1×10¹⁶ cm⁻³ or less. The first semiconductor region 6 is formed at least on the surface layer portion of the first main surface 3 within the chip 2. The first semiconductor region 6 is preferably exposed from the first main surface 3. In this embodiment, the first semiconductor region 6 is formed over the entire thickness range of the chip 2 and is exposed from the first main surface 3 and the second main surface 4.

Specifically, the first semiconductor region 6 is formed in the form of a layer extending along the first main surface 3 and the second main surface 4 over the entire region of the chip 2 and is exposed from the first main surface 3, the second main surface 4, and the first to fourth side surfaces 5A to 5D. That is, in this embodiment, the first semiconductor region 6 includes the first main surface 3, the second main surface 4, and the first to fourth side surfaces 5A to 5D.

In this embodiment, the chip 2 includes a single-layer structure consisting of a p-type semiconductor substrate (silicon substrate), and the first semiconductor region 6 is formed by using the p-type semiconductor substrate. The chip 2 may include a single-layer structure consisting of an n-type semiconductor substrate. In this case, the p-type first semiconductor region 6 may be formed by introducing a p-type impurity into at least the surface layer portion of the first main surface 3 in the n-type semiconductor substrate.

The semiconductor device 1A includes a plurality of circuit device regions 7 defined in the first main surface 3. The number and arrangement of the plurality of circuit device regions 7 are arbitrary. The plurality of circuit device regions 7 are regions containing various circuit devices (functional devices) formed by using the first main surface 3 and/or the surface layer portion of the first main surface 3. The circuit devices may include at least one of a semiconductor switching device, a semiconductor rectifying device, and a passive device. The plurality of circuit devices may constitute an integrated circuit such as LSI (Large Scale Integration).

The semiconductor switching device may include at least one of MISFET (Metal Insulator Semiconductor Field Effect Transistor), BJT (Bipolar Junction Transistor), IGBT (Insulated Gate Bipolar Junction Transistor), and JFET (Junction Field Effect Transistor).

The semiconductor rectifying device may include at least one of a pn junction diode, a pin junction diode, a Zener diode, a Schottky barrier diode, and a fast recovery diode. The passive devices may include at least one of resistors, capacitors, inductors, and fuses.

In this embodiment, the plurality of circuit device regions 7 includes at least one CMIS (Complementary Metal Insulator Semiconductor) region 8 and at least one light receiving region 9. The CMIS region 8 is a region containing CMIS, and the light receiving region 9 is a region containing a light receiving device for light detection.

The light receiving region 9 is provided in a region different from the CMIS region 8 in the first main surface 3. The light receiving region 9 is typically provided in a peripheral portion of the first main surface 3. The light receiving region 9 may be arranged in an inner portion of the first main surface 3 and face the peripheral portion of the first main surface 3 with the other circuit device region 7 interposed therebetween. The CMIS region 8 and the light receiving region 9 can be arranged at arbitrary locations and are not limited to a specific layout. The configuration of the CMIS region 8 and the configuration of the light receiving region 9 will be described in order below.

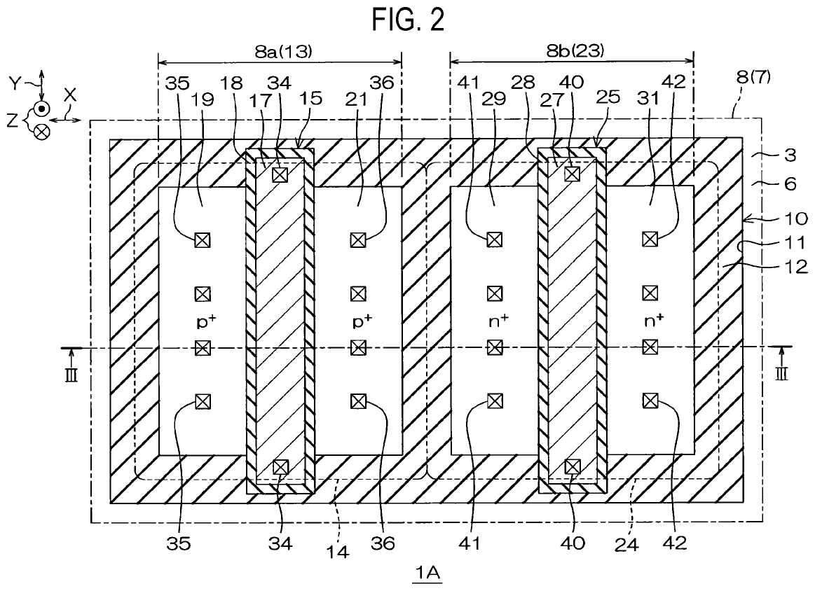

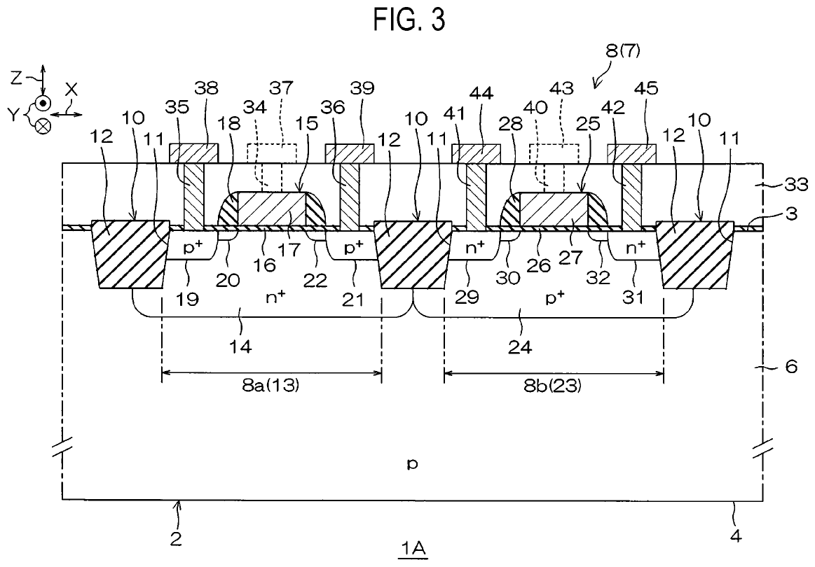

FIG. 2 is a plane view showing the CMIS region 8 in FIG. 1. FIG. 3 is a cross-sectional view taken along line III-III in FIG. 2. Referring to FIGS. 2 and 3, the CMIS region 8 includes a first MIS region 8a (first transistor region) and a second MIS region 8b (second transistor region). The first MIS region 8a is arranged on one side in the first direction X in plan view. The second MIS region 8b is arranged on the other side in the first direction X with respect to the first MIS region 8a and faces the first MIS region 8a in the first direction X.

The arrangement of the first MIS region 8a and the second MIS region 8b may be interchanged. Further, the first MIS region 8a and the second MIS region 8b may be arranged along the second direction Y and face each other in the second direction Y.

The semiconductor device 1A includes a first region isolation structure 10 formed on the first main surface 3 to electrically isolate the CMIS region 8 from other circuit device regions 7 (the light receiving region 9, etc.). In this embodiment, the first region isolation structure 10 consists of a trench insulation structure. The first region isolation structure 10 may be referred to as a “first trench insulation structure.” The first region isolation structure 10 is formed in the surface layer portion of the first semiconductor region 6 to be exposed from the first main surface 3.

The first region isolation structure 10 includes a first annular portion surrounding the first MIS region 8a in plan view and a second annular portion surrounding the second MIS region 8b in plan view. In this embodiment, the first annular portion is formed in a polygonal annular shape (in this embodiment, a square annular shape) including four sides parallel to the periphery (the first to fourth side surfaces 5A to 5D) of the first main surface 3 in plan view.

In this embodiment, the second annular portion is formed in a polygonal annular shape (in this embodiment, a square annular shape) including four sides parallel to the periphery of the first main surface 3 in plan view and is connected to the first annular portion. That is, the first region isolation structure 10 is formed in a ladder shape surrounding the first MIS region 8a and the second MIS region 8b in plan view. The second annular portion may be formed at an interval from the first annular portion.

The first region isolation structure 10 includes a first isolation trench 11 and a first buried insulator 12. The first isolation trench 11 is formed in the first main surface 3 and defines the wall surface of the first region isolation structure 10. The first isolation trench 11 is formed in a tapered shape in which the width of an opening gradually narrows from the opening toward the bottom wall when viewed in cross section.

The depth of the first isolation trench 11 may be 0.2 μm or more and 1 μm or less. The depth of the first isolation trench 11 may have a value belonging to any of ranges of 0.2 μm or more and 0.5 μm or less, 0.5 μm or more and 0.75 μm or less, and 0.75 μm or more and 1 μm or less.

The first buried insulator 12 is buried in the first isolation trench 11. In this embodiment, the first buried insulator 12 includes a first buried portion located on the bottom wall side of the first isolation trench 11 with respect to the first main surface 3, and a first protruding portion protruding upward from the first buried portion above the first main surface 3. The first buried insulator 12 may be formed to be flush with the first main surface 3. The first buried insulator 12 may contain at least one of silicon oxide and silicon nitride.

The semiconductor device 1A includes a pnp-type first MISFET structure 13 formed in the first MIS region 8a. The following configuration is described as a component of the semiconductor device 1A, but it is also a component of the first MISFET structure 13.

The semiconductor device 1A includes an n-type (second conductivity type) first well region 14 formed on the surface layer portion of the first main surface 3 in the first MIS region 8a. The n-type impurity concentration of the first well region 14 may be 1×10¹⁴ cm⁻³ or more and 1×10¹⁷ cm⁻³ or less. The first well region 14 is formed over the entire first MIS region 8a in plan view and is connected to the first region isolation structure 10. The first well region 14 is formed deeper than the first region isolation structure 10 and includes a portion covering the bottom wall of the first region isolation structure 10.

The semiconductor device 1A includes a first planar gate structure 15 arranged on the first main surface 3 in the first MIS region 8a. The first planar gate structure 15 includes a first gate insulating film 16, a first gate electrode 17, and a first sidewall insulating film 18. The first sidewall insulating film 18 may be called a “first sidewall structure.” The presence or absence of the first sidewall insulating film 18 is arbitrary and may be removed as necessary.

The first gate insulating film 16 covers the first main surface 3 in the form of a film in the first MIS region 8a. In this embodiment, the first gate insulating film 16 covers the entire first MIS region 8a and includes a portion connected to the first region isolation structure 10 (the first buried insulator 12). The first gate insulating film 16 has a thickness smaller than the thickness of the first protruding portion of the first buried insulator 12. It is preferable that the first gate insulating film 16 includes a silicon oxide film. It is particularly preferable that first gate insulating film 16 includes a silicon oxide film made of oxide of the chip 2 (the first main surface 3).

The first gate electrode 17 is arranged on the first gate insulating film 16 in the inner portion of the first MIS region 8a. In this embodiment, the first gate electrode 17 is formed in a strip shape extending in the second direction Y in plan view. The first gate electrode 17 includes a first end portion and a second end portion respectively drawn from above the first gate insulating film 16 to above the first buried insulator 12.

The first end portion and the second end portion are respectively orthogonal to a portion of the first region isolation structure 10 extending in the first direction X. The first gate electrode 17 preferably includes conductive polysilicon containing n-type impurities (pentavalent element) and/or p-type impurities (trivalent element).

The first sidewall insulating film 18 covers a sidewall of the first gate electrode 17. In this embodiment, the first sidewall insulating film 18 covers the sidewall of the first gate electrode 17 over the first buried insulator 12 and covers the sidewall of the first gate electrode 17 over the first gate insulating film 16. The first sidewall insulating film 18 may contain at least one of silicon oxide and silicon nitride.

The semiconductor device 1A includes a p-type first drain region 19 formed in the surface layer portion of the first well region 14. The p-type impurity concentration of the first drain region 19 may be 1×10¹⁸ cm⁻³ or more and 1×10²⁰ cm⁻³ or less. The p-type impurity concentration of the first drain region 19 is higher than the p-type impurity concentration of the first semiconductor region 6. The first drain region 19 is formed in a region on one side in the first direction X with respect to the first planar gate structure 15. The first drain region 19 is formed in a region between the first region isolation structure 10 and the first planar gate structure 15 in plan view.

In this embodiment, the first drain region 19 is formed in a self-aligned manner with respect to the first sidewall insulating film 18 and is formed along the first sidewall insulating film 18 in plan view. The first drain region 19 is formed at an interval from the bottom wall of the first region isolation structure 10 (the first isolation trench 11) to the first main surface 3 side. The first drain region 19 may be in contact with the first region isolation structure 10 (the first isolation trench 11).

The semiconductor device 1A includes a p-type first drain surface layer region 20 drawn from the surface layer portion of the first drain region 19 to a region directly below the first sidewall insulating film 18. The first drain surface layer region 20 faces the first sidewall insulating film 18 with the first gate insulating film 16 interposed therebetween. The first drain surface layer region 20 preferably has a p-type impurity concentration lower than the p-type impurity concentration of the first drain region 19. The p-type impurity concentration of the first drain surface layer region 20 may be 1×10¹⁵ cm⁻³ or more and 1×10¹⁸ cm⁻³ or less.

In this embodiment, the first drain surface layer region 20 is formed in a self-aligned manner with respect to the sidewall of the first gate electrode 17 and is formed along the sidewall of the first gate electrode 17 in plan view. The first drain surface layer region 20 is formed on the first main surface 3 side with respect to the bottom of the first drain region 19. The presence or absence of the first drain surface layer region 20 is arbitrary and may be removed as necessary.

The semiconductor device 1A includes a p-type first source region 21 formed in the surface layer portion of the first well region 14. The p-type impurity concentration of the first source region 21 may be 1×10¹⁸ cm⁻³ or more and 1×10²⁰ cm⁻³ or less. The p-type impurity concentration of the first source region 21 is higher than the p-type impurity concentration of the first semiconductor region 6. The p-type impurity concentration of the first source region 21 is preferably substantially equal to the p-type impurity concentration of the first drain region 19.

The first source region 21 is formed in a region on the other side in the first direction X with respect to the first planar gate structure 15. The first source region 21 is formed in a region between the first region isolation structure 10 and the first planar gate structure 15 in plan view and faces the first drain region 19 with the first planar gate structure 15 interposed therebetween.

In this embodiment, the first source region 21 is formed in a self-aligned manner with respect to the first sidewall insulating film 18 and is formed along the first sidewall insulating film 18 in plan view. The first source region 21 is formed at an interval from the bottom wall of the first region isolation structure 10 (the first isolation trench 11) to the first main surface 3 side. The first source region 21 may be in contact with the first region isolation structure 10 (the first isolation trench 11).

The semiconductor device 1A includes a p-type first source surface layer region 22 drawn from the surface layer portion of the first source region 21 to a region directly below the first sidewall insulating film 18. The first source surface layer region 22 faces the first sidewall insulating film 18 with the first gate insulating film 16 interposed therebetween. The first source surface layer region 22 preferably has a p-type impurity concentration lower than the p-type impurity concentration of the first source surface layer region 22. The p-type impurity concentration of the first source surface layer region 22 may be 1×10¹⁵ cm⁻³ or more and 1×10¹⁸ cm⁻³ or less. The p-type impurity concentration of the first source surface layer region 22 is preferably substantially equal to the p-type impurity concentration of the first drain surface layer region 20.

The first source surface layer region 22 faces the first drain surface layer region 20 with a portion of the first well region 14 interposed therebetween. In this embodiment, the first source surface layer region 22 is formed in a self-aligned manner with respect to the sidewall of the first gate electrode 17 and is formed along the sidewall of the first gate electrode 17 in plan view. The first source surface layer region 22 is formed on the first main surface 3 side with respect to the bottom of the first source region 21. The presence or absence of the first source surface layer region 22 is arbitrary and may be removed as necessary.

The semiconductor device 1A includes an npn-type second MISFET structure 23 formed in the second MIS region 8b. The second MISFET structure 23 is complementarily connected to the first MISFET structure 13 to form a CMIS together with the first MISFET structure 13. The following configuration is described as a component of the semiconductor device 1A, but it is also a component of the second MISFET structure 23.

The semiconductor device 1A includes a p-type second well region 24 formed in the surface layer portion of the first main surface 3 in the second MIS region 8b. The p-type impurity concentration of the second well region 24 is higher than the p-type impurity concentration of the first semiconductor region 6. The p-type impurity concentration of the second well region 24 may be 1×10¹⁴ cm⁻³ or more and 1×10¹⁷ cm⁻³ or less. The second well region 24 is formed over the entire second MIS region 8b in plan view and is connected to the first region isolation structure 10. The second well region 24 is formed deeper than the first region isolation structure 10 and includes a portion covering the bottom wall of the first region isolation structure 10.

The semiconductor device 1A includes a second planar gate structure 25 arranged on the first main surface 3 in the second MIS region 8b. The second planar gate structure 25 includes a second gate insulating film 26, a second gate electrode 27, and a second sidewall insulating film 28. The second sidewall insulating film 28 may be called a “second sidewall structure.” The presence or absence of the second sidewall insulating film 28 is arbitrary and may be removed as necessary.

The second gate insulating film 26 covers the first main surface 3 in the form of a film in the second MIS region 8b. In this embodiment, the second gate insulating film 26 covers the entire second MIS region 8b and includes a portion connected to the first region isolation structure 10 (the first buried insulator 12). The second gate insulating film 26 has a thickness smaller than the thickness of the first protruding portion of the first buried insulator 12. It is preferable that the second gate insulating film 26 includes a silicon oxide film. It is particularly preferable that the second gate insulating film 26 includes a silicon oxide film made of oxide of the chip 2 (the first main surface 3).

The second gate electrode 27 is arranged on the second gate insulating film 26 in the inner portion of the second MIS region 8b. In this embodiment, the second gate electrode 27 is formed in a strip shape extending in the second direction Y in plan view. The second gate electrode 27 includes a first end portion and a second end portion respectively drawn from above the second gate insulating film 26 to above the first buried insulator 12.

The first end portion and the second end portion are respectively orthogonal to a portion of the first region isolation structure 10 extending in the first direction X. The second gate electrode 27 preferably includes conductive polysilicon containing n-type impurities (pentavalent element) and/or p-type impurities (trivalent element). The second gate electrode 27 may have an impurity concentration different from the impurity concentration of the first gate electrode 17.

The second sidewall insulating film 28 covers a sidewall of the second gate electrode 27. In this embodiment, the second sidewall insulating film 28 covers the sidewall of the second gate electrode 27 over the first buried insulator 12 and covers the sidewall of the second gate electrode 27 over the second gate insulating film 26. The second sidewall insulating film 28 may contain at least one of silicon oxide and silicon nitride.

The semiconductor device 1A includes an n-type second drain region 29 formed in the surface layer portion of the second well region 24. The n-type impurity concentration of the second drain region 29 is higher than the n-type impurity concentration of the first well region 14. The n-type impurity concentration of the second drain region 29 may be 1×10¹⁸ cm⁻³ or more and 1×10²⁰ cm⁻³ or less.

The second drain region 29 preferably contains an n-type impurity (pentavalent element) having a relatively small diffusion coefficient. The n-type impurity of the second drain region 29 is preferably arsenic. The second drain region 29 is formed in a region on one side in the first direction X with respect to the second planar gate structure 25. The second drain region 29 is formed in a region between the first region isolation structure 10 and the second planar gate structure 25 in plan view.

In this embodiment, the second drain region 29 is formed in a self-aligned manner with respect to the second sidewall insulating film 28 and is formed along the second sidewall insulating film 28 in plan view. The second drain region 29 is formed at an interval from the bottom wall of the first region isolation structure 10 (the first isolation trench 11) to the first main surface 3 side. The second drain region 29 may be in contact with the first region isolation structure 10 (the first isolation trench 11).

The semiconductor device 1A includes an n-type second drain surface layer region 30 drawn from the surface layer portion of the second drain region 29 to a region directly below the second sidewall insulating film 28. The second drain surface layer region 30 faces the second sidewall insulating film 28 with the second gate insulating film 26 interposed therebetween. The second drain surface layer region 30 preferably has an n-type impurity concentration lower than the n-type impurity concentration of the second drain region 29. The n-type impurity concentration of the second drain surface layer region 30 may be 1×10¹⁵ cm⁻³ or more and 1×10¹⁸ cm⁻³ or less.

In this embodiment, the second drain surface layer region 30 is formed in a self-aligned manner with respect to the sidewall of the second gate electrode 27 and is formed along the sidewall of the second gate electrode 27 in plan view. The second drain surface layer region 30 is formed on the first main surface 3 side with respect to the bottom of the second drain region 29. The presence or absence of the second drain surface layer region 30 is arbitrary and may be removed as necessary.

The semiconductor device 1A includes an n-type second source region 31 formed in the surface layer portion of the second well region 24. The n-type impurity concentration of the second source region 31 is higher than the n-type impurity concentration of the first well region 14. The n-type impurity concentration of the second source region 31 may be 1×10¹⁸ cm⁻³ or more and 1×10²⁰ cm⁻³ or less. The n-type impurity concentration of the second source region 31 is preferably substantially equal to the n-type impurity concentration of the second drain region 29.

The second source region 31 preferably contains an n-type impurity (pentavalent element) having a relatively small diffusion coefficient. The n-type impurity of the second source region 31 is preferably arsenic. The second source region 31 is formed in a region on the other side in the first direction X with respect to the second planar gate structure 25. The second source region 31 is formed in a region between the first region isolation structure 10 and the second planar gate structure 25 in plan view and faces the second drain region 29 with the second planar gate structure 25 interposed therebetween.

In this embodiment, the second source region 31 is formed in a self-aligned manner with respect to the second sidewall insulating film 28 and is formed along the second sidewall insulating film 28 in plan view. The second source region 31 is formed at an interval from the bottom wall of the first region isolation structure 10 (the first isolation trench 11) to the first main surface 3 side. The second source region 31 may be in contact with the first region isolation structure 10 (the first isolation trench 11).

The semiconductor device 1A includes an n-type second source surface layer region 32 drawn from the surface layer portion of the second source region 31 to a region directly below the second sidewall insulating film 28. The second source surface layer region 32 faces the second sidewall insulating film 28 with the second gate insulating film 26 interposed therebetween. The second source surface layer region 32 preferably has an n-type impurity concentration lower than the n-type impurity concentration of the second source region 31. The n-type impurity concentration of the second source surface layer region 32 may be 1×10¹⁵ cm⁻³ or more and 1×10¹⁸ cm⁻³ or less. The n-type impurity concentration of the second source surface layer region 32 is preferably substantially equal to the n-type impurity concentration of the second drain surface layer region 30.

The second source surface layer region 32 faces the second drain surface layer region 30 with a portion of the second well region 24 interposed therebetween. In this embodiment, the second source surface layer region 32 is formed in a self-aligned manner with respect to the sidewall of the second gate electrode 27 and is formed along the sidewall of the second gate electrode 27 in plan view. The second source surface layer region 32 is formed on the first main surface 3 side with respect to the bottom of the second source region 31. The presence or absence of the second source surface layer region 32 is arbitrary and may be removed as necessary.

The semiconductor device 1A includes an interlayer insulating film 33 that covers the CMIS region 8 on the first main surface 3. The interlayer insulating film 33 may include at least one of a silicon oxide film and a silicon nitride film. The interlayer insulating film 33 covers the first region isolation structure 10, the first planar gate structure 15, the first drain region 19, the first source region 21, the second planar gate structure 25, the second drain region 29, and the second source region 31.

The semiconductor device 1A includes at least one (in this embodiment, a plurality of) first gate via electrode 34, at least one (in this embodiment, a plurality of) first drain via electrode 35, and at least one (in this embodiment, a plurality of) first source via electrode 36 which are buried in the interlayer insulating film 33 on the first MIS region 8a side.

The plurality of first gate via electrodes 34 are buried in via openings formed in the interlayer insulating film 33, respectively, and are electrically connected to the first gate electrode 17. In this embodiment, the plurality of first gate via electrodes 34 are connected to the first end portion and the second end portion of the first gate electrode 17, respectively. That is, the plurality of first gate via electrodes 34 face the first region isolation structure 10 (the first buried insulator 12) with the first gate electrode 17 interposed therebetween. One or more first gate via electrodes 34 may be connected to any position (for example, central portion) of the first gate electrode 17.

The plurality of first drain via electrodes 35 are buried in via openings formed in the interlayer insulating film 33, respectively, and are electrically connected to the first drain region 19. In this embodiment, the plurality of first drain via electrodes 35 are arranged at intervals in the second direction Y. One or more first drain via electrodes 35 extending in a strip shape in the second direction Y may be connected to the first drain region 19.

The plurality of first source via electrodes 36 are buried in via openings formed in the interlayer insulating film 33, respectively, and are electrically connected to the first source regions 21. In this embodiment, the plurality of first source via electrodes 36 are arranged at intervals in the second direction Y. One or more first source via electrodes 36 extending in a strip shape in the second direction Y may be connected to the first source region 21.

The semiconductor device 1A includes a first gate wiring 37, a first drain wiring 38, and a first source wiring 39 which are arranged on the interlayer insulating film 33 on the first MIS region 8a side. The first gate wiring 37 is electrically connected to the plurality of first gate via electrodes 34 on the interlayer insulating film 33. The first drain wiring 38 is electrically connected to the plurality of first drain via electrodes 35 on the interlayer insulating film 33. The first source wiring 39 is electrically connected to the plurality of first source via electrodes 36 on the interlayer insulating film 33.

The semiconductor device 1A includes at least one (in this embodiment, a plurality of) second gate via electrode 40, at least one (in this embodiment, a plurality of) second drain via electrode 41, and at least one (in this embodiment, a plurality of) second source via electrode 42 which are buried in the interlayer insulating film 33 on the second MIS region 8b side.

The plurality of second gate via electrodes 40 are buried in via openings formed in the interlayer insulating film 33, respectively, and are electrically connected to the second gate electrode 27. In this embodiment, the plurality of second gate via electrodes 40 are connected to the first end portion and the second end portion of the second gate electrode 27, respectively. That is, the plurality of second gate via electrodes 40 face the first region isolation structure 10 (the first buried insulator 12) with the second gate electrode 27 interposed therebetween. One or more second gate via electrodes 40 may be connected to any position (for example, central portion) of the second gate electrode 27.

The plurality of second drain via electrodes 41 are buried in via openings formed in the interlayer insulating film 33, respectively, and are electrically connected to the second drain region 29. In this embodiment, the plurality of second drain via electrodes 41 are arranged at intervals in the second direction Y. One or more second drain via electrodes 41 extending in a strip shape in the second direction Y may be connected to the second drain region 29.

The plurality of second source via electrodes 42 are buried in via openings formed in the interlayer insulating film 33, respectively, and are electrically connected to the second source regions 31. In this embodiment, the plurality of second source via electrodes 42 are arranged at intervals in the second direction Y. One or more second source via electrodes 42 extending in a strip shape in the second direction Y may be connected to the second source region 31.

The semiconductor device 1A includes a second gate wiring 43, a second drain wiring 44, and a second source wiring 45 which are arranged on the interlayer insulating film 33 on the second MIS region 8b side. The second gate wiring 43 is electrically connected to the plurality of second gate via electrodes 40 on the interlayer insulating film 33. The second drain wiring 44 is electrically connected to the plurality of second drain via electrodes 41 on the interlayer insulating film 33. The second source wiring 45 is electrically connected to the plurality of second source via electrodes 42 on the interlayer insulating film 33.

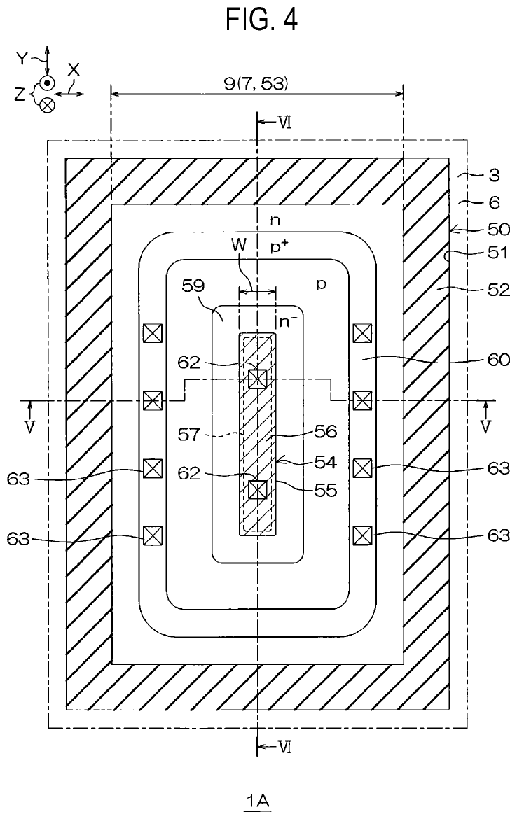

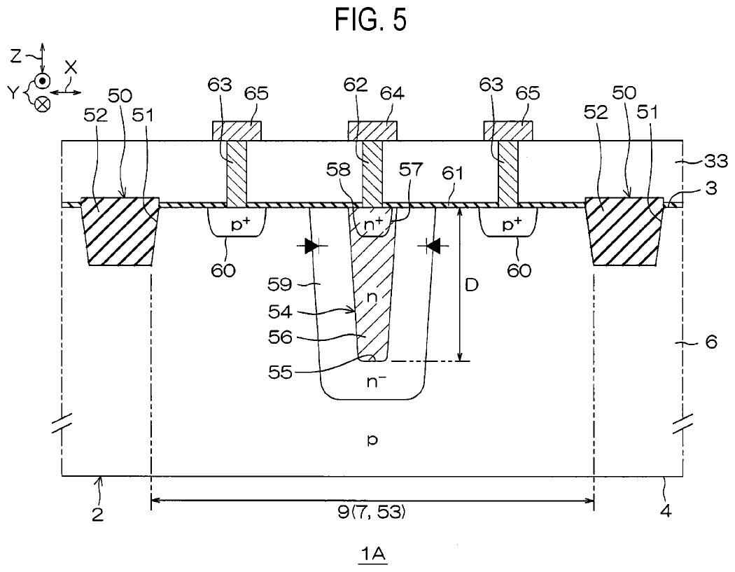

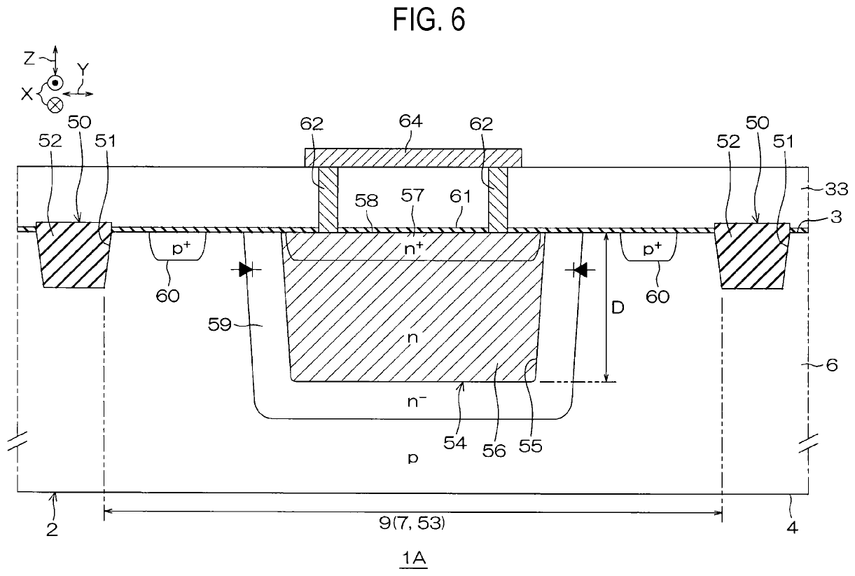

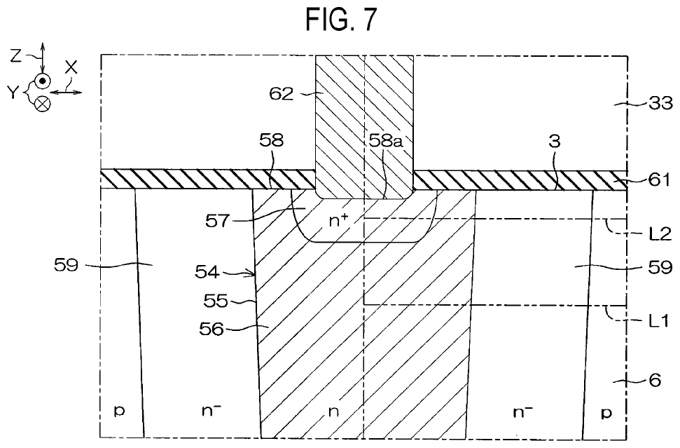

FIG. 4 is a plane view showing the light receiving region 9 in FIG. 1. FIG. 5 is a cross-sectional view taken along line V-V in FIG. 4. FIG. 6 is a cross-sectional view taken along line VI-VI in FIG. 4. FIG. 7 is a cross-sectional view showing the vicinity of the upper end portion of a trench structure 54 in FIG. 5.

Referring to FIGS. 4 to 7, the semiconductor device 1A includes a second region isolation structure 50 formed at the first main surface 3 to electrically isolate the light receiving region 9 from other circuit device regions 7 (the CMIS region 8, etc.). In this embodiment, the second region isolation structure 50 consists of a trench isolation structure. The second region isolation structure 50 may be referred to as a “second trench isolation structure.”

The second region isolation structure 50 is formed at the surface layer portion of the first semiconductor region 6 to be exposed from the first main surface 3. The second region isolation structure 50 is formed in an annular shape surrounding the light receiving region 9 in plan view. In this embodiment, the second region isolation structure 50 is formed in a polygonal annular shape (in this embodiment, a square annular shape) including four sides parallel to the periphery (the first to fourth side surfaces 5A to 5D) of the first main surface 3 in plan view.

The second region isolation structure 50 includes a second isolation trench 51 and a second buried insulator 52. The second isolation trench 51 is formed at the first main surface 3 and defines the wall surface of the second region isolation structure 50. The second isolation trench 51 is formed in a tapered shape in which the width of an opening gradually narrows from the opening toward the bottom wall when viewed in cross section.

The depth of the second isolation trench 51 may be 0.24 μm or more and 1 μm or less. The depth of the second isolation trench 51 may have a value belonging to any of ranges of 0.2 μm or more and 0.5 μm or less, 0.5 μm or more and 0.75 μm or less, and 0.75 μm or more and 1 μm or less. The depth of the second isolation trench 51 is preferably substantially equal to the depth of the first isolation trench 11. The depth of the second isolation trench 51 may be larger than the depth of the first isolation trench 11 or may be smaller than the depth of the first isolation trench 11.

The second buried insulator 52 is buried in the second isolation trench 51. In this embodiment, the second buried insulator 52 includes a second buried portion located on the bottom wall side of the second isolation trench 51 with respect to the first main surface 3, and a second protruding portion protruding upward from the second buried portion above the first main surface 3. The second buried insulator 52 may be formed to be flush with the first main surface 3. The second buried insulator 52 may contain at least one of silicon oxide and silicon nitride.

The semiconductor device 1A includes a photodiode structure 53 as an example of a light receiving device formed in the light receiving region 9. The following configuration is described as a component of the semiconductor device 1A, but it is also a component of the photodiode structure 53.

The semiconductor device 1A includes at least one (in this embodiment, one) trench structure 54 formed in the first main surface 3 in the light receiving region 9. The trench structure 54 is located within the first semiconductor region 6. The trench structure 54 is formed at an inner portion of the light receiving region 9 at an interval from the second region isolation structure 50.

The trench structure 54 is formed in a strip shape extending in the second direction Y in plan view. The trench structure 54 may be formed in a strip shape extending in the first direction X in plan view. The trench structure 54 does not necessarily have to be formed in a strip shape extending in one direction in plan view, and may be formed in a polygonal shape (square shape, hexagonal shape, etc.), circular shape, or elliptical shape in plan view. In this embodiment, the trench structure 54 is formed in a polygonal shape (specifically rectangular shape) including four sides parallel to the second region isolation structure 50 (the periphery of the first main surface 3).

The trench structure 54 is formed deeper than the first region isolation structure 10 when viewed in cross section. Further, the trench structure 54 is formed deeper than the second region isolation structure 50 when viewed in cross section. That is, the bottom wall of the trench structure 54 is located in a region on the second main surface 4 side with respect to the bottom wall of the first region isolation structure 10 and the bottom wall of the second region isolation structure 50. The bottom wall of the trench structure 54 is preferably located in a region closer to the second main surface 4 side than the bottom of the first well region 14 and the bottom of the second well region 24.

The trench structure 54 includes a trench 55, n-type polysilicon 56, and an n-type high-concentration impurity region 57. The polysilicon 56 may also be referred to as “conductive polysilicon,” “doped polysilicon,” “doped polysilicon electrode,” “polysilicon electrode,” and the like.

The trench 55 is formed in the first main surface 3 to be located within the first semiconductor region 6, and defines the wall surface of the trench structure 54. In this embodiment, the trench 55 is formed in a tapered shape in which the width of an opening gradually narrows from the opening toward the bottom wall when viewed in cross section.

The trench 55 is preferably formed in a tapered shape both when viewed in cross section along the first direction X and when viewed in cross section along the second direction Y. The trench 55 may be formed perpendicular to the first main surface 3. The bottom wall of the trench 55 is formed parallel to the first main surface 3 when viewed in cross section. The bottom wall of the trench 55 may be formed in an arc shape toward the second main surface 4 side.

The trench 55 has a trench width W and a trench depth D. The trench width W may be 0.5 μm or more and 5 μm or less. The trench width W may have a value belonging to any of ranges of 0.5 μm or more and 1 μm or less, 1 μm or more and 2 μm or less, 2 μm or more and 3 μm or less, 3 μm or more and 4 μm or less, and 4 μm or more and 5 μm or less.

The trench depth D may be 0.5 μm or more and 20 μm or less. The trench depth D may have a value belonging to any of ranges of 0.5 μm or more and 1 μm or less, 1 μm or more and 5 μm or less, 5 μm or more and 10 μm or less, 10 μm or more and 15 μm or less, and 15 μm or more and 20 μm or less.

The trench 55 is preferably a high-aspect ratio trench having an aspect ratio D/W of 1 or more. The aspect ratio D/W is the ratio of the trench depth D to the trench width W. The aspect ratio D/W may be 1 or more and 5 or less. The aspect ratio D/W may have a value belonging to any of ranges of 1 or more and 2 or less, 2 or more and 3 or less, 3 or more and 4 or less, and 4 or more and 5 or less.

The trench depth D is adjusted according to the wavelength band of light incident on the light receiving region 9. The internal photoelectric effect (photoconductivity) of the chip 2 caused by the incident light depends on the material of the chip 2. In the case of the chip 2 made of Si single crystal, the chip 2 has sensitivity in a wavelength band (ultraviolet region to infrared region) of 200 nm or more and 1,100 nm or less.

Blue light and ultraviolet light, which have a relatively small wavelength range of 500 nm or less, have a small penetration depth into the chip 2, so that the trench depth D may be set to a relatively small value. For example, when detecting the incident light having a relatively small wavelength range of 500 nm or less, the trench depth D may be 0.5 μm or more and 1 μm or less.

On the other hand, red light and infrared light, which have a relatively large wavelength range of 600 nm or more, have a large penetration depth into the chip 2, so that the trench depth D needs to be set to a relatively large value. For example, when detecting the incident light having a relatively large wavelength range of 600 nm or more, the trench depth D may be 1 μm or more and 20 μm or less.

The n-type polysilicon 56 is buried in the trench 55 and is mechanically and electrically connected to the chip 2 on the wall surface of the trench 55. Although it is also conceivable to bury the polysilicon 56 in the trench 55 via an insulator (insulating film), the polysilicon 56 is buried in the trench 55 without an insulator and includes a mechanical connection to the chip 2.

In this embodiment, the polysilicon 56 is buried in the trench 55, as a cathode buried electrode (polar buried electrode). The polysilicon 56 may be considered as a buried material that includes polysilicon buried in the trench 55 and an n-type impurity region (cathode region) formed within the polysilicon.

The polysilicon 56 has an impurity concentration different from those of the first well region 14, the first gate electrode 17, the first drain region 19 (the first source region 21), the second gate electrode 27, and the second drain region 29 (the second source region 31). The n-type impurity concentration of the polysilicon 56 is preferably lower than the n-type impurity concentration of the second drain region 29 (the second source region 31). The n-type impurity concentration of the polysilicon 56 may be 1×10¹⁵ cm⁻³ or more and 1×10¹⁹ cm⁻³ or less.

The polysilicon 56 preferably contains a different type of n-type impurity (pentavalent element) from the n-type impurity (pentavalent element) of the second drain region 29 (the second source region 31). The polysilicon 56 preferably contains an n-type impurity having a relatively large diffusion coefficient. The polysilicon 56 preferably contains an n-type impurity having a diffusion coefficient larger than that of arsenic. It is preferable that the n-type impurity of the polysilicon 56 is phosphorous or antimony. It is particularly preferable that the n-type impurity of the polysilicon 56 is phosphorus.

The polysilicon 56 fills the trench 55 back from the bottom wall side toward the opening side. In other words, the polysilicon 56 is buried in the trench 55, as a single material. Specifically, the polysilicon 56 is formed by laminating polysilicon layers from the wall surface of the trench 55 to the inner portion of the trench 55 to be integrated in the inner portion of the trench 55 when viewed in cross section.

In other words, the polysilicon 56 includes a configuration in which the entire trench 55 is filled back, and does not include a configuration in which the wall surface of the trench 55 is covered with the form of a film to define a recess space within the trench 55. The polysilicon 56 may include a lamination boundary portion extending along the depth direction of the trench 55 in the inner portion. The lamination boundary portion is an integrated portion (connection portion) of the polysilicon layers laminated inward from the sidewalls on both sides when viewed in cross section.

Referring to FIG. 7, the polysilicon 56 includes an upper end portion 58 (upper end surface) exposed from the opening of the trench 55. The upper end portion 58 includes a flat surface extending parallel to the first main surface 3. The upper end portion 58 may be continuous with the first main surface 3. That is, the upper end portion 58 may be formed to be flush with the first main surface 3. In this case, the first main surface 3 may be a grinding surface and the upper end portion 58 may also be a grinding surface. That is, the upper end portion 58 may form one grinding surface with the first main surface 3.

The n-type high-concentration impurity region 57 has an n-type impurity concentration higher than the n-type impurity concentration of the polysilicon 56 and is formed within the polysilicon 56. The high-concentration impurity region 57 is a region formed by introducing an n-type impurity into the polysilicon 56. That is, in this embodiment, the high-concentration impurity region 57 is a high-concentration cathode region in which the polysilicon 56 is used as a low-concentration cathode region.

The n-type impurity concentration of the high-concentration impurity region 57 is preferably higher than the n-type impurity concentration of the second drain surface layer region 30 (the second source surface layer region 32). The n-type impurity concentration of the high-concentration impurity region 57 is preferably higher than the n-type impurity concentration of the second drain region 29 (the second source region 31). The n-type impurity concentration of the high-concentration impurity region 57 is preferably the sum of the n-type impurity concentration of the polysilicon 56 and the n-type impurity concentration of the second drain region 29 (the second source region 31).

The high-concentration impurity region 57 preferably contains an n-type impurity (pentavalent element) different from the n-type impurity (pentavalent element) of the polysilicon 56. The high-concentration impurity region 57 preferably contains an n-type impurity having a diffusion coefficient smaller than the diffusion coefficient of the n-type impurity of the polysilicon 56. The high-concentration impurity region 57 preferably contains an n-type impurity having a diffusion coefficient smaller than the diffusion coefficient of phosphorus.

It is particularly preferable that the n-type impurity of the high-concentration impurity region 57 is arsenic or antimony. It is particularly preferable that the n-type impurity of the polysilicon 56 is arsenic. The n-type impurity of the high-concentration impurity region 57 is preferably of the same type as the n-type impurity of the second drain region 29 (the second source region 31).

In this embodiment, a single high-concentration impurity region 57 is formed within the polysilicon 56. The high-concentration impurity region 57 is formed in a strip shape extending in the second direction Y along the trench 55 in plan view. A plurality of high-concentration impurity regions 57 may be formed at intervals along the trench 55 in plan view.

The high-concentration impurity region 57 is formed within the polysilicon 56 at an interval from the lower end of the polysilicon 56 (the bottom wall of the trench 55) to the upper end portion 58 side of the polysilicon 56 when viewed in cross section. As a result, the high-concentration impurity region 57 faces the chip 2 with a portion of the polysilicon 56 (the low-concentration impurity region) interposed therebetween in the depth direction of the trench 55. The high-concentration impurity region 57 is preferably formed at an interval from the middle portion of the depth range of the trench 55 to the upper end portion 58 side of the polysilicon 56.

In this embodiment, the high-concentration impurity region 57 is formed in the surface layer portion of the polysilicon 56 and is exposed from the upper end portion 58 of the polysilicon 56. The thickness of the high-concentration impurity region 57 is preferably substantially equal to the thickness of the second drain region 29 (the second source region 31). The thickness of the high-concentration impurity region 57 is a thickness based on the upper end portion 58 of the polysilicon 56. Depending on the height position of the upper end portion 58 of the polysilicon 56, the bottom of the high-concentration impurity region 57 is not necessarily located on the same plane as the bottom of the second drain region 29 (the second source region 31).

The high-concentration impurity region 57 is formed within the polysilicon 56 inward at an interval from the wall surface of the trench 55 in plan view and cross-sectional view. The high-concentration impurity region 57 faces the surface layer portion of the first main surface 3 with a portion of the polysilicon 56 interposed therebetween in the horizontal direction (the first direction X and the second direction Y) along the first main surface 3. In this embodiment, the high-concentration impurity region 57 is formed inward at an interval from the entire circumference of the wall surface of the trench 55 in plan view. That is, the high-concentration impurity region 57 is surrounded by a portion of the polysilicon 56 in plan view.

The semiconductor device 1A includes an n-type second semiconductor region 59 formed within the chip 2 along the wall surface of the trench structure 54 in the light receiving region 9. The second semiconductor region 59 is formed within the first semiconductor region 6 and is mechanically and electrically connected to the polysilicon 56 on the wall surface of the trench 55. The second semiconductor region 59 forms a pn junction with the first semiconductor region 6.

The pn junction functions as a photodiode including the p-type first semiconductor region 6 as an anode and the second semiconductor region 59 as a cathode. When a reverse bias voltage is applied between the first semiconductor region 6 and the second semiconductor region 59, the pn junction forms a depletion layer within the chip 2 due to a potential difference between the first semiconductor region 6 and the second semiconductor region 59. Incident light entering this depletion layer generates a photocurrent due to the photoelectric effect.

The second semiconductor region 59 has an n-type impurity concentration lower than the n-type impurity concentration of the high-concentration impurity region 57. The n-type impurity concentration of the second semiconductor region 59 is lower than the n-type impurity concentration of the second drain region 29 (the second source region 31). The n-type impurity concentration of the second semiconductor region 59 is lower than the n-type impurity concentration of the polysilicon 56. The n-type impurity concentration of the second semiconductor region 59 may be 1×10¹⁴ cm⁻³ or more and 1×10¹⁷ cm⁻³ or less.

The second semiconductor region 59 preferably contains a different type of n-type impurity (pentavalent element) from the n-type impurity (pentavalent element) of the second drain region 29 (the second source region 31). The second semiconductor region 59 preferably contains a different type of n-type impurity from the n-type impurity of the high-concentration impurity region 57. In this embodiment, the second semiconductor region 59 is a region formed by introducing an n-type impurity into the p-type first semiconductor region 6. Specifically, the second semiconductor region 59 is a region formed by diffusing an n-type impurity into the first semiconductor region 6 using the polysilicon 56 as a solid-phase diffusion source.

That is, the n-type impurity of the second semiconductor region 59 is of the same type as the n-type impurity of the polysilicon 56 and has a diffusion coefficient larger than the diffusion coefficient of the n-type impurity of the high-concentration impurity region 57. Further, the second semiconductor region 59 contains the p-type impurity of the first semiconductor region 6 and the n-type impurity of the polysilicon 56 and replaces the conductivity type of the first semiconductor region 6 from p-type to n-type. Therefore, the n-type impurity concentration of the second semiconductor region 59 is higher than the p-type impurity concentration of the first semiconductor region 6.

The high-concentration impurity region 57 is not formed as a solid-phase diffusion source for the second semiconductor region 59. Further, the n-type impurity of the high-concentration impurity region 57 has a relatively low diffusion coefficient. Further, the high-concentration impurity region 57 is formed at an inner portion of the polysilicon 56. Therefore, the high-concentration impurity region 57 does not supply an n-type impurity to the first semiconductor region 6.

Even if the high-concentration impurity region 57 supplies an n-type impurity to the first semiconductor region 6, the amount of n-type impurity supplied is so small that it does not affect the n-type impurity concentration of the second semiconductor region 59. Therefore, it can be said that the second semiconductor region 59 does not contain the n-type impurity of the high-concentration impurity region 57. The n-type impurity concentration of the second semiconductor region 59 is determined by the amount of n-type impurity supplied from the polysilicon 56 and is adjusted by the n-type impurity concentration of the polysilicon 56.

The second semiconductor region 59 is formed in an annular shape (in this embodiment, a square annular shape) surrounding the wall surface of the trench structure 54 in plan view. The second semiconductor region 59 is formed along the sidewall and the bottom wall of the trench structure 54 when viewed in cross section, and is exposed from the first main surface 3 on the opening side of the trench structure 54.

The second semiconductor region 59 is mechanically and electrically connected to the polysilicon 56 over the entire region of the wall surface of the trench structure 54 to form a pn junction along the sidewall and the bottom wall of the trench structure 54. The depth position of the pn junction with respect to the first main surface 3 is adjusted by the trench depth D. That is, by forming the trench structure 54 having a relatively large trench depth D, a pn junction can be formed at a relatively deep position. As a result, detection sensitivity for incident light (red light to infrared light) in a relatively large wavelength band can be enhanced.

A portion of the second semiconductor region 59 along the sidewall of the trench structure 54 extends along the sidewall of the trench structure 54 while being inclined with respect to the first main surface 3. When the sidewall of the trench structure 54 is formed perpendicular to the first main surface 3, the second semiconductor region 59 may extend perpendicular to the first main surface 3. A portion of the second semiconductor region 59 along the bottom wall of the trench structure 54 extends parallel to the bottom wall of the trench structure 54. When the bottom wall of the trench structure 54 is formed in an arc shape, the second semiconductor region 59 may be curved in an arc shape along the bottom wall.

The second semiconductor region 59 includes a portion facing the high-concentration impurity region 57 via a portion of the polysilicon 56 at the opening end of the trench structure 54 (the surface layer portion of the first main surface 3) and is electrically connected to the high-concentration impurity region 57 via a portion of the polysilicon 56. The second semiconductor region 59 is connected to the polysilicon 56 in a region on the bottom wall side of the trench structure 54 with respect to the bottom of the high-concentration impurity region 57.

The second semiconductor region 59 is formed along the wall surface of the trench structure 54 when viewed in cross section, and does not include a portion drawn in the form of a layer in the horizontal direction (lateral direction) along the first main surface 3 in the surface layer portion of the first main surface 3.

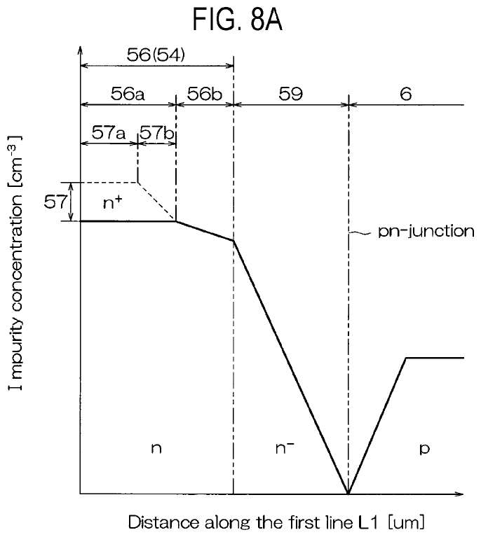

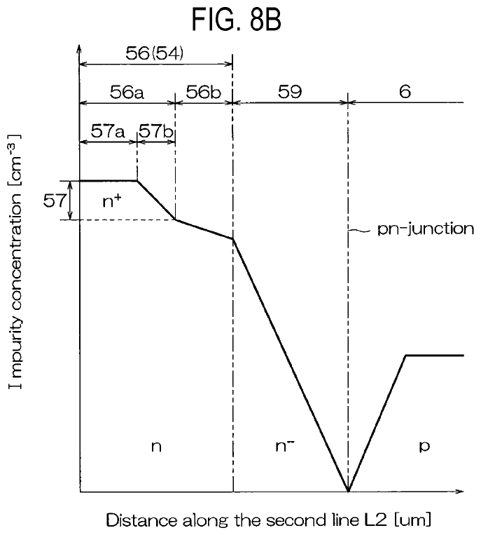

Referring to FIGS. 8A and 8B together with FIG. 7, examples of concentration gradients of the polysilicon 56, the high-concentration impurity region 57, and the second semiconductor region 59 are shown below. FIG. 8A is a first graph showing an example of a concentration gradient along a first line L1 in FIG. 7. FIG. 8B is a second graph showing an example of a concentration gradient along a second line L2 in FIG. 7.

Referring to FIG. 7, the first line L1 is a virtual line set in the horizontal direction (the first direction X) along the first main surface 3 from the central portion of the polysilicon 56 to pass through the polysilicon 56, the second semiconductor region 59, and the first semiconductor region 6. The second line L2 is a virtual line set in the horizontal direction (the first direction X) along the first main surface 3 from the central portion of the polysilicon 56 to pass through the high-concentration impurity region 57, the polysilicon 56, the second semiconductor region 59, and the first semiconductor region 6.

In FIGS. 8A and 8B, the vertical axis indicates an impurity concentration [cm⁻³], and the horizontal axis indicates a distance [μm] when the central portion of the polysilicon 56 is set as a zero point. In FIG. 8A, the impurity concentration of the second line L2 is indicated by a broken line, and in FIG. 8B, the impurity concentration of the first line L1 is indicated by a broken line.

Referring to FIG. 8A, the polysilicon 56 includes an inner portion 56a having a relatively high n-type impurity concentration and a peripheral portion 56b having an n-type impurity concentration lower than the n-type impurity concentration of the inner portion 56a. The n-type impurity concentration of the inner portion 56a is substantially constant. On the other hand, the n-type impurity concentration of the peripheral portion 56b gradually decreases from the inner portion 56a toward the wall surface of the trench 55. That is, the polysilicon 56 has a concentration gradient that gradually decreases from the inner portion 56a (the central portion of the trench 55) toward the peripheral portion 56b (the wall surface of the trench 55). The polysilicon 56 may have a concentration gradient that gradually decreases continuously from the inner portion 56a toward the peripheral portion 56b.

The second semiconductor region 59 has a concentration gradient that gradually decreases starting from the wall surface of the trench structure 54 (the peripheral portion 56b of the polysilicon 56). The n-type impurity concentration of the second semiconductor region 59 monotonously decreases from the wall surface of the trench structure 54 (the peripheral portion 56b of the polysilicon 56). In a portion of the second semiconductor region 59 covering the sidewall, the n-type impurity concentration gradually decreases along the horizontal direction starting from the sidewall. On the other hand, in the portion of the second semiconductor region 59 covering the sidewall, the n-type impurity concentration gradually decreases in the thickness direction of the chip 2 starting from the bottom wall.

Referring to FIG. 8B, the high-concentration impurity region 57 includes an inner portion 57a having a relatively high n-type impurity concentration and a peripheral portion 57b having an n-type impurity concentration lower than the n-type impurity concentration of the inner portion 57a. The n-type impurity concentration of the inner portion 57a is substantially constant. On the other hand, the n-type impurity concentration of the peripheral portion 57b gradually decreases from the inner portion 57a toward the wall surface of the trench 55.

That is, the high-concentration impurity region 57 has a concentration gradient that gradually decreases from the inner portion 57a (the central portion of the trench 55) toward the peripheral portion 57b (the wall surface of the trench 55). The peripheral portion 57b of the high-concentration impurity region 57 may be connected to the inner portion 56a of the polysilicon 56 or may be connected to the peripheral portion 56b of the polysilicon 56. The high-concentration impurity region 57 may have a concentration gradient that gradually decreases continuously from the inner portion 57a toward the peripheral portion 57b.

The second semiconductor region 59 has a concentration gradient that gradually decreases starting from the wall surface of the trench structure 54 (the peripheral portion 56b of the polysilicon 56) even in a portion facing the high-concentration impurity region 57. In other words, it can be said that the n-type impurity concentration of the second semiconductor region 59 is not affected by the high-concentration impurity region 57. In the present disclosure, such a state is defined that the second semiconductor region 59 does not contain the n-type impurity of the high-concentration impurity region 57.

Referring again to FIGS. 4 to 6, the semiconductor device 1A includes a p-type contact region 60 formed in the surface layer portion of the first main surface 3 at an interval from the trench structure 54 in the light receiving region 9. The contact region 60 has a p-type impurity concentration higher than the p-type impurity concentration of the first semiconductor region 6. That is, the contact region 60 is a high-concentration anode region with the first semiconductor region 6 as a low-concentration anode region.

The p-type impurity concentration of the contact region 60 is preferably higher than the p-type impurity concentration of the first drain surface layer region 20 (the first source surface layer region 22). The p-type impurity concentration of the contact region 60 is preferably substantially equal to the p-type impurity concentration of the first drain region 19 (the first source region 21). The p-type impurity concentration of the contact region 60 may be 1×10¹⁸ cm⁻³ or more and 1×10²⁰ cm⁻³ or less.

In this embodiment, the contact region 60 is formed in a region between the second region isolation structure 50 and the second semiconductor region 59 at an interval from the second region isolation structure 50 and the second semiconductor region 59. The contact region 60 may be formed in contact with the second region isolation structure 50 (the trench 55 and the second isolation trench 51). The contact region 60 faces the second semiconductor region 59 with a portion of the first semiconductor region 6 interposed therebetween in the horizontal direction along the first main surface 3.

The contact region 60 is formed at an interval from the depth position of the bottom wall of the trench structure 54 to the first main surface 3 side. That is, the contact region 60 is formed in a region shallower than the trench structure 54. The contact region 60 is formed at an interval from the depth position of the bottom wall of the second region isolation structure 50 (the first region isolation structure 10) to the first main surface 3 side. That is, the contact region 60 is formed in a region shallower than the second region isolation structure 50. The contact region 60 preferably has a thickness substantially equal to the thickness of the first drain region 19 (the first source region 21).

The contact region 60 is formed in a strip shape extending along the trench structure 54 in plan view. In this embodiment, the contact region 60 has a strip-shaped portion extending along the first direction X and a strip-shaped portion extending along the second direction Y in plan view. Specifically, the contact region 60 is formed in an annular shape (in this embodiment, a square annular shape) surrounding the trench structure 54 in plan view.

The semiconductor device 1A includes a main surface insulating film 61 covering the first main surface 3 in the light receiving region 9. The main surface insulating film 61 covers the first main surface 3 in the form of a film in the light receiving region 9. In this embodiment, the main surface insulating film 61 covers the entire region of the light receiving region 9 and includes a portion connected to the second region isolation structure 50 (the second buried insulator 52).

The main surface insulating film 61 includes a portion covering the outside of the trench structure 54 and a portion covering the inside of the trench structure 54 in the light receiving region 9. The main surface insulating film 61 covers the first semiconductor region 6, the second semiconductor region 59, and the contact region 60 in a regions outside the trench structure 54. The main surface insulating film 61 covers the inner portion and the peripheral portion of the polysilicon 56 in a region inside the trench structure 54. That is, the main surface insulating film 61 also covers the high-concentration impurity region 57 in the region inside the trench structure 54.

The main surface insulating film 61 has a thickness smaller than the thickness of the upper end portion 58 of the second protruding portion of the second buried insulator 52. The thickness of the main surface insulating film 61 may be substantially equal to either one or both of the thickness of the first gate insulating film 16 and the thickness of the second gate insulating film 26. It is preferable that the main surface insulating film 61 includes a silicon oxide film. It is particularly preferable that the main surface insulating film 61 includes a silicon oxide film made of oxide of the chip 2 (the first main surface 3).

In this case, the main surface insulating film 61 preferably includes a silicon oxide film made of oxide of the polysilicon 56 in a portion covering the polysilicon 56. In this case, the main surface insulating film 61 contains the n-type impurity of the polysilicon 56 and the n-type impurity of the high-concentration impurity region 57 in the portion covering the polysilicon 56.

The semiconductor device 1A includes the above-described interlayer insulating film 33 covering the light receiving region 9 on the first main surface 3. The interlayer insulating film 33 covers the first semiconductor region 6, the second region isolation structure 50, the trench structure 54, the second semiconductor region 59, the contact region 60, and the main surface insulating film 61 in the light receiving region 9.

The semiconductor device 1A includes at least one (in this embodiment, a plurality of) cathode via electrode 62 (first polarity via electrode) and at least one (in this embodiment, a plurality of) anode via electrode 63 (second polarity via electrode) which are buried in the interlayer insulating film 33 in the light receiving region 9.

The plurality of cathode via electrodes 62 are buried in via openings formed in the interlayer insulating film 33, respectively, and are mechanically and electrically connected to the upper end portion 58 of the polysilicon 56. In this embodiment, the plurality of cathode via electrodes 62 are mechanically and electrically connected to the high-concentration impurity region 57. The plurality of cathode via electrodes 62 form ohmic contact with the high-concentration impurity region 57.

Referring to FIG. 7, the upper end portion 58 of the polysilicon 56 may include a plurality of recesses 58a recessed toward the bottom wall of the trench 55. In this case, the plurality of cathode via electrodes 62 may be connected to the upper end portion 58 of the polysilicon 56 via a plurality of via openings communicating with the plurality of recesses 58a. In this embodiment, the plurality of cathode via electrodes 62 are mechanically and electrically connected to the polysilicon 56 (the high-concentration impurity region 57) within the recesses.

In this embodiment, the plurality of cathode via electrodes 62 are arranged at intervals in the extending direction (the second direction Y) of the trench structure 54. One or more cathode via electrodes 62 extending in a strip shape in the second direction Y may be connected to the polysilicon 56.

In this embodiment, the plurality of cathode via electrodes 62 are connected to the polysilicon 56 at intervals from the second semiconductor region 59. Specifically, the plurality of cathode via electrodes 62 are connected to the inner portion of the polysilicon 56 at intervals from the wall surface of the trench 55 (the periphery of the polysilicon 56). Therefore, the plurality of cathode via electrodes 62 include only a mechanical connection to the polysilicon 56 and no mechanical connection to the second semiconductor region 59.

The plurality of anode via electrodes 63 are buried in via openings formed in the interlayer insulating film 33, respectively, and are electrically and mechanically connected to arbitrary locations in the contact region 60, respectively. In this embodiment, the plurality of anode via electrodes 63 are arranged at intervals in the second direction Y in a portion of the contact region 60 extending in the second direction Y.

The plurality of anode via electrodes 63 may be arranged at intervals in the first direction X in a portion of the contact region 60 extending in the first direction X. Further, the plurality of anode via electrodes 63 may be arranged at intervals in the first direction X in the portion of the contact region 60 extending in the first direction X, and may be arranged at intervals in the second direction Y in the portion of the contact region 60 extending in the second direction Y.

One or more anode via electrodes 63 extending in a strip shape along the contact region 60 in the first direction X and/or the second direction Y may be connected to the contact region 60. For example, a single anode via electrode 63 extending in an annular shape along the contact region 60 may be formed.

The semiconductor device 1A includes one or more (in this embodiment, one) cathode wiring 64 and one or more (in this embodiment, one) anode wiring 65, which are arranged on the interlayer insulating film 33 in the light receiving region 9. The cathode wiring 64 is connected to the plurality of cathode via electrodes 62 on the interlayer insulating film 33.

As a result, the cathode wiring 64 is electrically connected to one trench structure 54 (the polysilicon 56) via the plurality of cathode via electrodes 62. A plurality of cathode wirings 64 may be connected to the plurality of cathode via electrodes 62. That is, the plurality of cathode wirings 64 may be electrically connected to one trench structure 54 (the polysilicon 56) via the plurality of cathode via electrodes 62.

The anode wiring 65 is electrically connected to the plurality of anode via electrodes 63 on the interlayer insulating film 33. As a result, the anode wiring 65 is electrically connected to one contact region 60 via the plurality of anode via electrodes 63. A plurality of anode wirings 65 may be connected to the plurality of anode via electrodes 63. That is, the plurality of anode wirings 65 may be electrically connected to one contact region 60 via the plurality of anode via electrodes 63.

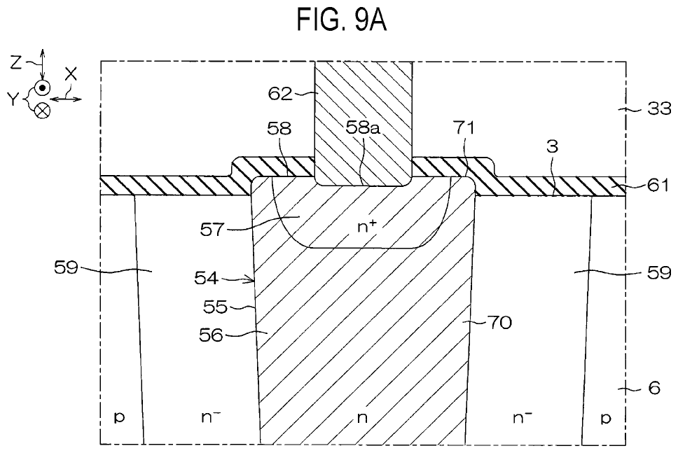

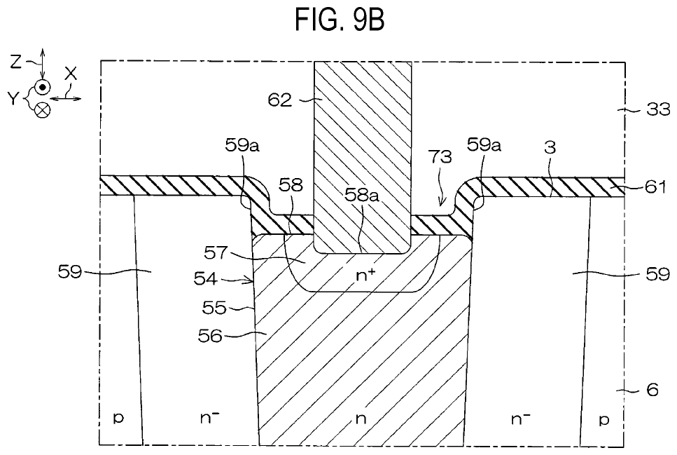

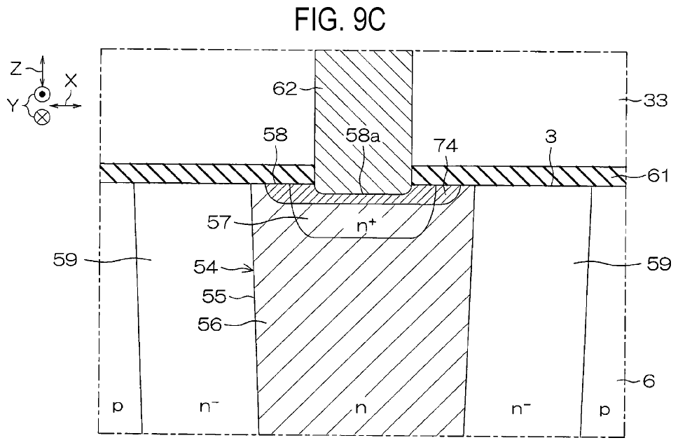

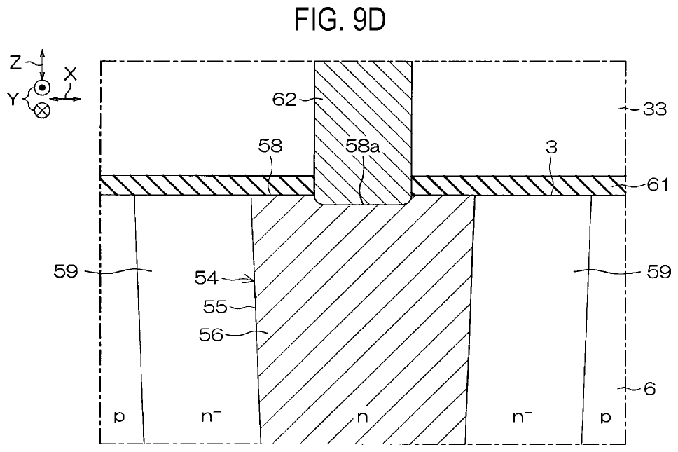

Referring to FIGS. 9A to 9D, modification examples (first to fourth modification examples) of the trench structure 54 are shown below. FIG. 9A is a cross-sectional view showing the first modification example of the trench structure 54. FIG. 9B is a cross-sectional view showing the second modification example of the trench structure 54. FIG. 9C is a cross-sectional view showing the third modification example of the trench structure 54. FIG. 9D is a cross-sectional view showing the fourth modification example of the trench structure 54.

Referring to FIG. 9A, the polysilicon 56 may include a trench buried portion 70 buried in the trench 55 and a trench protruding portion 71 protruding from the trench buried portion 70 above the first main surface 3 (on the side opposite to the chip 2). The thickness of the trench protruding portion 71 may be larger than the thickness of the second protruding portion of the second buried insulator 52 or may be smaller than the thickness of the second protruding portion of the second buried insulator 52. The upper end portion 58 of the polysilicon 56 is formed by trench protruding portion 71.

The high-concentration impurity region 57 may include a portion located in the trench buried portion 70 and a portion located in the trench protruding portion 71. The cross-sectional area of the portion of the high-concentration impurity region 57 located within the trench protruding portion 71 is preferably smaller than the cross-sectional area of the portion of the high-concentration impurity region 57 located within the trench buried portion 70. The cross-sectional area of the portion located within the trench protruding portion 71 may be larger than the cross-sectional area of the portion located within the trench buried portion 70.

The aforementioned main surface insulating film 61 covers the trench protruding portion 71 (the upper end portion 58) of the polysilicon 56 from above the second semiconductor region 59 via the protruding sidewall of the polysilicon 56. The aforementioned plurality of cathode via electrodes 62 are mechanically and electrically connected to the trench protruding portion 71 (the upper end portion 58) of the polysilicon 56.

Referring to FIG. 9B, the polysilicon 56 may include an upper end portion 58 located on the bottom wall side of the trench 55 with respect to the first main surface 3. That is, the polysilicon 56 may include an upper end portion 58 that defines the sidewall of the trench 55 and the recess space 73. The depth of the recess space 73 is preferably shallower than the middle portion of the depth range of the trench 55. The depth of the recess space 73 is preferably 1 μm or less with respect to the first main surface 3.

The polysilicon 56 defines a sidewall window portion that exposes a portion (the surface layer portion of the first main surface 3) of the chip 2 in a portion of the sidewall of the trench 55 located between the upper end portion 58 and the first main surface 3. The polysilicon 56 preferably defines the sidewall window portion over the entire circumference of the wall surface of the trench 55.

The aforementioned second semiconductor region 59 is formed along the entire region of the wall surface of the trench 55. In other words, the second semiconductor region 59 includes an exposed portion 59a exposed from the sidewall window portion of the trench 55 in the surface layer portion of the first main surface 3. The exposed portion 59a is exposed from the entire region of the sidewall window portion. The exposed portion 59a is also exposed from the first main surface 3.

The aforementioned main surface insulating film 61 enters the recess space 73 from above the first main surface 3 (the second semiconductor region 59) and covers the sidewall window portion of the trench 55 and the upper end portion 58 of the polysilicon 56 in the form of a film. That is, the main surface insulating film 61 covers the exposed portion 59a of the second semiconductor region 59 at the sidewall window portion of the trench 55. The outer surface of a portion of the insulating main surface of the main surface insulating film 61 located in the trench 55 may be located on the bottom wall side of the trench 55 with respect to the first main surface 3. The outer surface of the portion of the main surface insulating film 61 covering the polysilicon 56 may be located above the first main surface 3.

When the main surface insulating film 61 contains a silicon oxide film made of oxide of the chip 2, the main surface insulating film 61 may contain the n-type impurity of the second semiconductor region 59 in the portion covering the sidewall window portion. That is, the main surface insulating film 61 may contain the n-type impurity of the polysilicon 56 even in the sidewall window portion. The aforementioned plurality of cathode via electrodes 62 are formed inward at intervals from the wall surface of the trench 55 and are mechanically and electrically connected to the upper end portion 58 of the polysilicon 56 within the trench 55.

Referring to FIG. 9C, the trench structure 54 may include a silicide layer 74 covering the upper end portion 58 of the polysilicon 56. The silicide layer 74 may be integrated with the upper end portion 58 of the polysilicon 56. The silicide layer 74 preferably consists of a polycide region obtained by siliciding the upper end portion 58 of the polysilicon 56 with a metal material. The silicide layer 74 may include at least one of a TiSi layer, a TiSi₂ layer, a NiSi layer, a CoSi layer, a CoSi₂ layer, a MoSi₂ layer, and a WSi₂ layer.

The silicide layer 74 extends along the upper end portion 58 of the polysilicon 56 in the form of a layer or film. The silicide layer 74 may be formed on the upper end portion 58 side of the polysilicon 56 at an interval from the bottom of the high-concentration impurity region 57. That is, the silicide layer 74 may contain the n-type impurity of the polysilicon 56 and the n-type impurity of the high-concentration impurity region 57. Substantially the entire high-concentration impurity region 57 may be replaced with the silicide layer 74.

In this embodiment, a single silicide layer 74 is formed in the upper end portion 58 of the polysilicon 56. The silicide layer 74 is formed in a strip shape extending in the second direction Y along the trench 55 in plan view. A plurality of silicide layers 74 may be formed at intervals along the trench 55 in plan view.

The silicide layer 74 may be formed at the upper end portion 58 of the polysilicon 56 inward at an interval from the wall surface of the trench 55 in plan view and cross-sectional view. In this case, the silicide layer 74 may be formed inward at an interval from the entire circumference of the wall surface of the trench 55 in plan view. That is, the silicide layer 74 may be surrounded by a portion of the polysilicon 56 (the low-concentration impurity region) in plan view.

The silicide layer 74 may face the surface layer portion of the first main surface 3 with a portion of the polysilicon 56 interposed therebetween in the horizontal direction (the first direction X and the second direction Y) along the first main surface 3. The silicide layer 74 may cover the entire region of the upper end portion 58 of the polysilicon 56 to be in contact with the surface layer portion of the chip 2. The silicide layer 74 may be formed partially or entirely in the surface layer portion of the second semiconductor region 59. In this case, the silicide layer 74 preferably consists of a silicide region obtained by siliciding the first main surface 3 (the chip 2) with a metal material.

The aforementioned main surface insulating film 61 may include a portion covering the silicide layer 74. The main surface insulating film 61 may be formed to expose the silicide layer 74. The aforementioned plurality of cathode via electrodes 62 are mechanically and electrically connected to the silicide layer 74. That is, the plurality of cathode via electrodes 62 are connected to the high-concentration impurity region 57 and the polysilicon 56 via the silicide layer 74. The plurality of cathode via electrodes 62 form ohmic contact with the silicide layer 74.

In this embodiment, the aforementioned recess 58a is formed in the silicide layer 74. The recess 58a may penetrate the silicide layer 74 to expose the polysilicon 56. The configuration in which the trench structure 54 includes the silicide layer 74 is also applicable to the first and second modification examples.

Although not shown in detail, a silicide layer similar to the silicide layer 74 may be formed in a structure to which a via electrode is to be connected. In other words, silicide layers may be formed in the surface layer portion of the first gate electrode 17, the surface layer portion of the first drain region 19 (the first drain surface layer region 20), the surface layer portion of the first source region 21 (the first source surface layer region 22), the surface layer portion of the second gate electrode 27, the surface layer portion of the second drain region 29 (the second drain surface layer region 30), the surface layer portion of the second source region 31 (the second source surface layer region 32), and the surface layer portion of the contact region 60, respectively.

Referring to FIG. 9D, the trench structure 54 does not necessarily need to include the high-concentration impurity region 57. Therefore, the trench structure 54 without the high-concentration impurity regions 57 may be employed. In this case, the aforementioned main surface insulating film 61 covers the polysilicon 56 in a portion covering the trench structure 54. Further, the aforementioned cathode via electrodes 62 are connected to the polysilicon 56. The configuration in which the trench structure 54 does not include the high-concentration impurity region 57 is also applicable to the first to third modification examples.

As described above, the semiconductor device includes the chip 2, the p-type (first conductivity type) first semiconductor region 6, the trench structure 54, and the n-type (second conductivity type) second semiconductor region 59. The chip 2 includes the first main surface 3. The first semiconductor region 6 is formed at least in the surface layer portion of the first main surface 3. The trench structure 54 includes the trench 55 and the n-type polysilicon 56.

The trench 55 is formed at the first main surface 3 so as to be located within the first semiconductor region 6. The polysilicon 56 is mechanically and electrically connected to the chip 2 and located within the trench 55. The second semiconductor region 59 is formed at the surface layer portion of the first main surface 3 along the wall surface of the trench structure 54.

The second semiconductor region 59 forms a pn junction, as a photodiode, with the first semiconductor region 6.

According to this configuration, it is possible to provide a semiconductor device 1A including a photodiode with a novel layout in which a pn junction can be formed in a relatively deep region in the chip 2 using the trench structure 54.

The second semiconductor region 59 preferably contains an n-type impurity of the same type as the n-type impurity of the polysilicon 56. The second semiconductor region 59 preferably has an impurity concentration lower than that of the polysilicon 56. The second semiconductor region 59 preferably has a concentration gradient that gradually decreases starting from the polysilicon 56.

The trench structure 54 preferably includes the n-type high-concentration impurity region 57 having a higher n-type impurity concentration than the polysilicon 56 within the polysilicon 56. The high-concentration impurity region 57 is preferably formed at the surface layer portion of the polysilicon 56 at an interval from the bottom wall of the trench 55. The high-concentration impurity region 57 is preferably formed at an interval from the middle portion of the depth range of the trench 55 to the opening side of the trench 55.

The high-concentration impurity region 57 preferably forms a concentration gradient that gradually decreases from the inner portion of the polysilicon 56 toward the peripheral portion within the trench 55. The high-concentration impurity region 57 preferably contains a different type of n-type impurity from the n-type impurity of the polysilicon 56.

The semiconductor device 1A preferably includes the interlayer insulating film 33 covering the first main surface 3, and the cathode via electrodes 62 (via electrodes) electrically connected to the polysilicon 56 within the interlayer insulating film 33. The cathode via electrodes 62 are preferably mechanically and electrically connected to the polysilicon 56 at intervals from the second semiconductor region 59. The cathode via electrodes 62 preferably have no mechanical connection to the second semiconductor region 59. The cathode via electrodes 62 preferably form ohmic contact with the high-concentration impurity region 57.

The semiconductor device 1A preferably includes the cathode wiring 64 electrically connected to the cathode via electrodes 62 on the interlayer insulating film 33. The semiconductor device 1A preferably includes the p-type contact region 60 formed at the surface layer portion of the first main surface 3 at an interval from the trench structure 54. The contact region 60 preferably has a p-type impurity concentration higher than the p-type impurity concentration of the first semiconductor region 6.

The contact region 60 preferably extends in a strip shape along the trench structure 54 in plan view. The contact region 60 is preferably formed in an annular shape surrounding the trench structure 54 in plan view. The semiconductor device 1A preferably includes the anode via electrodes 63 (via electrodes) electrically connected to the contact region 60 within the interlayer insulating film 33. The semiconductor device 1A preferably includes the anode wiring 65 electrically connected to the anode via electrodes 63 on the interlayer insulating film 33.

The semiconductor device 1A preferably includes the light receiving region 9 provided in the first main surface 3, and the second region isolation structure 50 electrically isolating the light receiving region 9 from other regions. In this case, the trench structure 54 is formed in the light receiving region 9. Further, the second semiconductor region 59 is formed along the wall surface of the trench structure 54 in the light receiving region 9.

The semiconductor device 1A may include the CMIS region 8 (transistor region) provided in the first main surface 3. In this case, the light receiving region 9 is provided in a region different from the CMIS region 8 in the first main surface 3. The CMIS region 8 may include the second planar gate structure 25 (planar gate structure), the n-type second drain region 29 (drain region), and the n-type second source region 31 (source region).

The second planar gate structure 25 is arranged on the first main surface 3. The second drain region 29 is formed in a region on one side of the second planar gate structure 25 in the surface layer portion of the first main surface 3. The second source region 31 is formed in a region on the other side of the second planar gate structure 25 in the surface layer portion of the first main surface 3.

The polysilicon 56 may have an n-type impurity concentration lower than the n-type impurity concentration of the second drain region 29 (the second source region 31). The second semiconductor region 59 may have an n-type impurity concentration lower than the n-type impurity concentration of the second drain region 29 (the second source region 31). The high-concentration impurity region 57 may have an n-type impurity concentration higher than the n-type impurity concentration of the second drain region 29 (the second source region 31).

The second planar gate structure 25 includes the second gate insulating film 26 (gate insulating film) arranged on the first main surface 3, and the second gate electrode 27 (gate electrode) arranged on the second gate insulating film 26. The second gate electrode 27 preferably includes conductive polysilicon. In this case, the polysilicon 56 preferably has an impurity concentration different from that of the second gate electrode 27.

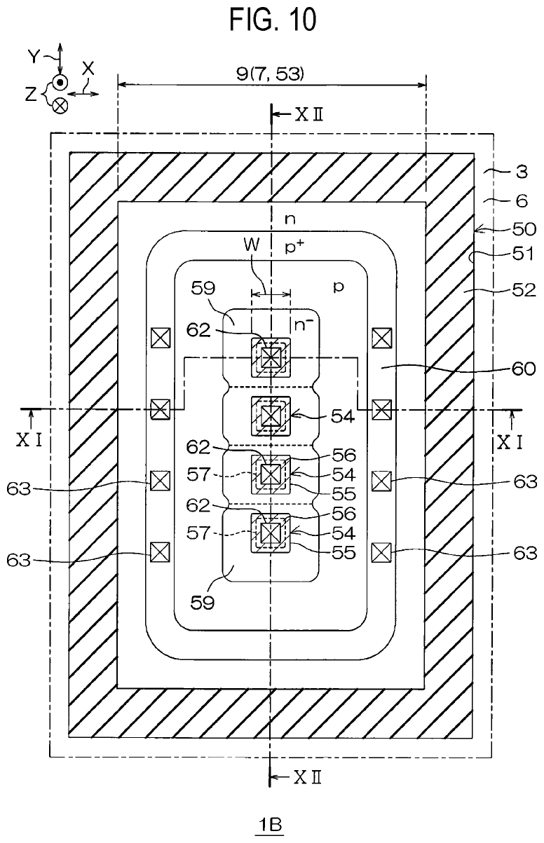

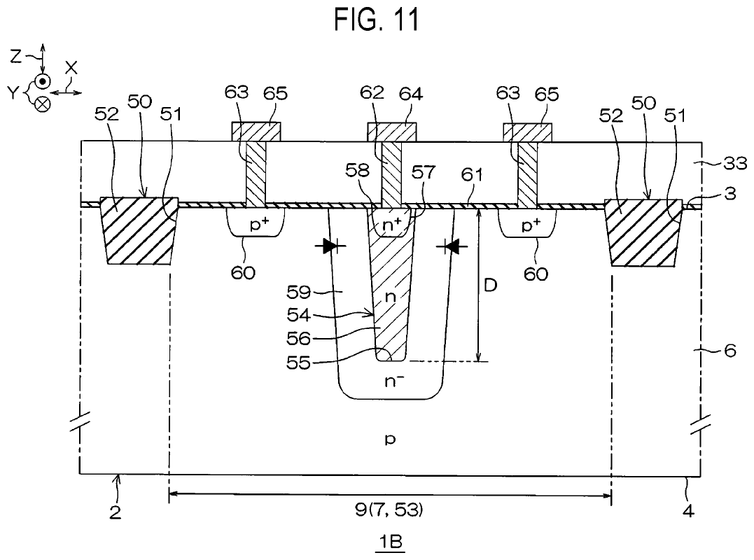

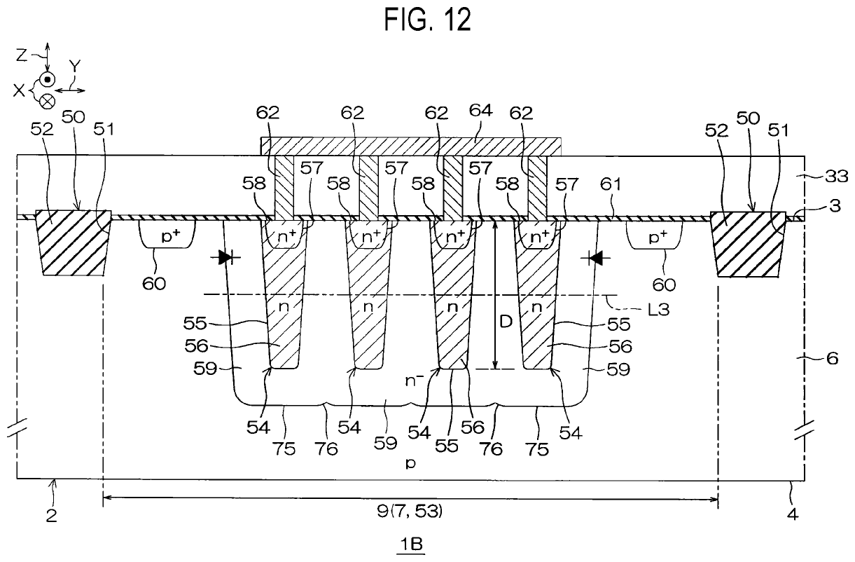

FIG. 10 is a plane view showing a light receiving region 9 of a semiconductor device 1B according to a second embodiment. FIG. 11 is a cross-sectional view taken along line XI-XI in FIG. 10. FIG. 12 is a cross-sectional view taken along line XII-XII in FIG. 10. Referring to FIGS. 10 to 12, the semiconductor device 1B includes a plurality of trench structures 54 arranged in the first main surface 3 at intervals in the light receiving region 9.

The plurality of trench structures 54 may be arranged at intervals in the first direction X or the second direction Y. In this embodiment, the plurality of trench structures 54 are arranged at intervals in the second direction Y. The number of trench structures 54 may be two or more, and is not limited to a specific number. In this embodiment, as an example, four trench structures 54 are provided.

The plurality of trench structures 54 are preferably arranged at equal intervals. The plurality of trench structures 54 may be arranged at unequal intervals. In this embodiment, each trench structure 54 is formed in a square shape in plan view. The plurality of trench structures 54 may be formed in a polygonal, circular, or elliptical shape in plan view. Others, the configuration of each trench structure 54 is the same as in the case of the first embodiment. The configurations according to the first to fourth modification examples may be applied to each trench structure 54.

The semiconductor device 1B includes a plurality of second semiconductor regions 59 formed within the chip 2 along the wall surfaces of the plurality of trench structures 54 in the light receiving region 9. The plurality of second semiconductor regions 59 are formed in a one-to-one correspondence with the plurality of trench structures 54. Each second semiconductor region 59 is formed along the sidewall and the bottom wall of the corresponding trench structure 54 when viewed in cross section, and is exposed from the first main surface 3 on the opening side of the trench structure 54.

As in the first embodiment, the plurality of second semiconductor regions 59 are regions (diffusion regions) formed by diffusing an n-type impurity (pentavalent elements) into the first semiconductor region 6 using the polysilicon 56 of the corresponding trench structure 54 as a solid-phase diffusion source. The second semiconductor regions 59 form pn junctions along the sidewalls and the bottom wall of the corresponding trench structure 54.

The depth position of each pn junction with respect to the first main surface 3 is adjusted by the trench depth D of each trench structure 54. The plurality of trench structures 54 preferably have the same trench depths D. A plurality of trench depths D can be appropriately adjusted according to the wavelength band of incident light to be detected, and the plurality of trench structures 54 may have different trench depths D. In this case, the detection sensitivity of incident light can be adjusted for each trench structure 54.

The plurality of second semiconductor regions 59 are each formed in an annular shape (in this embodiment, a square annular shape) surrounding the wall surface of the corresponding trench structure 54 in plan view. In this embodiment, the plurality of second semiconductor regions 59 are connected in a region between the plurality of adjacent trench structures 54. As a result, a single second semiconductor region 59 collectively enclosing the plurality of trench structures 54 is formed in the surface layer portion of the first main surface 3.

A portion of each second semiconductor region 59 along the sidewall of the corresponding trench structure 54 is inclined with respect to the first main surface 3 to extend along the sidewall of the trench structure 54. When the sidewall of the trench structure 54 is formed perpendicular to the first main surface 3, each second semiconductor region 59 may extend perpendicular to the first main surface 3. A portion of each second semiconductor region 59 along the bottom wall of the corresponding trench structure 54 extends parallel to the bottom wall of the trench structure 54. When the bottom wall of the trench structure 54 is formed in an arc shape, each second semiconductor region 59 may be curved in an arc shape along the bottom wall.

In this embodiment, the plurality of second semiconductor regions 59 form a plurality of bulging portion 75 and a plurality of recessed portions 76 in a region below the plurality of trench structures 54. The plurality of bulging portions 75 are formed along the bottom walls of the plurality of trench structures 54, respectively. The plurality of bulging portions 75 bulge in an arc shape toward the second main surface 4 side. Each bulging portion 75 is formed wider than the width of the trench 55 of the corresponding trench structure 54.

A plurality of recessed portions 76 are portions formed by connecting the shallow portions of the plurality of bulging portions 75 to each other, and are respectively formed in regions between the plurality of trench structures 54. The plurality of recessed portions 76 are located on the first main surface 3 side with respect to the deepest portions of the plurality of bulging portions 75. The plurality of second semiconductor regions 59 may be connected such that the plurality of bulging portions 75 and the plurality of recessed portions 76 are not formed.

The plurality of second semiconductor regions 59 are mechanically and electrically connected to the polysilicon 56 over the entire region of the wall surfaces of the corresponding trench structures 54. Each second semiconductor region 59 includes a portion facing the high-concentration impurity region 57 via a portion of the polysilicon 56 at the opening end (the surface layer portion of the first main surface 3) of the corresponding trench structure 54, and is electrically connected to the high-concentration impurity region 57 via the portion of the polysilicon 56. Each second semiconductor region 59 is connected to the polysilicon 56 in a region on the bottom wall side of the trench structure 54 corresponding to the bottom of the high-concentration impurity region 57.

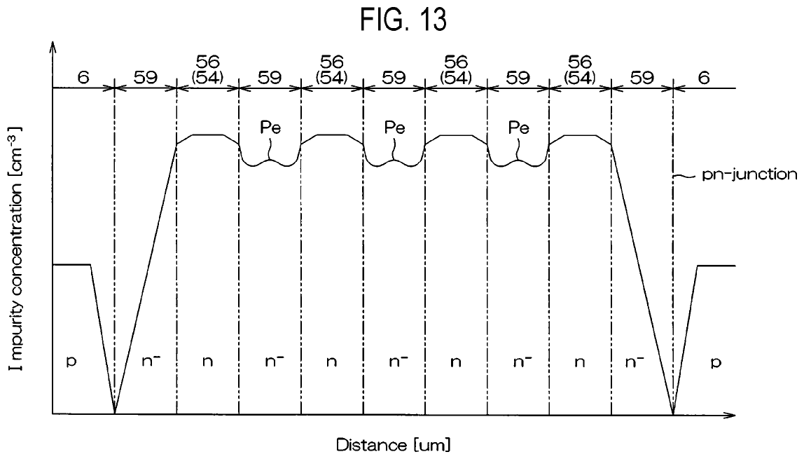

FIG. 13 is a graph showing a concentration gradient along a third line L3 in FIG. 12. Referring to FIG. 12, the third line L3 is a virtual line set in the horizontal direction (the first direction X) across the middle portion of the thickness range of the plurality of trench structures 54 to pass through the plurality of trench structures 54 (the polysilicon 56), the plurality of second semiconductor regions 59, and the plurality of first semiconductor regions 6.

In FIG. 13, the vertical axis indicates an impurity concentration [cm⁻³], and the horizontal axis indicates a distance [μm] in the second direction Y. Here, the concentration gradients of the plurality of second semiconductor regions 59 are specifically shown. The descriptions according to FIGS. 8A and 8B are applied to the concentration gradient in each trench structure 54.

Referring to FIG. 13, each of the plurality of second semiconductor regions 59 has a concentration gradient that gradually decreases starting from the wall surface of the corresponding trench structure 54 (the peripheral portion 56b of the polysilicon 56). The n-type impurity concentration of each of the plurality of second semiconductor regions 59 monotonously decreases from the wall surface of the trench structure 54 (the peripheral portion 56b of the polysilicon 56).

In portions of the plurality of second semiconductor regions 59 covering the sidewalls of the corresponding trench structures 54, the n-type impurity concentration gradually decreases along the horizontal direction starting from the sidewalls. On the other hand, in portions of the plurality of second semiconductor regions 59 covering the bottom walls of the corresponding trench structures 54, the n-type impurity concentration gradually decreases to the thickness of the chip 2 starting from the bottom wall.

A concentration gradient in which the n-type impurity concentration turns from decreasing to increasing is formed at a connection portion between the plurality of second semiconductor regions 59. As a result, a peak value Pe of the n-type impurity concentration is formed in a region between the plurality of trench structures 54. The peak value Pe is formed by the n-type impurity diffused from the polysilicon 56 on one side and the n-type impurity diffused from the poly silicon 56 on the other side overlapping in a region between the adjacent trench structures 54.

In this embodiment, the peak value Pe is lower than the n-type impurity concentration of the polysilicon 56. The peak value Pe may be adjusted to be higher than the n-type impurity concentration of the polysilicon 56. The peak value Pe is adjusted according to the interval between the plurality of trench structures 54, the n-type impurity concentration of the polysilicon 56, the conditions of thermal diffusion process, and the like. The adjustment of the peak value Pe contributes to adjustment of the electrical characteristics of the pn junction (photodiode).

Referring again to FIGS. 9A to 9D and 10, in this embodiment, the aforementioned contact region 60 is formed in an annular shape collectively surrounding the plurality of trench structures 54 and the plurality of second semiconductor regions 59 in plan view. As a result, the contact region 60 faces the plurality of trench structures 54 and the plurality of second semiconductor regions 59 in the horizontal direction with a portion of the first semiconductor region 6 interposed therebetween.

The aforementioned plurality of cathode via electrodes 62 are connected to the plurality of polysilicons 56, respectively. In this embodiment, a single cathode via electrode 62 is connected to each polysilicon 56 in a one-to-one correspondence. A plurality of cathode via electrodes 62 may be connected to each polysilicon 56.

In this embodiment, the aforementioned cathode wiring 64 is connected to the plurality of cathode via electrodes 62 over the interlayer insulating film 33. As a result, the cathode wiring 64 is electrically connected to the plurality of trench structures 54 (the plurality of polysilicons 56) via the plurality of cathode via electrodes 62. A plurality of cathode wirings 64 may be connected to the plurality of cathode via electrodes 62. That is, the plurality of cathode wirings 64 may be electrically connected to the plurality of trench structures 54 (the plurality of polysilicons 56) via the plurality of cathode via electrodes 62.

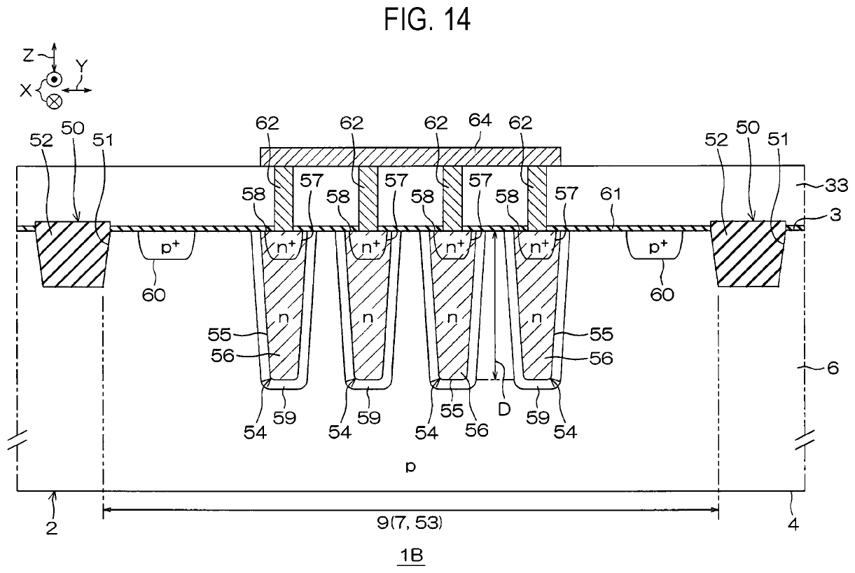

FIG. 14 is a cross-sectional view showing a modification example of the second semiconductor region 59 according to the second embodiment. In the second embodiment, an example in which the plurality of second semiconductor regions 59 are connected to each other is shown. However, as shown in FIG. 14, the plurality of second semiconductor regions 59 may be formed at intervals from each other in a region between the plurality of adjacent trench structures 54.

In this case, the plurality of second semiconductor regions 59 face each other with a portion of the first semiconductor region 6 interposed therebetween in the region between the plurality of adjacent trench structures 54. That is, the plurality of second semiconductor regions 59 also form pn junctions in the region between the plurality of adjacent trench structures 54. In this case, the aforementioned peak value Pe (see FIG. 13) is not formed in the region between the plurality of trench structures 54.

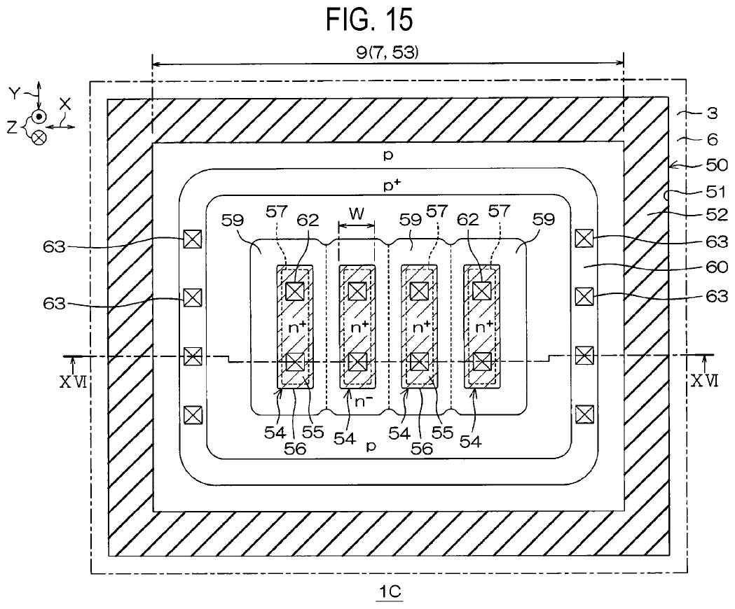

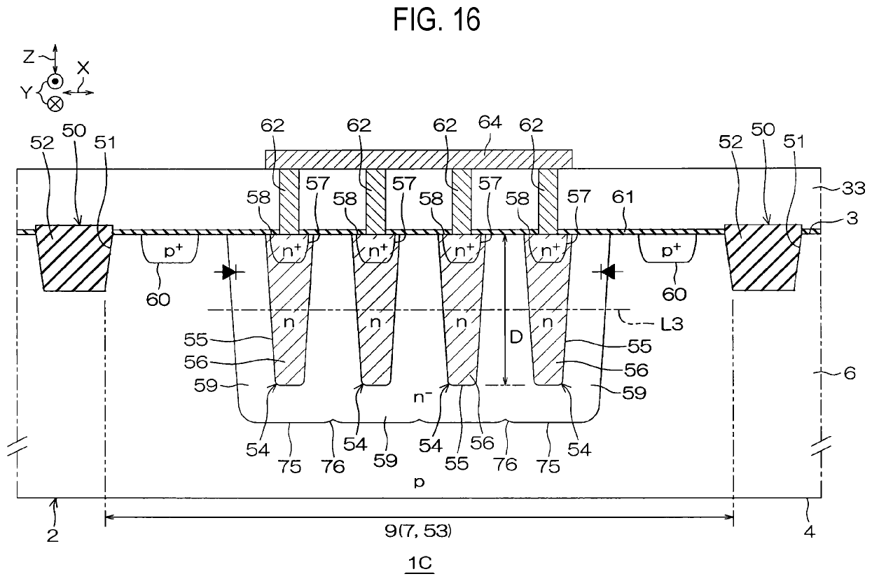

FIG. 15 is a plane view showing a light receiving region 9 of a semiconductor device 1C according to a third embodiment. FIG. 16 is a cross-sectional view taken along line XVI-XVI in FIG. 15. Referring to FIGS. 15 and 16, like the semiconductor device 1B, the semiconductor device 1C includes a plurality of trench structures 54 arranged in the first main surface 3 at intervals in the light receiving region 9. The plurality of trench structures 54 may be arranged at intervals in the first direction X or the second direction Y.

In this embodiment, the plurality of trench structures 54 are arranged at intervals in the first direction X and are formed in a strip shape extending in the second direction Y. The plurality of trench structures 54 may be arranged at intervals in the second direction Y and may be formed in a strip shape extending in the first direction X.

The number of trench structures 54 may be two or more, and is not limited to a specific number. In this embodiment, as an example, four trench structures 54 are provided. Others, the configuration of each trench structure 54 is the same as in the first and second embodiments. The configurations according to the first to fourth modification examples may be applied to each trench structure 54.

As in the case of the second embodiment, the semiconductor device 1C includes a plurality of second semiconductor regions 59 formed within the chip 2 along the wall surfaces of the plurality of trench structures 54 in the light receiving region 9. The plurality of second semiconductor regions 59 are formed in an annular shape (in this embodiment, a rectangular annular shape) surrounding the wall surfaces of the corresponding trench structures 54 in plan view, respectively. Others, the configuration of each second semiconductor region 59 is the same as in the first and second embodiments (see also FIGS. 10 to 14).

The aforementioned plurality of cathode via electrodes 62 are connected to the plurality of polysilicons 56, respectively. In this embodiment, the plurality of cathode via electrodes 62 are connected to each polysilicon 56 in a one-to-many correspondence. A single cathode via electrode 62 may be connected to each polysilicon 56.

In this embodiment, the aforementioned cathode wiring 64 is connected to the plurality of cathode via electrodes 62 over the interlayer insulating film 33. As a result, the cathode wiring 64 is electrically connected to the plurality of trench structures 54 (the plurality of polysilicons 56) via the plurality of cathode via electrodes 62. A plurality of cathode wirings 64 may be connected to the plurality of cathode via electrodes 62. That is, the plurality of cathode wirings 64 may be electrically connected to the plurality of trench structures 54 (the plurality of polysilicons 56) via the plurality of cathode via electrodes 62.

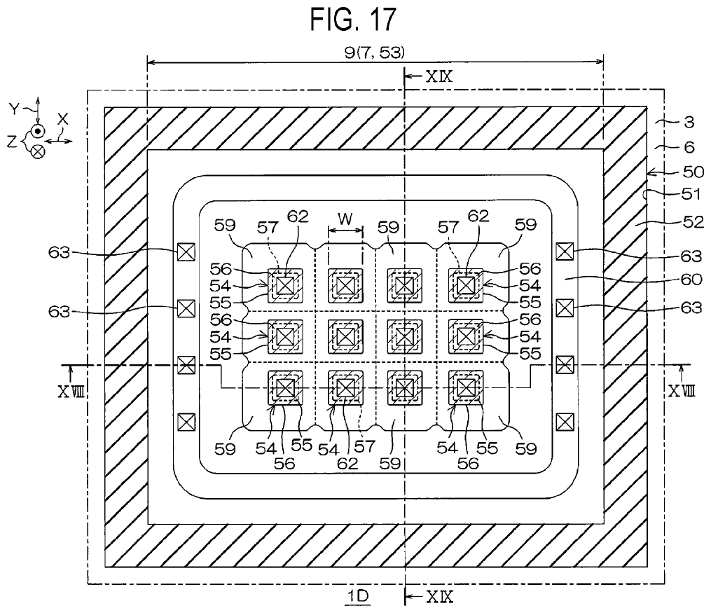

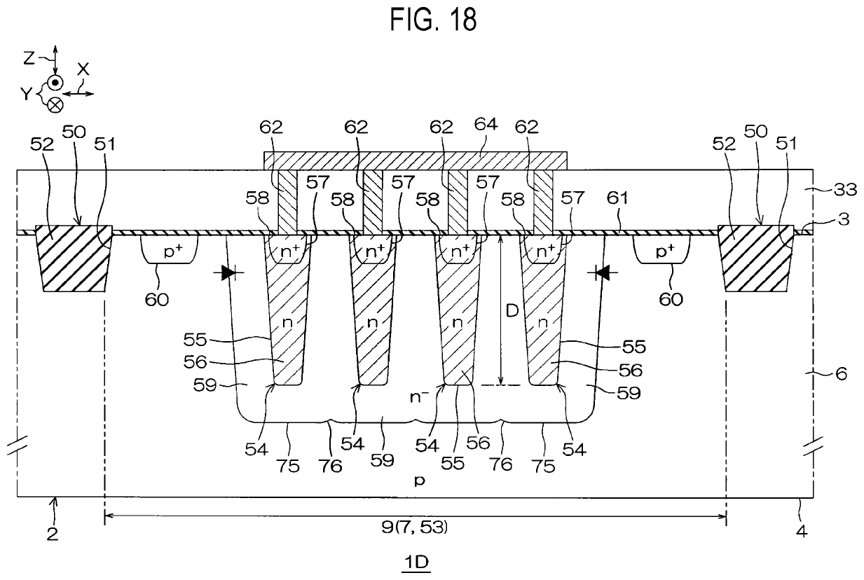

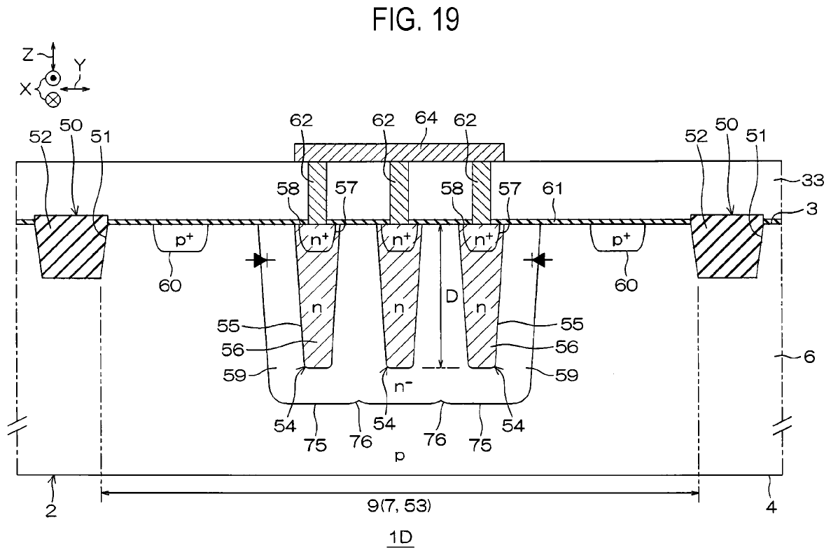

FIG. 17 is a plane view showing a light receiving region 9 of a semiconductor device 1D according to a fourth embodiment. FIG. 18 is a cross-sectional view taken along line XVIII-XVIII in FIG. 17. FIG. 19 is a cross-sectional view taken along line XIX-XIX in FIG. 17. The semiconductor device 1D includes a form in which the configuration of the semiconductor device 1B and the configuration of the semiconductor device 1C are combined.

Referring to FIGS. 17 to 19, the semiconductor device 1D includes a plurality of trench structures 54 arranged in the first main surface 3 at intervals in the first direction X and the second direction Y in the light receiving region 9. In this embodiment, the plurality of trench structures 54 are arranged in the form of a matrix at intervals in the first direction X and the second direction Y so that crossroads are defined in the first main surface 3 in plan view.

In the matrix-formed layout, the plurality of trench structures 54 arranged in the first direction X face the other plurality of trench structures 54 in the second direction Y in plan view. Further, the plurality of trench structures 54 arranged in the second direction Y face the other plurality of trench structures 54 in the first direction X in plan view.

The plurality of trench structures 54 may be arranged in a zigzag pattern in the first direction X and the second direction Y so that T-junctions are defined in the first main surface 3 in plan view. In the zigzag-patterned layout, the plurality of trench structures 54 arranged in the first direction X may face regions between the other plurality of trench structures 54 in the second direction Y in plan view. Further, the plurality of trench structures 54 arranged in the second direction Y may face regions between the other plurality of trench structures 54 in the first direction X in plan view.

As in the second and third embodiments, the semiconductor device 1D includes a plurality of second semiconductor regions 59 formed within the chip 2 along the wall surfaces of the plurality of trench structures 54 in the light receiving region 9. The plurality of second semiconductor regions 59 are formed in an annular shape (in this embodiment, a rectangular annular shape) surrounding the wall surfaces of the corresponding trench structures 54 in plan view, respectively.

That is, the plurality of second semiconductor regions 59 are formed in the surface layer portion of the first main surface 3 to be spaced apart from each other or connected to each other along the first direction X and the second direction Y, corresponding to the arrangement of the plurality of trench structures 54. Others, the configuration of each second semiconductor region 59 is the same as in the first to third embodiments (see also FIGS. 10 to 14).

The aforementioned plurality of cathode via electrodes 62 are connected to the plurality of polysilicons 56, respectively. In this embodiment, a single cathode via electrode 62 is connected to each polysilicon 56 in a one-to-one correspondence. A plurality of cathode via electrodes 62 may be connected to each polysilicon 56.

In this embodiment, the aforementioned cathode wiring 64 is connected to the plurality of cathode via electrodes 62 over the interlayer insulating film 33. As a result, the cathode wiring 64 is electrically connected to the plurality of trench structures 54 (the plurality of polysilicons 56) via the plurality of cathode via electrodes 62. A plurality of cathode wirings 64 may be connected to the plurality of cathode via electrodes 62. That is, the plurality of cathode wirings 64 may be electrically connected to the plurality of trench structures 54 (the plurality of polysilicons 56) via the plurality of cathode via electrodes 62.

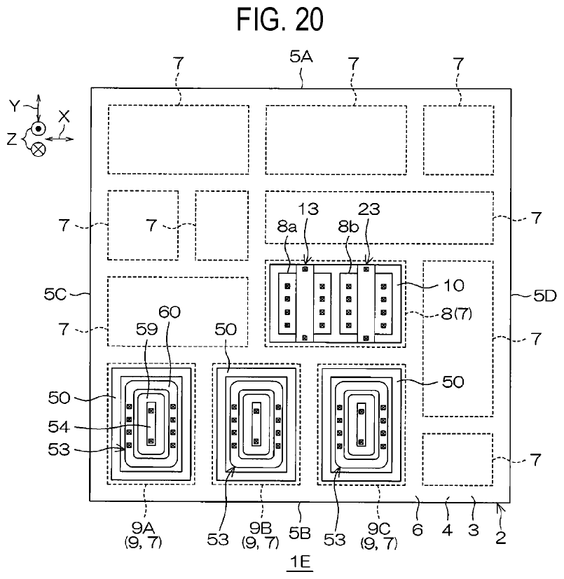

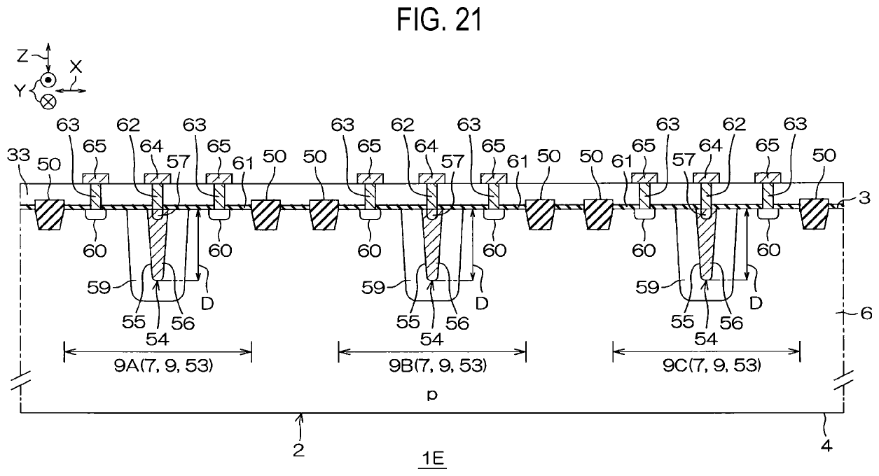

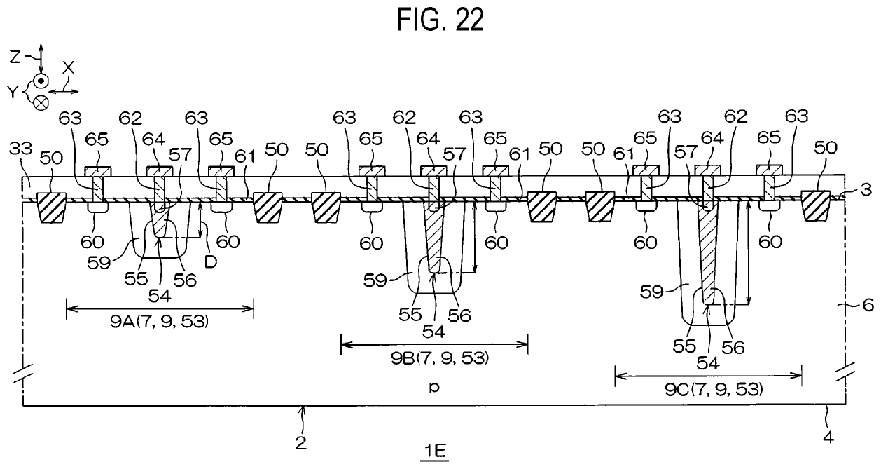

FIG. 20 is a plane view showing a semiconductor device 1E according to a fifth embodiment. FIG. 21 is a cross-sectional view showing a main part of the semiconductor device 1E of FIG. 20. FIG. 22 is a cross-sectional view showing a modification example of the light receiving region 9 according to the fifth embodiment.

The semiconductor device 1E includes a plurality of light receiving regions 9. In this embodiment, the plurality of light receiving regions 9 are provided in the first main surface 3 to be adjacent to each other at the peripheral portion of the first main surface 3. The plurality of light receiving regions 9 are arbitrary and may be provided in the inner portion of the first main surface 3. Further, at least one of the plurality of light receiving regions 9 may be interposed in a region between other circuit device regions 7 so as not to be adjacent to other light receiving regions 9.

Each light receiving region 9 is electrically isolated from other regions by the aforementioned second region isolation structure 50. Each light receiving region 9 may be any one of the light receiving regions 9 according to the first to fourth embodiments. That is, the plurality of light receiving regions 9 may include the same internal structure, or may include different internal structures.

The plurality of light receiving regions 9 may be regions for detecting incident light in different wavelength bands. Each light receiving region 9 may be a region for detecting incident light having any one wavelength band selected from ultraviolet light, blue light, green light, yellow light, red light, and infrared light. For example, the plurality of light receiving regions 9 may include a first light receiving region 9A for detecting incident light of a first wavelength, a second light receiving region 9B for detecting incident light of a second wavelength smaller than the first wavelength, and a third light receiving region 9C for detecting incident light of a third wavelength smaller than the second wavelength.

Referring to FIG. 22, the plurality of light receiving regions 9 may include a plurality of trench structures 54 having different trench depths D. That is, the plurality of trench structures 54 may be formed in the plurality of light receiving regions 9 with different trench depths D. The plurality of trench depths D may be adjusted according to the wavelength band of incident light to be detected.

The first light receiving region 9A may include a trench structure 54 having a relatively small trench depth D. The second light receiving region 9B may include a trench structure 54 having a trench depth D larger than the trench depth D on the first light receiving region 9A side. The third light receiving region 9C may include a trench structure 54 having a trench depth D larger than the trench depth D on the second light receiving region 9B side.

According to these configurations, second semiconductor regions 59 (pn junctions) having different depths can be formed along trench structures 54 having different trench depths D. Therefore, incident light in different wavelength bands can be appropriately detected by the plurality of light receiving regions 9.

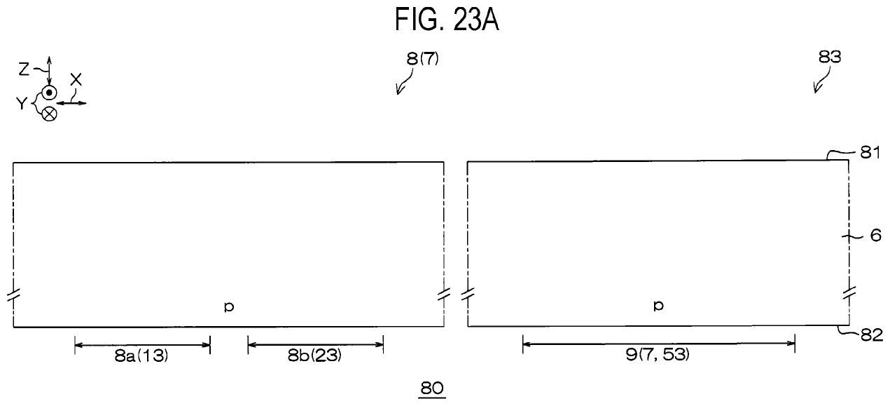

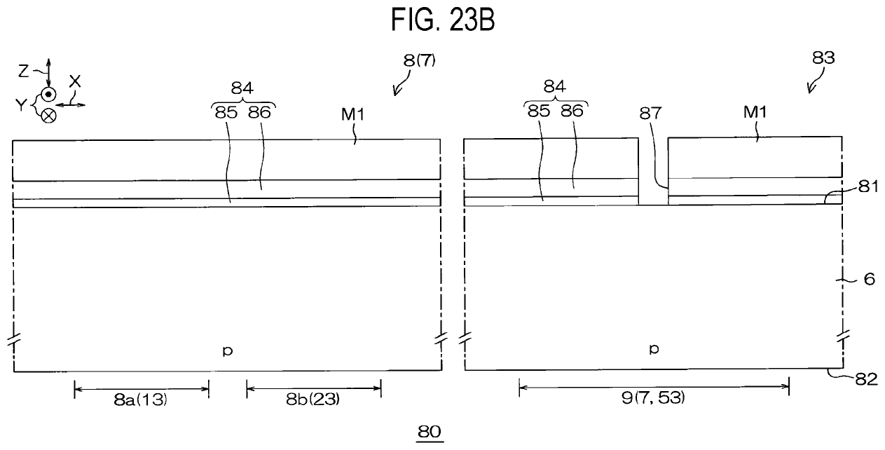

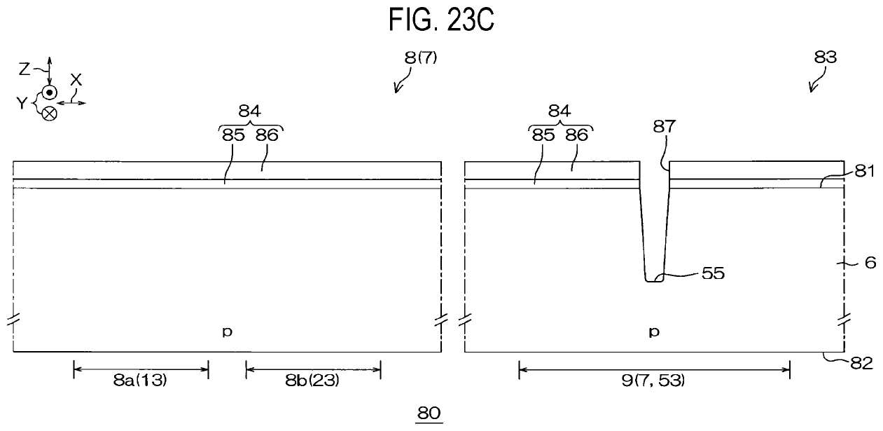

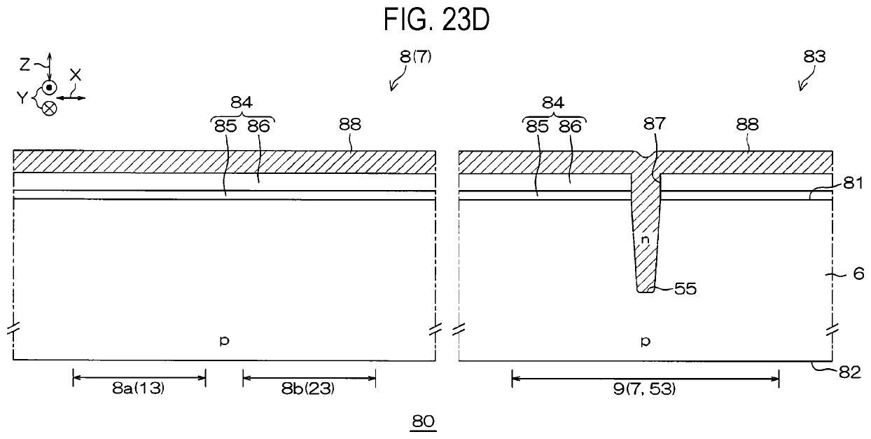

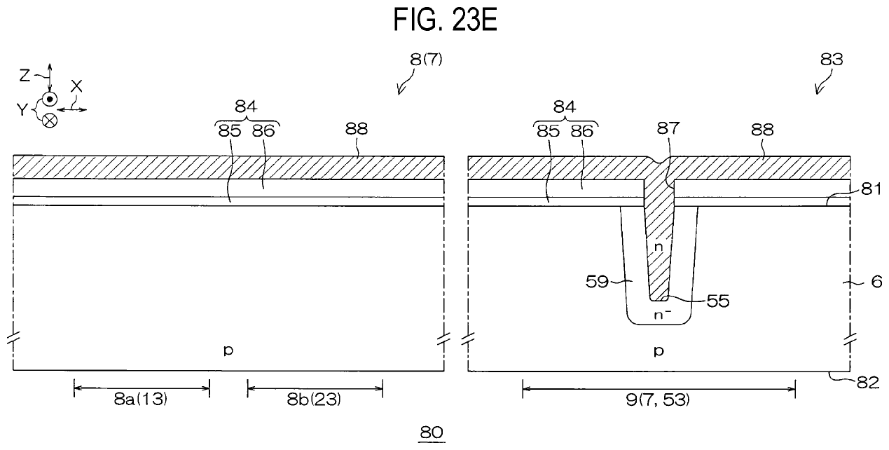

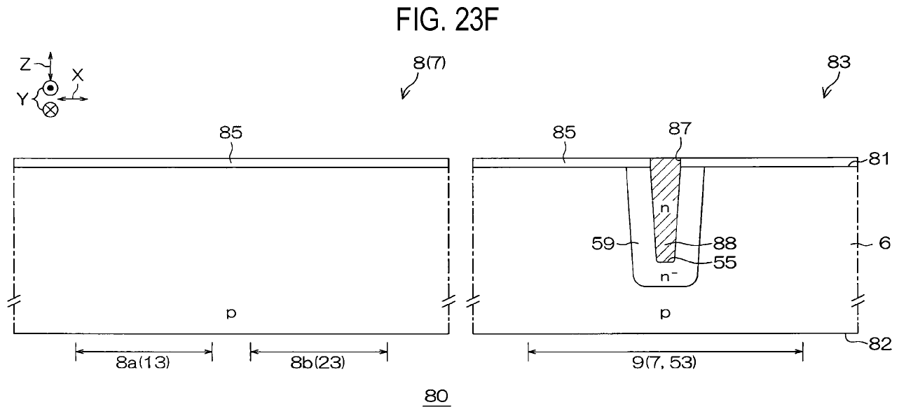

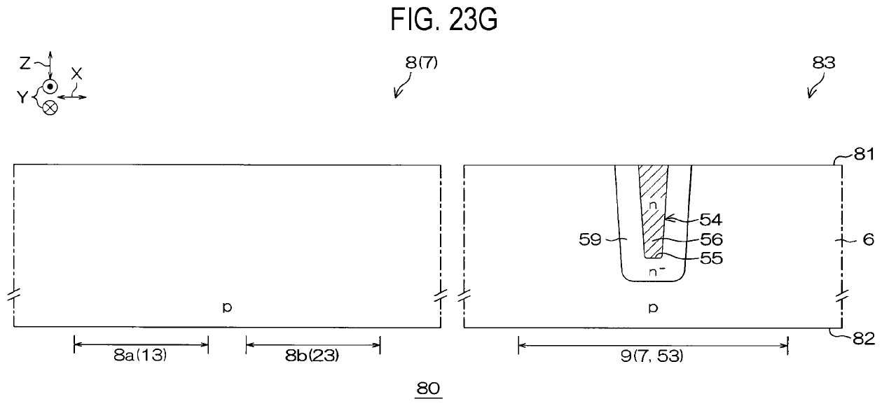

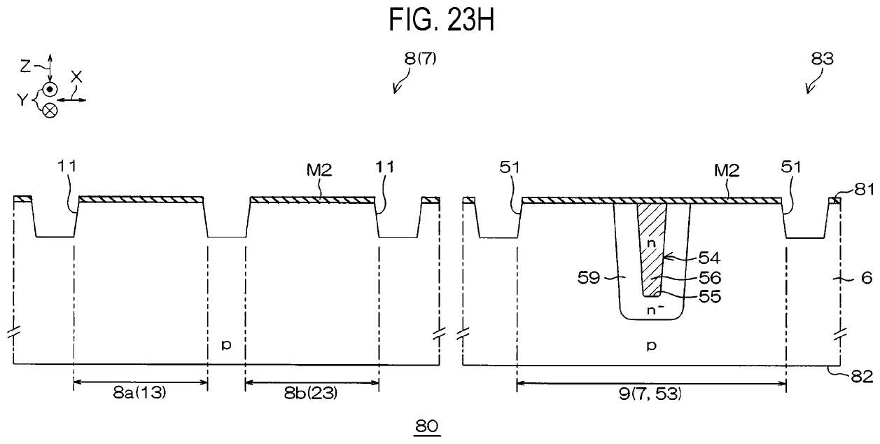

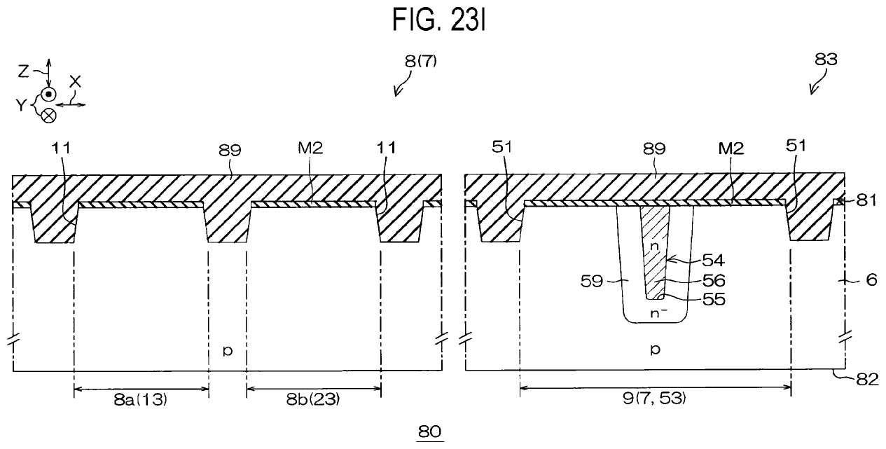

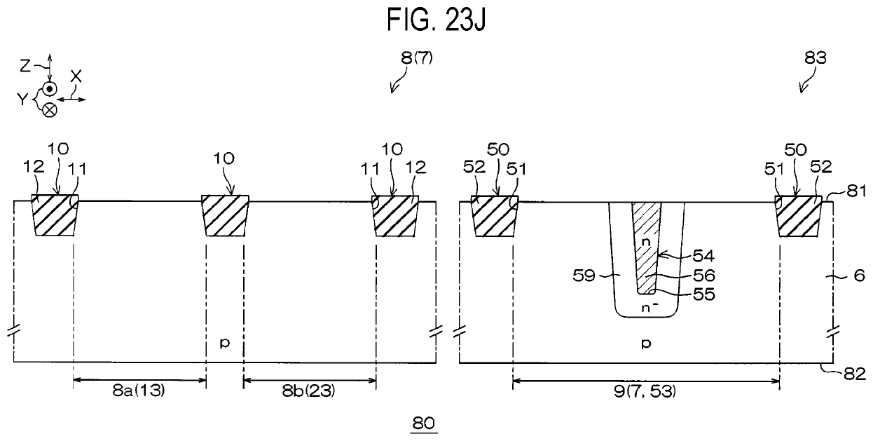

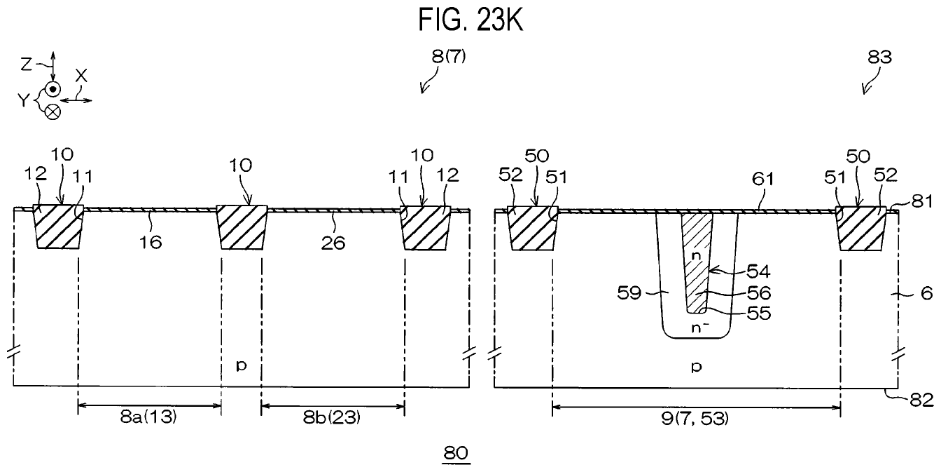

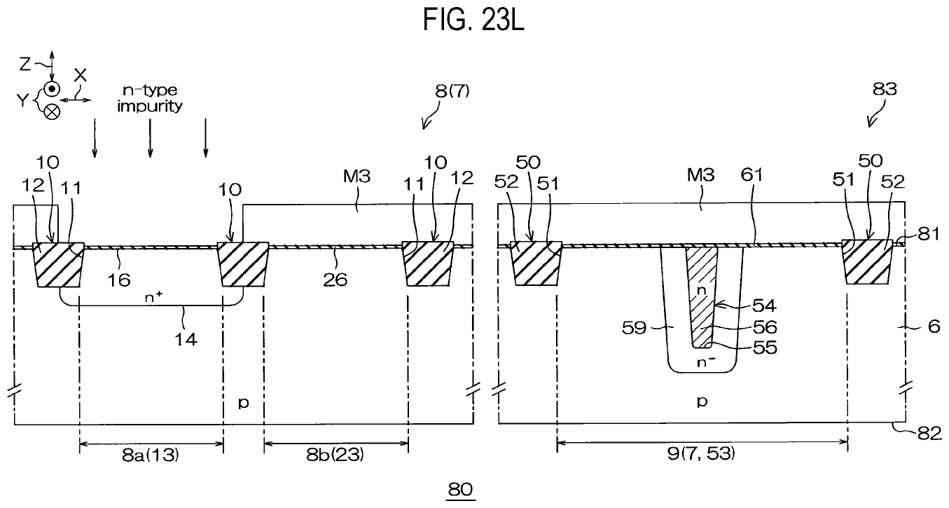

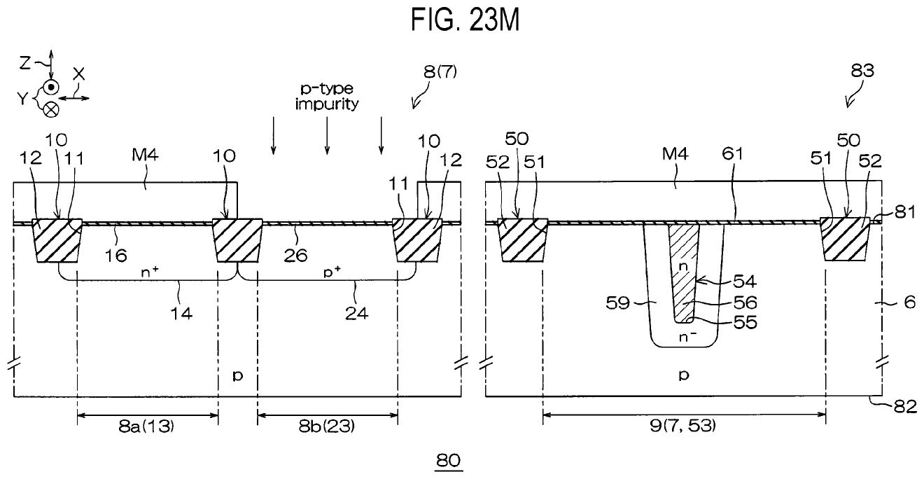

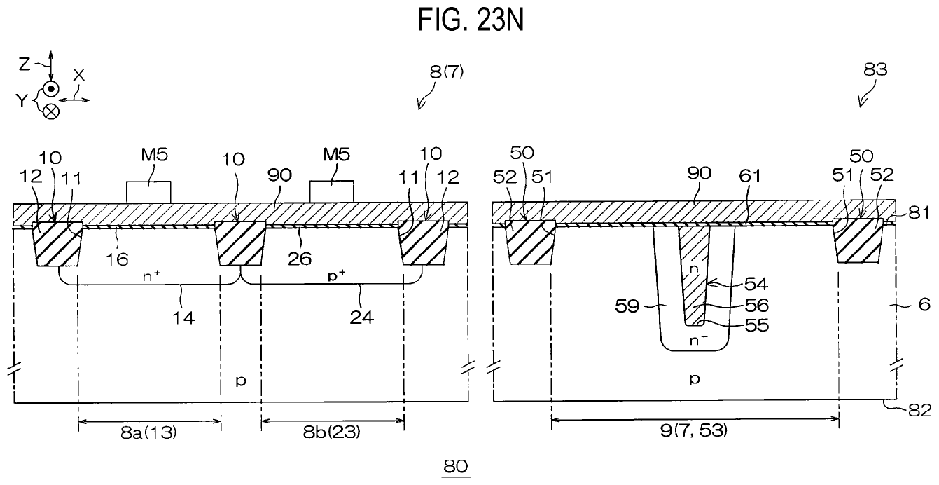

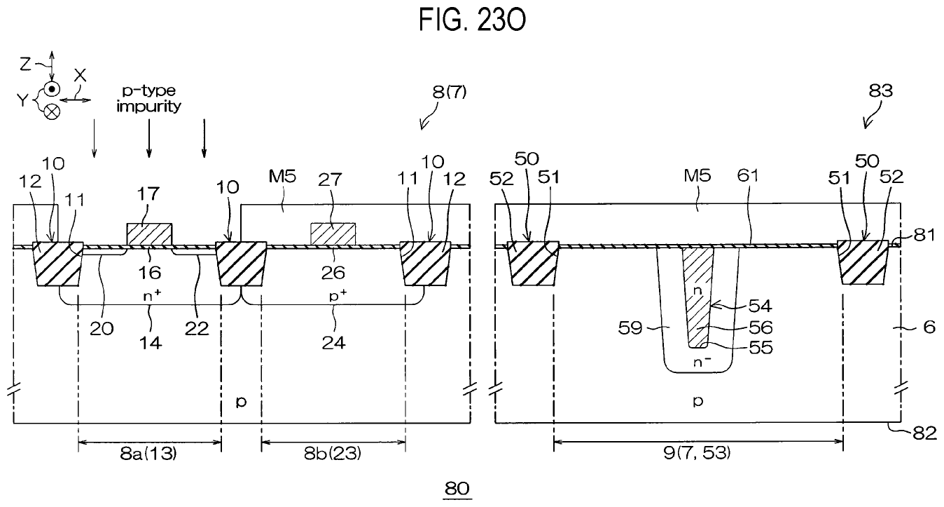

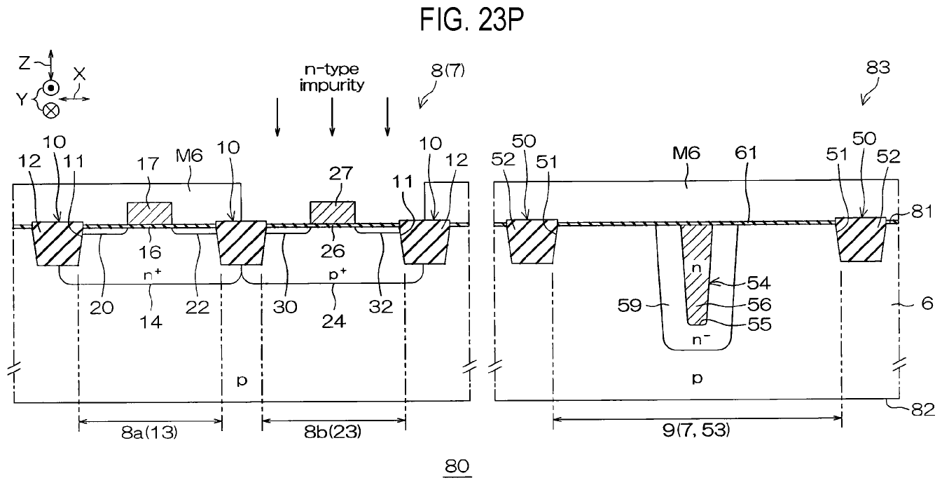

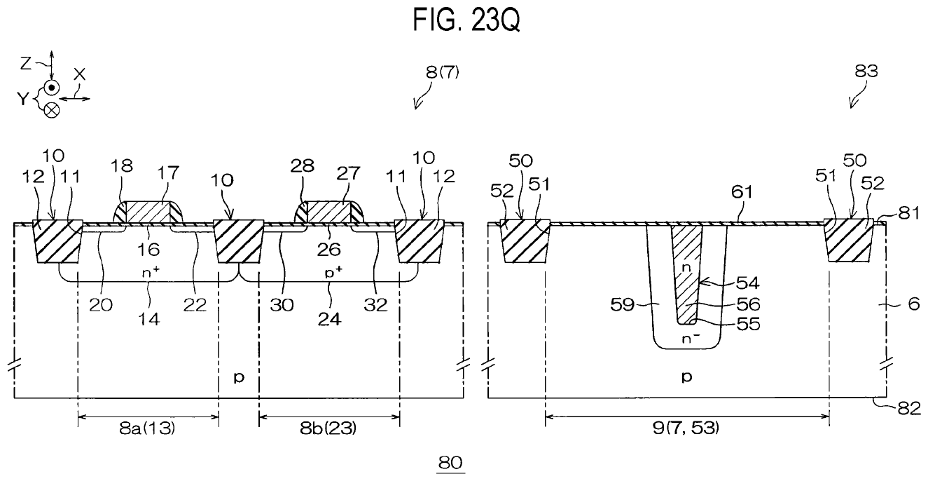

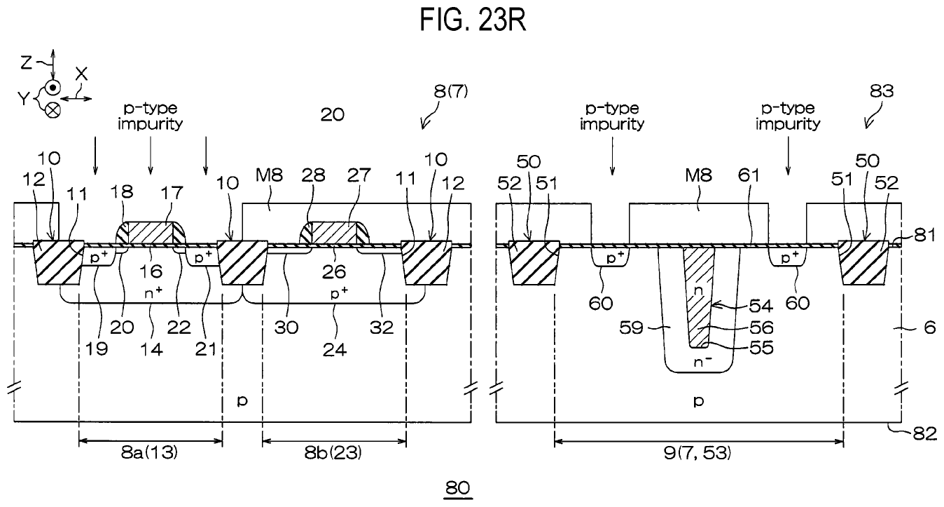

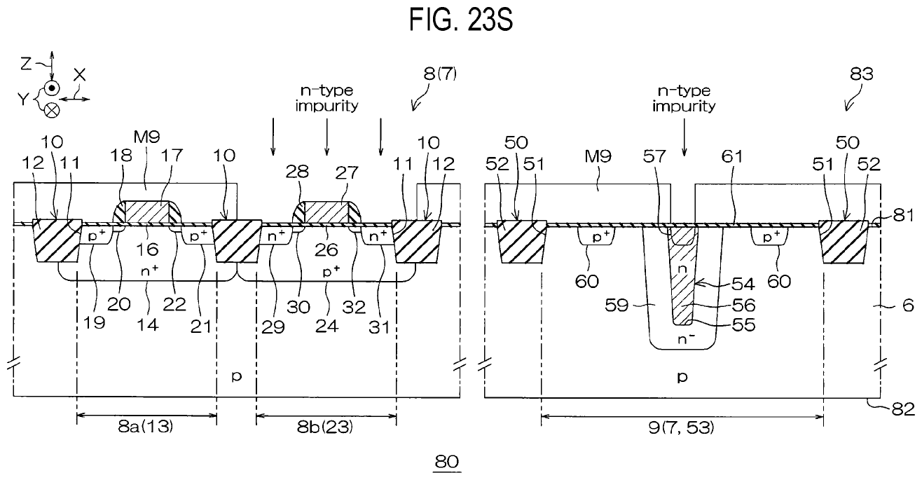

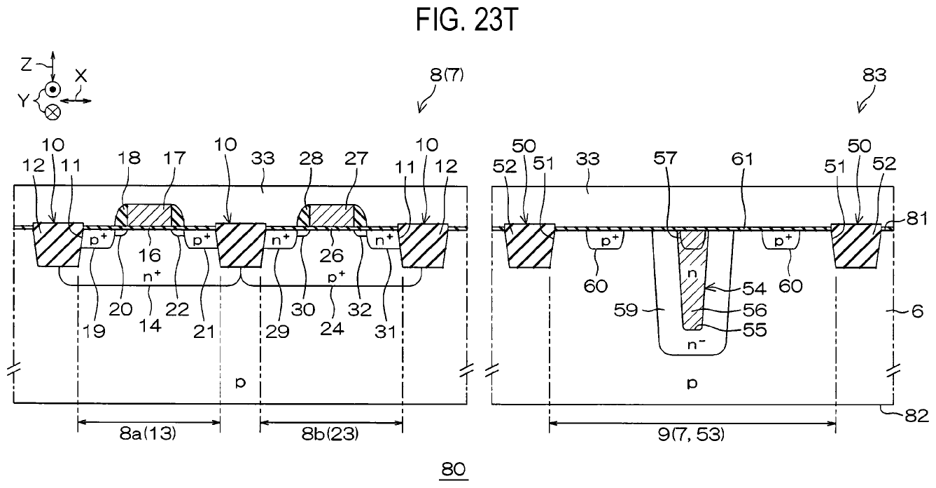

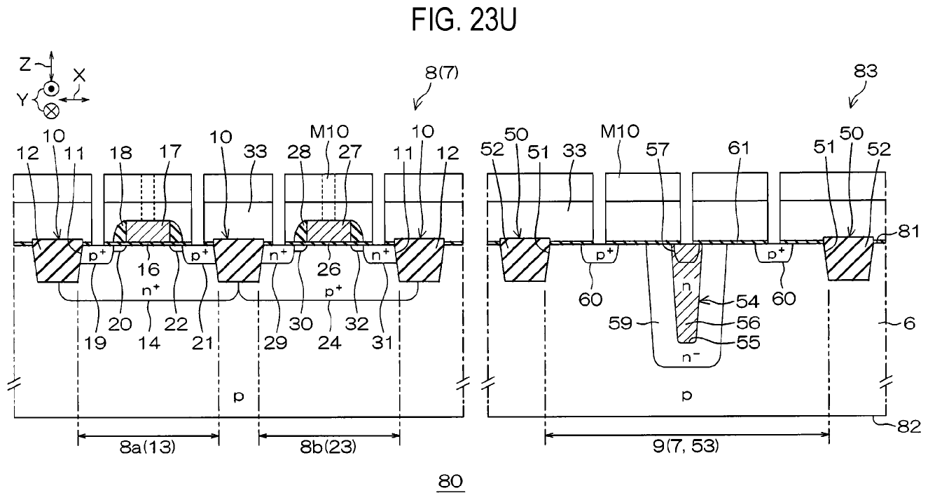

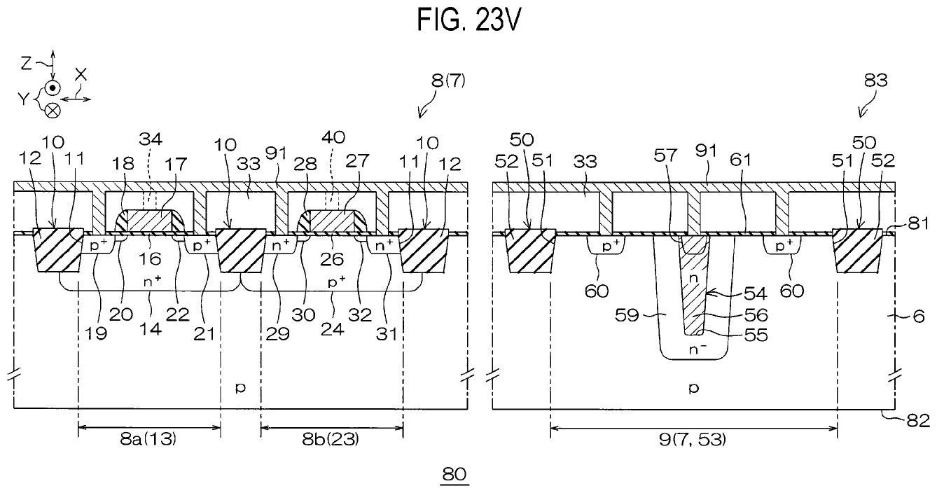

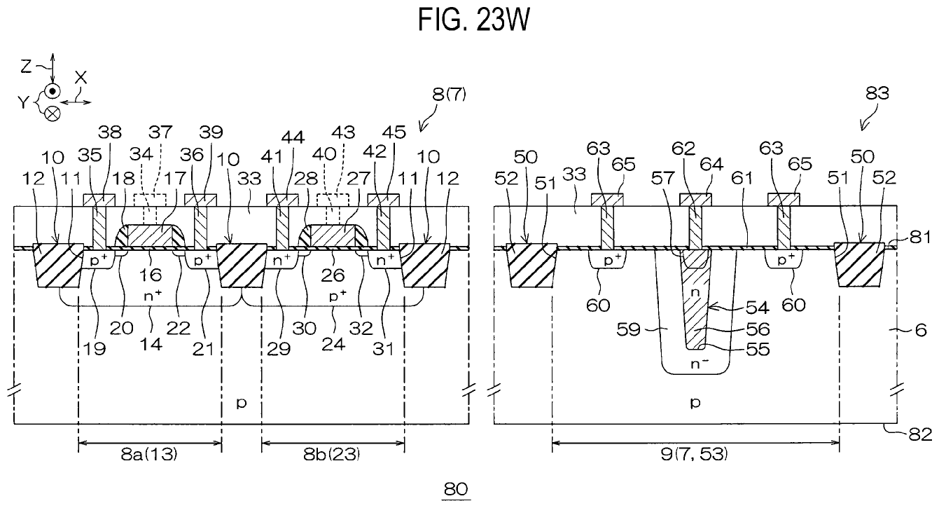

An example of a manufacturing method applied to the semiconductor devices 1A to 1E is shown below. FIGS. 23A to 23W are cross-sectional views showing an example of a method of manufacturing the semiconductor devices 1A to 1E. In the following, a method of manufacturing the semiconductor device 1A is illustrated. The semiconductor devices 1B to 1E are obtained by changing the layout of various masks and adjusting the number and layout of the trench structures 54 in the method of manufacturing the semiconductor device 1A.

Referring to FIG. 23A, a plate-shaped (for example, disc-shaped or polygonal plate-shaped) wafer 80 (in this embodiment, a silicon wafer) is prepared as a base of the chip 2. The wafer 80 includes a first wafer main surface 81 on one side and a second wafer main surface 82 on the other side. The first wafer main surface 81 and the second wafer main surface 82 correspond to the first main surface 3 and the second main surface 4 of the chip 2, respectively.

The wafer 80 includes a first semiconductor region 6 therein. The first semiconductor region 6 is formed in at least the surface layer portion of the first wafer main surface 81 within the wafer 80. The first semiconductor region 6 is preferably exposed from the first wafer main surface 81. In this embodiment, the first semiconductor region 6 is formed over the entire thickness range of the wafer 80 and is exposed from the first wafer main surface 81 and the second wafer main surface 82.

Specifically, the first semiconductor region 6 is formed in the form of a layer extending along the first wafer main surface 81 and the second wafer main surface 82 over the entire region of the wafer 80. In this embodiment, the wafer 80 includes a single-layer structure consisting of a p-type semiconductor wafer, and the first semiconductor region 6 is formed using the p-type semiconductor wafer.

Next, a plurality of device formation regions 83 respectively corresponding to the semiconductor devices 1A (the semiconductor devices 1B to 1E) are set in the wafer 80 (the first wafer main surface 81). For example, the plurality of device formation regions 83 are set in the form of a matrix along the first direction X and the second direction Y. Each device formation region 83 includes a plurality of circuit device regions 7.

The plurality of circuit device regions 7 include at least one CMIS region 8 and at least one light receiving region 9. In FIGS. 23A to 23W, the CMIS region 8 is shown on the left side of the paper, and the light receiving region 9 is shown on the right side of the paper. The CMIS region 8 includes a first MIS region 8a and a second MIS region 8b.

Next, referring to FIG. 23B, an inorganic mask 84 is formed on the first wafer main surface 81. A forming step of the inorganic mask 84 includes a step of forming the inorganic mask 84 made of a material different from that of the wafer 80. Specifically, the forming step of the inorganic mask 84 includes a step of forming an inorganic film having an etching rate different from that of the wafer 80 on the first wafer main surface 81. In this embodiment, the forming step of the inorganic mask 84 includes a forming step of a first inorganic insulating film 85 and a forming step of a second inorganic insulating film 86.

The forming step of the first inorganic insulating film 85 includes a step of forming the first inorganic insulating film 85 covering the first wafer main surface 81. The first inorganic insulating film 85 may be a silicon oxide film. The first inorganic insulating film 85 may be formed by a CVD (Chemical Vapor Deposition) method and/or an oxidation treatment method (for example, a thermal oxidation treatment method). In the oxidation treatment method, the first inorganic insulating film 85 is formed by oxidation treatment on the first wafer main surface 81.

The forming step of the second inorganic insulating film 86 includes a step of forming the second inorganic insulating film 86 covering the first inorganic insulating film 85. The second inorganic insulating film 86 includes an insulator different from that of the first inorganic insulating film 85. The second inorganic insulating film 86 may be a silicon nitride film. The second inorganic insulating film 86 may be formed by a CVD method. The second inorganic insulating film 86 is preferably formed thicker than the first inorganic insulating film 85. The inorganic mask 84 may include a single-layer structure consisting of the first inorganic insulating film 85 or the second inorganic insulating film 86.

Next, a first mask M1 having a predetermined pattern is formed on the inorganic mask 84. For example, the first mask M1 is a resist mask (organic mask). The first mask M1 has a layout that exposes a region where a trench 55 is to be formed in the light receiving region 9 and covers the other regions.

Next, unnecessary portions of the second inorganic insulating film 86 are removed by an etching method through the first mask M1. The etching method may be a dry etching method and/or a wet etching method. Next, unnecessary portions of the first inorganic insulating film 85 are removed by an etching method through the first mask M1. The etching method may be a dry etching method and/or a wet etching method. As a result, the inorganic mask 84 having at least one (in this embodiment, one) opening 87 that exposes the region where the trench 55 is to be formed is formed over the first wafer main surface 81. After that, the first mask M1 is removed.

Next, referring to FIG. 23C, unnecessary portions of the first wafer main surface 81 are removed by an etching method through the inorganic mask 84. As a result, the trench 55 having a layout corresponding to the layout of the opening 87 is formed in a portion of the first wafer main surface 81 exposed through the opening 87. The etching method may be a dry etching method and/or a wet etching method. When the trench 55 having a relatively large trench depth D is formed, the trench 55 may be formed by the Bosch process.

Next, referring to FIG. 23D, an n-type polysilicon layer (polysilicon) 88 is formed to fill the trench 55 and covers the inorganic mask 84. The polysilicon layer 88 is deposited in the form of a film along the wall surface of the trench 55 and the outer surface of the inorganic mask 84. The polysilicon layer 88 is laminated until portions covering both sidewalls of the trench 55 are integrated in the inner portion of the trench 55 when viewed in cross section. For example, the polysilicon layer 88 may be formed by a CVD method using an n-type impurity (pentavalent element) as a dopant. The CVD method may be a low-pressure CVD method and/or a plasma CVD method.

Next, referring to FIG. 23E, a portion of the polysilicon layer 88 located inside the trench 55 is used as a solid-phase diffusion source for n-type impurity to diffuse the n-type impurity in the polysilicon layer 88 into the first semiconductor region 6 by a thermal diffusion method. As a result, an n-type second semiconductor region 59 is formed in the first semiconductor region 6 along the wall surface of the trench 55. The second semiconductor region 59 forms a pn junction, as a photodiode, with the first semiconductor region 6.

A portion of the polysilicon layer 88 located outside the trench 55 faces the first wafer main surface 81 with the inorganic mask 84 interposed therebetween. Therefore, the inorganic mask 84 functions as a barrier film that suppresses diffusion of the n-type impurity in the polysilicon layer 88 from the first wafer main surface 81 side into the first semiconductor region 6.

As a result, the second semiconductor region 59 is formed which extends in the form of a layer along the wall surface of the trench 55 and does not include a portion drawn in the form of a layer in the horizontal direction in the surface layer portion of the first wafer main surface 81. A detailed description of the configuration of the second semiconductor region 59 formed in this step is omitted because it is the same as the above-described first to fourth embodiments.

A relatively large heat load is applied to the wafer 80 in a forming step of the second semiconductor region 59 having the n-type impurity diffusion region over a relatively deep and relatively wide range. Therefore, by performing the forming step of the second semiconductor region 59 before a forming step of other semiconductor regions (structures in the CMIS region 8, etc.), unwanted diffusion of impurities into other semiconductor regions due to the thermal diffusion step of the second semiconductor region 59 can be avoided. For example, the second semiconductor region 59 is preferably an impurity region formed first in a semiconductor process performed on the wafer 80.

On the other hand, the diffusion range of the n-type impurity in the second semiconductor region 59 caused by the thermal diffusion step of other impurity regions can be adjusted in advance by back calculation. Therefore, the thermal diffusion step of the second semiconductor region 59 preferably includes a step of limiting (stopping on the way) the diffusion range of the n-type impurity in consideration of the diffusion range caused by the heat load in the subsequent steps. According to this method, through a series of steps, the second semiconductor region 59 can be properly formed, and at the same time, other semiconductor regions can also be properly formed.

Next, referring to FIG. 23F, the portion of the polysilicon layer 88 covering the inorganic mask 84 is removed. The polysilicon layer 88 may be removed by a grinding method and/or an etching method. The grinding method may be a CMP (Chemical Mechanical Polishing) method. The etching method may be a dry etching method and/or a wet etching method. When the polysilicon layer 88 is removed by the etching method, the polysilicon layer 88 is removed using the second inorganic insulating film 86 as an etching stop layer.

Next, the second inorganic insulating film 86 is removed. The second inorganic insulating film 86 may be removed by a grinding method and/or an etching method. The grinding method may be a CMP method. The etching method may be a dry etching method and/or a wet etching method. When the second inorganic insulating film 86 is removed by the etching method, the second inorganic insulating film 86 is removed using the first inorganic insulating film 85 as an etching stop layer. When the polysilicon layer 88 is removed by the grinding method, the second inorganic insulating film 86 may be removed simultaneously with the polysilicon layer 88 using the grinding method for the polysilicon layer 88.

Next, referring to FIG. 23G, the first inorganic insulating film 85 is removed. The first inorganic insulating film 85 may be removed by a grinding method and/or an etching method. The grinding method may be a CMP method. The etching method may be a dry etching method and/or a wet etching method. When the first inorganic insulating film 85 is removed by the etching method, the first inorganic insulating film 85 is removed using the wafer 80 as an etching stop layer. As a result, the trench structure 54 including the polysilicon 56 buried within the trench 55 is formed.

When the second inorganic insulating film 86 is removed by the grinding method, the first inorganic insulating film 85 may be removed simultaneously with the polysilicon layer 88 using the grinding method for the second inorganic insulating film 86. When the polysilicon layer 88 is removed by the grinding method, the second inorganic insulating film 86 may be removed simultaneously with the polysilicon layer 88 using the grinding method for the polysilicon layer 88.

For example, the above-described configuration of FIG. 7 is obtained by performing a grinding method on the first wafer main surface 81, the inorganic mask 84 (the second inorganic insulating film 86), and the polysilicon layer 88. For example, the above-described configuration of FIG. 9A is obtained by removing the inorganic mask 84 (the laminated film including the first inorganic insulating film 85 and the second inorganic insulating film 86, or the single-layer film consisting of the second inorganic insulating film 86) by an etching method while a portion of the polysilicon layer 88 remains in the opening 87. For example, the above-described configuration of FIG. 9B is obtained by removing the polysilicon layer 88 by an etching method until the etching surface of the polysilicon layer 88 is located closer to the bottom wall side of the trench 55 than the first wafer main surface 81.

The above-described diffusion step of the second semiconductor region 59 may be performed after the removing step of the inorganic mask 84 (see FIG. 23G) (that is, after forming the trench structure 54). The above-described diffusion step of the second semiconductor region 59 may be performed during the removing step of the inorganic mask 84. That is, the above-described diffusion step of the second semiconductor region 59 may be performed between the removing step of the first inorganic insulating film 85 (see FIG. 23F) and the removing step of the second inorganic insulating film 86 (see FIG. 23G).

Next, referring to FIG. 23H, a second mask M2 having a predetermined pattern is formed on the first wafer main surface 81. For example, the second mask M2 is a hard mask (inorganic mask). The second mask M2 may include at least one of a silicon oxide film and a silicon nitride film. The second mask M2 has a layout that exposes a region where the first isolation trench 11 and the second isolation trench 51 are to be formed in the light receiving region 9, and covers the other regions.

Next, unnecessary portions of the first wafer main surface 81 are removed by an etching method through the second mask M2. The etching method may be a dry etching method and/or a wet etching method. As a result, the first isolation trench 11 and the second isolation trench 51 are formed in the first wafer main surface 81.

Next, referring to FIG. 23I, a base insulating film 89 is formed to fill the first isolation trench 11 and the second isolation trench 51 and cover the first wafer main surface 81. The base insulating film 89 may include at least one of a silicon oxide film and a silicon nitride film. The base insulating film 89 preferably includes an insulator different from that of the second mask M2. For example, the base insulating film 89 may be formed by a CVD method.

Next, referring to FIG. 23J, a portion of the base insulating film 89 covering the second mask M2 is removed. The base insulating film 89 may be removed by a grinding method and/or an etching method. The grinding method may be a CMP method. The etching method may be a dry etching method and/or a wet etching method.

Next, the second mask M2 is removed. The second mask M2 may be removed by a grinding method and/or an etching method. The grinding method may be a CMP method. The etching method may be a dry etching method and/or a wet etching method. As a result, the first region isolation structure 10 and the second region isolation structure 50 are formed.

When the base insulating film 89 is removed by the grinding method, the second mask M2 may be removed simultaneously with the base insulating film 89 using the grinding method for the base insulating film 89. In this case, the first buried insulator 12 with no protruding portion and the second buried insulator 52 with no protruding portion are formed.

That is, the end portion of the first buried insulator 12 is formed to be flush with the first wafer main surface 81 (the upper end portion 58 of the polysilicon 56), and the end portion of the second buried insulator 52 is formed to be flush with the first wafer main surface 81 (the upper end portion 58 of the polysilicon 56). The end portion of the first buried insulator 12 forms one ground surface with the first wafer main surface 81, and the end portion of the second buried insulator 52 forms one ground surface with the first wafer main surface 81.

Next, referring to FIG. 23K, a first gate insulating film 16 is formed on the first wafer main surface 81 in the first MIS region 8a. The first gate insulating film 16 may be a silicon oxide film. In this case, the forming step of the first gate insulating film 16 may include an oxidation treatment step (for example, a thermal oxidation treatment step) on the first wafer main surface 81. The first gate insulating film 16 may be formed by a CVD method.

Further, a second gate insulating film 26 is formed on the first wafer main surface 81 in the second MIS region 8b. The second gate insulating film 26 may be a silicon oxide film. In this case, the forming step of the second gate insulating film 26 may include an oxidation treatment step (for example, a thermal oxidation treatment step) on the first wafer main surface 81. The second gate insulating film 26 may be formed by a CVD method.

Further, a main surface insulating film 61 is formed on the first wafer main surface 81 in the light receiving region 9. The main surface insulating film 61 may be a silicon oxide film. In this case, the forming step of the main surface insulating film 61 may include an oxidation treatment step (for example, a thermal oxidation treatment step) on the first wafer main surface 81. The main surface insulating film 61 may be formed by a CVD method.

When the oxidation treatment step is performed, the main surface insulating film 61 includes a silicon oxide film made of oxide of the wafer 80 in a portion covering the first wafer main surface 81, and includes a silicon oxide film made of oxide of the polysilicon 56 in a portion covering the polysilicon 56. The forming step of the first gate insulating film 16, the forming step of the second gate insulating film 26, and the forming step of the main surface insulating film 61 may be performed simultaneously. The forming step of the first gate insulating film 16, the forming step of the second gate insulating film 26, and the forming step of the main surface insulating film 61 may be performed separately.

Next, referring to FIG. 23L, a third mask M3 having a predetermined pattern is formed on the first wafer main surface 81. The third mask M3 is a resist mask (organic mask) as an ion implantation mask. The third mask M3 exposes the first wafer main surface 81 of the first MIS region 8a and covers the other regions.

Next, an n-type impurity is introduced into the surface layer portion of the first wafer main surface 81 of the first MIS region 8a by an ion implantation method through the third mask M3. After that, the third mask M3 is removed, and the first well region 14 is formed through thermal diffusion of the n-type impurity. The diffusion step of the first well region 14 may include a diffusion step of the n-type impurity of the polysilicon 56 and a diffusion step of the n-type impurity of the second semiconductor region 59.

Next, referring to FIG. 23M, a fourth mask M4 having a predetermined pattern is formed on the first wafer main surface 81. The fourth mask M4 is a resist mask (organic mask) as an ion implantation mask. The fourth mask M4 exposes the first wafer main surface 81 of the second MIS region 8b and covers the other regions.

Next, a p-type impurity is introduced into the surface layer portion of the first wafer main surface 81 of the second MIS region 8b by an ion implantation method through the fourth mask M4. After that, the fourth mask M4 is removed, and the second well region 24 is formed through thermal diffusion of the p-type impurity. The diffusion step of the second well region 24 may include a diffusion step of the n-type impurity of the polysilicon 56 and a diffusion step of the n-type impurity of the second semiconductor region 59. The diffusion step of the second well region 24 may be performed simultaneously with the diffusion step of the first well region 14. The p-type impurity introduction step of the second well region 24 may be performed before the n-type impurity introduction step of the first well region 14.

Next, referring to FIG. 23N, a gate electrode layer 90 serving as the base of the first gate electrode 17 and second gate electrode 27 is formed on the first wafer main surface 81. The gate electrode layer 90 contains polysilicon and may be formed by a CVD method.

Next, a fifth mask M5 having a predetermined pattern is formed on the gate electrode layer 90. The fifth mask M5 covers a region where the first gate electrode 17 and the second gate electrode 27 are to be formed, and exposes the other regions. Next, unnecessary portions of the gate electrode layer 90 are removed by an etching method through the fifth mask M5. As a result, the first gate electrode 17 and the second gate electrode 27 are formed. The etching method may be a dry etching method and/or a wet etching method.

Next, referring to FIG. 23O, a sixth mask M6 having a predetermined pattern is formed on the first wafer main surface 81. The sixth mask M6 is a resist mask (organic mask) as an ion implantation mask. The sixth mask M6 exposes the first wafer main surface 81 of the first MIS region 8a and covers the other regions. The sixth mask M6 also exposes the first gate electrode 17 in the first MIS region 8a.

Next, a p-type impurity is introduced into the surface layer portion of the first wafer main surface 81 of the first MIS region 8a by an ion implantation method through the sixth mask M6. Specifically, the p-type impurity is introduced into the surface layer portion of the first well region 14 and the first gate electrode 17. The p-type impurity is introduced in a self-aligned manner with respect to the sidewall of the first gate electrode 17 using the first gate electrode 17 as a mask (shield).

After that, the sixth mask M6 is removed, and the first drain surface layer region 20 and the first source surface layer region 22 are formed through thermal diffusion treatment of the p-type impurity. This diffusion step may include an n-type impurity diffusion step of the polysilicon 56 and an n-type impurity diffusion step of the second semiconductor region 59.

Next, referring to FIG. 23P, a seventh mask M7 having a predetermined pattern is formed on the first wafer main surface 81. The seventh mask M7 is a resist mask (organic mask) as an ion implantation mask. The seventh mask M7 exposes the first wafer main surface 81 of the second MIS region 8b and covers the other regions. The second MIS region 8b also exposes the second gate electrode 27 in the first MIS region 8a.

Next, an n-type impurity is introduced into the surface layer portion of the first wafer main surface 81 of the second MIS region 8b by an ion implantation method through the seventh mask M7. Specifically, the n-type impurity is introduced into the surface layer portion of the second well region 24 and the second gate electrode 27. The n-type impurity is introduced in a self-aligned manner with respect to the sidewall of the second gate electrode 27 using the second gate electrode 27 as a mask (shield).

After that, the seventh mask M7 is removed, and the second drain surface layer region 30 and the second source surface layer region 32 are formed through thermal diffusion treatment of the n-type impurity. The diffusion step of the second drain surface layer region 30 (the second source surface layer region 32) may include a diffusion step of the n-type impurity of the polysilicon 56 and a diffusion step of the n-type impurity of the second semiconductor region 59.

The diffusion step of the second drain surface layer region 30 (the second source surface layer region 32) may be performed simultaneously with the diffusion step of the first drain surface layer region 20 (the first source surface layer region 22). The n-type impurity introduction step of the second drain surface layer region 30 (the second source surface layer region 32) may be performed before the p-type impurity introduction step of the first drain surface layer region 20 (the first source surface layer region 22).

Next, referring to FIG. 23Q, a first sidewall insulating film 18 and a second sidewall insulating film 28 are formed. In this step, an insulating film (not shown) serving as the base of the first sidewall insulating film 18 and second sidewall insulating film 28 is formed on the first wafer main surface 81 to cover the first gate electrode 17 and the second gate electrode 27. The insulating film may be formed by a CVD method.

Next, unnecessary portions of the insulating film are removed by an etching method so that the insulating film partially remains in the sidewall of the first gate electrode 17 and the sidewall of the second gate electrode 27. For example, the etching method may be an anisotropic etching method (dry etching method). As a result, the first sidewall insulating film 18 and the second sidewall insulating film 28 are formed.

Next, referring to FIG. 23R, an eighth mask M8 having a predetermined pattern is formed on the first wafer main surface 81. The eighth mask M8 is a resist mask (organic mask) as an ion implantation mask. The eighth mask M8 exposes a region where the p-type first drain region 19, the p-type first source region 21, and the p-type contact region 60 are to be formed in the first MIS region 8a and the light receiving region 9, and covers the other regions. The eighth mask M8 also exposes the first gate electrode 17 and the first sidewall insulating film 18 in the first MIS region 8a.

Next, by an ion implantation method through the eighth mask M8, a p-type impurity is introduced into the surface layer portion of the first wafer main surface 81 of the first MIS region 8a, and a p-type impurity is introduced into the surface layer portion of the first wafer main surface 81 of the light receiving region 9. In the first MIS region 8a, the p-type impurity is introduced into the surface layer portion of the first well region 14 and the first gate electrode 17.

The p-type impurity is introduced in a self-aligned manner with respect to the first sidewall insulating film 18 using the first sidewall insulating film 18 as a mask (shield). In the light receiving region 9, the p-type impurity is introduced at a position at an interval from the second region isolation structure 50 and the trench structure 54 (the second semiconductor region 59) in the surface layer portion of the first wafer main surface 81.

After that, the eighth mask M8 is removed, and the first drain region 19, the first source region 21, and the contact region 60 are formed through thermal diffusion treatment of the p-type impurity. This diffusion step may include an n-type impurity diffusion step of the polysilicon 56 and an n-type impurity diffusion step of the second semiconductor region 59. The forming step of the first drain region 19, the forming step of the first source region 21, and the forming step of the contact region 60 may be performed separately in any order.

Next, referring to FIG. 23S, a ninth mask M9 having a predetermined pattern is formed on the first wafer main surface 81. The ninth mask M9 is a resist mask (organic mask) as an ion implantation mask. The ninth mask M9 exposes a region where the n-type second drain region 29, the n-type second source region 31, and the n-type high-concentration impurity region 57 are to be formed in the second MIS region 8b and the light receiving region 9, and covers the other regions. The ninth mask M9 also exposes the second gate electrode 27 and the second sidewall insulating film 28 in the second MIS region 8b. The ninth mask M9 exposes the trench structure 54 (the polysilicon 56) in the light receiving region 9.

Next, by an ion implantation method through the ninth mask M9, an n-type impurity is introduced into the surface layer portion of the first wafer main surface 81 of the second MIS region 8b, and an n-type impurity is introduced into the polysilicon 56 of the light receiving region 9. In the second MIS region 8b, the n-type impurity is introduced into the surface layer portion of the second well region 24 and the second gate electrode 27. The n-type impurity is introduced in a self-aligned manner with respect to the second sidewall insulating film 28 using the second sidewall insulating film 28 as a mask (shield). In the light receiving region 9, the n-type impurity is introduced into the upper end portion 58 (surface layer portion) of the polysilicon 56.

After that, the ninth mask M9 is removed, and the second drain region 29, the second source region 31, and the high-concentration impurity region 57 are formed through thermal diffusion treatment of the n-type impurity. This diffusion step may include an n-type impurity diffusion step of the polysilicon 56 and an n-type impurity diffusion step of the second semiconductor region 59.

The diffusion step of the second drain region 29 and the like may be performed simultaneously with the diffusion step of the first drain region 19 and the like. The n-type impurity introduction step of the second drain region 29 and the like may be performed before the p-type impurity introduction step of the first drain region 19 and the like. The forming step of the second drain region 29, the forming step of the second source region 31, and the forming step of the high-concentration impurity region 57 may be performed separately in any order. For example, the above-described configuration of FIG. 9D can be obtained by omitting the step of introducing the n-type impurity into the polysilicon layer 88 (the polysilicon 56).

Next, referring to FIG. 23T, an interlayer insulating film 33 covering the CMIS region 8 and the light receiving region 9 is formed on the first main surface 3. The interlayer insulating film 33 may include at least one of a silicon oxide film and a silicon nitride film. The interlayer insulating film 33 may be formed by a CVD method.

Next, referring to FIG. 23U, a tenth mask M10 having a predetermined pattern is formed on the interlayer insulating film 33. For example, the tenth mask M10 is a resist mask (organic mask). The tenth mask M10 exposes a region where a plurality of via openings are to be formed, and covers the other regions. Next, unnecessary portions of the interlayer insulating film 33 are removed by an etching method through the tenth mask M10. As a result, the plurality of via openings are formed in the interlayer insulating film 33. The etching method may be a dry etching method and/or a wet etching method.

Next, referring to FIG. 23V, a base electrode 91 is formed to fill the plurality of via openings and cover the interlayer insulating film 33. The n-type base electrode 91 may be formed by a sputtering method and/or a CVD method. Next, a portion of the base electrode 91 located on the interlayer insulating film 33 is removed by an etching method. As a result, the first gate via electrode 34, the first drain via electrode 35, the first source via electrode 36, the second gate via electrode 40, the second drain via electrode 41, the second source via electrode 42, the cathode via electrode 62, and the anode via electrode 63 are formed.

For example, the forming step of the silicide layer 74 may be performed prior to the forming step of the base electrode 91 or using the forming step of the base electrode 91 (see FIG. 9C). In this case, a metal film is formed to cover connection objects (the first wafer main surface 81, the first gate electrode 17, the second gate electrode 27, the polysilicon 56, etc.) within the plurality of via openings. Next, the metal film is silicided with the connection objects by a heat treatment method. The heat treatment method may be a RTA (Rapid Thermal Anneal) method. The metal film may remain as a portion of the via electrode, or may be removed by an etching method or the like.

Next, referring to FIG. 23W, a first gate wiring 37, a first drain wiring 38, a first source wiring 39, a second gate wiring 43, a second drain wiring 44, a second source wiring 45, a cathode wiring 64, and an anode wiring 65 are formed. This step includes a step of forming an electrode layer serving as a base for these wirings on the interlayer insulating film 33, and a step of removing unnecessary portions of the electrode layer by an etching method through a mask having a predetermined pattern. After that, the wafer 80 is cut along the device formation regions 83 to obtain a plurality of semiconductor devices 1A from one wafer 80.

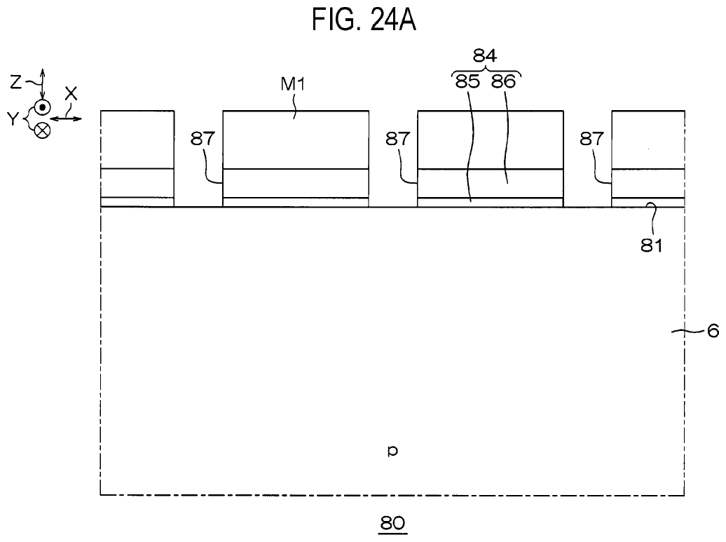

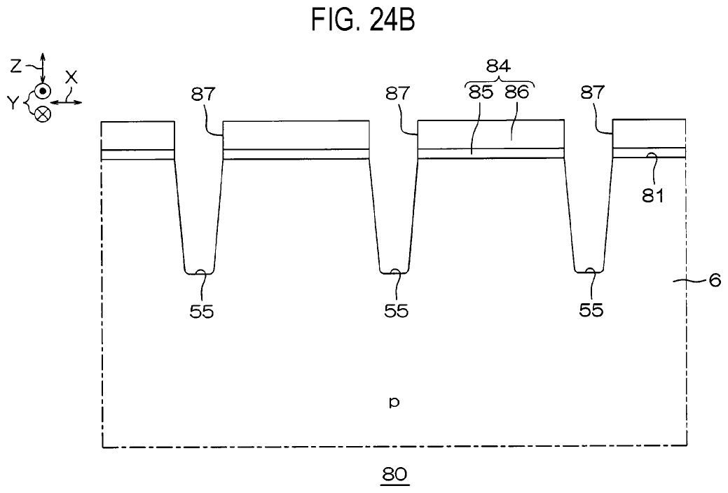

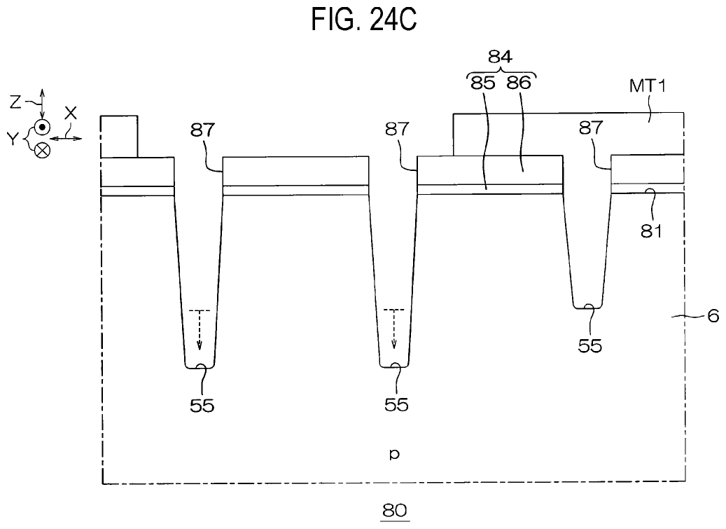

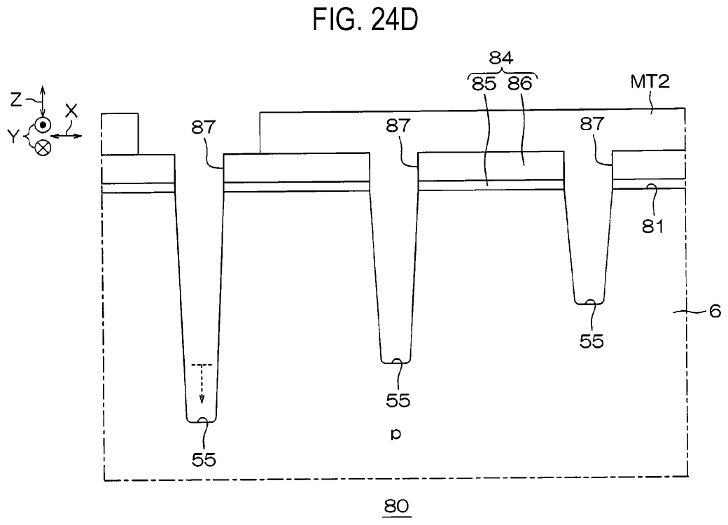

When a plurality of trenches 55 are formed, steps shown in FIGS. 24A to 24D are performed instead of the steps shown in FIGS. 23B and 23C. FIGS. 24A to 24D are schematic cross-sectional views showing an example of a forming step of the plurality of trenches 55. FIGS. 24A to 24D also show an example of the forming step of the plurality of trenches 55 having different trench depths D.

Referring to FIG. 24A, when the plurality of trenches 55 are formed, the layout of the first mask M1 according to the step of FIG. 23B is changed to form an inorganic mask 84 including a plurality of openings 87 exposing a region where the plurality of trenches 55 are to be formed.

Next, referring to FIG. 24B, unnecessary portions of the first wafer main surface 81 are removed by an etching method through the inorganic mask 84 to form the plurality of trenches 55 in the first wafer main surface 81 (see FIG. 23C). When the plurality of trench structures 54 having substantially the same trench depths D are formed, the steps after FIG. 23D may be performed after this step.

Next, referring to FIG. 24C, a first trench mask TM1 is formed on the inorganic mask 84. The first trench mask TM1 exposes any trenches 55 whose trench depth D is to be increased, and covers any trenches 55 whose trench depth D is to be maintained. Next, the trenches 55 to be etched are further dug down by an etching method through the first trench mask TM1. After that, the first trench mask TM1 is removed.

Next, referring to FIG. 24D, when the trenches 55 with different trench depths D are further formed, a second trench mask TM2 is formed on the inorganic mask 84. The second trench mask TM2 exposes any trenches 55 whose trench depth D is to be increased, and covers any trenches 55 whose trench depth D is to be maintained.

Next, the trenches 55 to be etched are further dug down by an etching method through the second trench mask TM2. After that, the second trench mask TM2 is removed. In this way, the plurality of trenches 55 having different trench depths D are formed. After this step, the steps after FIG. 23D are performed.

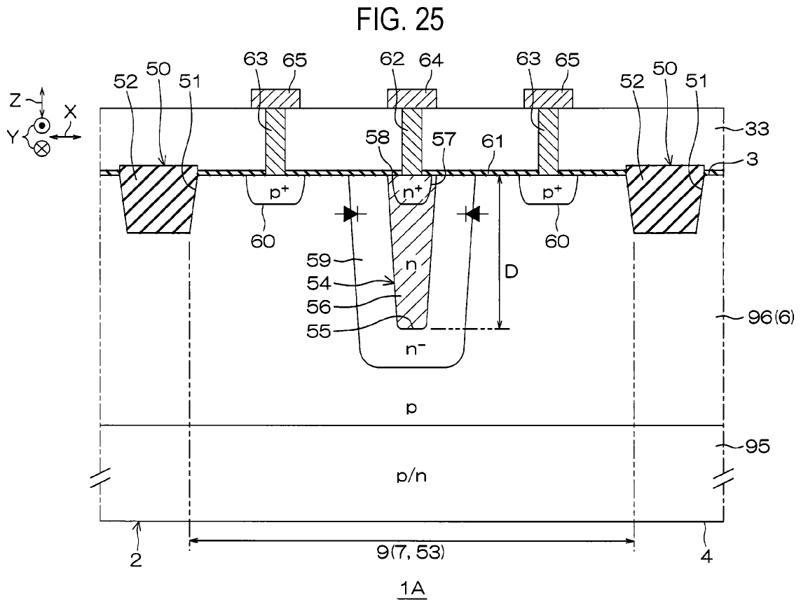

A modification examples applied to the semiconductor devices 1A to 1E are shown below. FIG. 25 is a cross-sectional view showing a modification example of the chip 2. In each of the above-described embodiments, the chip 2 including a single-layer structure consisting of the first semiconductor region 6 (semiconductor substrate) is shown. However, as shown in FIG. 25, the chip 2 may include a laminated structure including a semiconductor substrate 95 (Si substrate) and an epitaxial layer 96 (Si epitaxial layer).

The conductivity type of the semiconductor substrate 95 is arbitrary. The conductivity type of the semiconductor substrate 95 may be an n-type or a p-type. The conductivity type of the epitaxial layer 96 is arbitrary. The conductivity type of the epitaxial layer 96 may be an n-type or a p-type. The thickness of the epitaxial layer 96 is preferably less than the thickness of the semiconductor substrate 95.

For example, when the n-type epitaxial layer 96 is employed, the p-type first semiconductor region 6 may be formed by introducing a p-type impurity into the n-type epitaxial layer 96. For example, when the p-type epitaxial layer 96 is employed, the p-type first semiconductor region 6 may be formed by the p-type epitaxial layer 96.

In other words, the first semiconductor region 6 may be formed in the surface layer portion of the first main surface 3 at an interval from the second main surface 4 to the first main surface 3 side. Further, the first semiconductor region 6 may be formed in the form of a layer extending along the first main surface 3 in the surface layer portion of the first main surface 3, and may be exposed from the first main surface 3 and the first to fourth side surfaces 5A to 5D.

When the p-type semiconductor substrate 95 and the p-type epitaxial layer 96 are employed, the first semiconductor region 6 may be regarded as being formed by both the p-type semiconductor substrate 95 and the p-type epitaxial layer 96, or may be regarded as being formed by the p-type epitaxial layer 96 alone.

When the p-type semiconductor substrate 95 and the p-type epitaxial layer 96 are employed, the trench structure 54 may be formed within the epitaxial layer 96 at an interval from the semiconductor substrate 95. When the p-type semiconductor substrate 95 and the p-type epitaxial layer 96 are employed, the trench structure 54 may be formed across a boundary portion between the semiconductor substrate 95 and the epitaxial layer 96.

That is, the trench structure 54 may include a portion located within the semiconductor substrate 95 and a portion located within the epitaxial layer 96. In this case, the second semiconductor region 59 may include a portion located within the semiconductor substrate 95 and a portion located within the epitaxial layer 96.

In the chip 2 according to the modification example, the epitaxial layer 96 is provided as a device formation layer, and each of the structure of the CMIS region 8 and the structure of the light receiving region 9 is formed in the epitaxial layer 96. Such a configuration is obtained by performing the steps after FIG. 23B after preparing the wafer 80 including a laminated structure including the semiconductor substrate 95 and the epitaxial layer 96 in the above-described preparation step of the wafer 80 (see FIG. 23A).

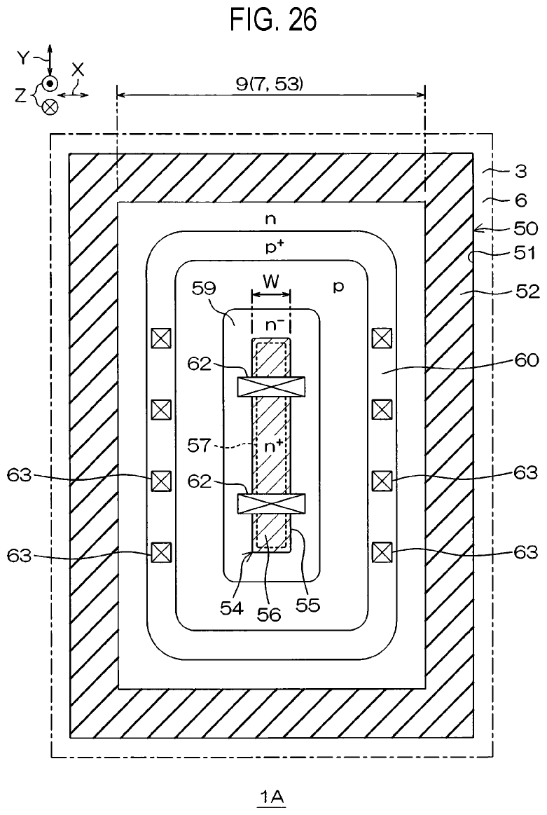

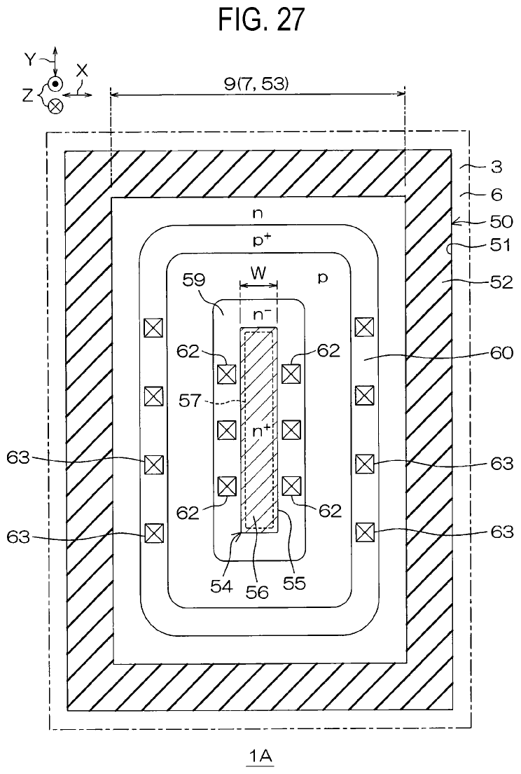

FIG. 26 is a plane view showing a first modification example of the cathode via electrode 62. FIG. 27 is a plane view showing a second modification example of the cathode via electrode 62. In each of the above-described embodiments, the cathode via electrode 62 is connected to the polysilicon 56 at an interval from the second semiconductor region 59.

However, referring to FIG. 26, the cathode via electrode 62 may be mechanically and electrically connected to both the polysilicon 56 and the second semiconductor region 59 cross the sidewall of the trench 55. Further, referring to FIG. 27, the cathode via electrode 62 may be mechanically and electrically connected to the second semiconductor region 59 at an interval from the polysilicon 56. That is, the cathode via electrode 62 that do not include a mechanical connection to the polysilicon 56 may be employed.

The above-described embodiment can be implemented in other forms. For example, in each of the above-described embodiments, the plurality of circuit device regions 7 are provided in the first main surface 3. However, the semiconductor devices 1A to 1E in which the first main surface 3 is provided with only a single light receiving region 9 or a plurality of light receiving regions 9 and no other circuit device regions 7 may be employed.

In the above-described embodiments, the example is shown in which the first region isolation structure 10 is the trench isolation structure. However, the first region isolation structure 10 may be a first field oxide film formed by selective oxidation of the first main surface 3. The first field oxide film may be called a “first LOCOS (Local Oxidation of Silicon) film.”

In the above-described embodiments, the example is shown in which the second region isolation structure 50 is the trench isolation structure. However, the second region isolation structure 50 may be a second field oxide film formed by selective oxidation of the first main surface 3. The second field oxide film may be called a “second LOCOS film.”

In the above-described embodiments, the example is shown in which the second region isolation structure 50 is the shallower trench isolation structure than the trench structure 54. However, the second region isolation structure 50 may be a deep trench isolation structure having a depth equal to or greater than the trench depth D of the trench structure 54. In this case, the second region isolation structure 50 may contain polysilicon buried in the second isolation trench 51 with an insulating film interposed therebetween.

In the above-described embodiments, the first direction X and the second direction Y are defined by the extending direction of the first to fourth side surfaces 5A to 5D. However, the first direction X and the second direction Y may be arbitrary directions as long as they maintain a relationship of intersecting (specifically, being perpendicular to) each other. For example, the first direction X may be the extending direction of the third side surface 5C (the fourth side surface 5D), and the second direction Y may be the extending direction of the first side surface 5A (the second side surface 5B). Further, the first direction X may be a direction intersecting the first to fourth side surfaces 5A to 5D, and the second direction Y may be a direction intersecting the first to fourth side surfaces 5A to 5D.

Examples of the features extracted from the present disclosure and the accompanying drawings are shown below. In the following, alphanumeric characters in parentheses represent corresponding components and the like in the above-described embodiments, but the scope of each clause is not limited to embodiments. A “semiconductor device” in the following clauses may be replaced with a “photodiode device,” a “semiconductor light receiving device,” an “integrated circuit device,” etc., as necessary.

[A1] A semiconductor device (1A to 1E) including: a chip (2) including a main surface (3); a first conductivity type (p-type) first semiconductor region (6) formed at least in a surface layer portion of the main surface (3); a trench structure (54) including a trench (55) formed in the main surface (3) to be located within the first semiconductor region (6), and a second conductivity type (n-type) polysilicon (56) mechanically and electrically connected to the chip (2) and located within the trench (55); and a second conductivity type (n-type) second semiconductor region (59) formed within the first semiconductor region (6) along a wall surface of the trench structure (54) and forming a pn junction, as a photodiode, with the first semiconductor region (6).

[A2] The semiconductor device (1A to 1E) of A1, wherein the second semiconductor region (59) contains a second conductivity type impurity of a same type as a second conductivity type impurity of the polysilicon (56).

[A3] The semiconductor device (1A to 1E) of A1 or A2, wherein the second semiconductor region (59) has an impurity concentration lower than an impurity concentration of the polysilicon (56).

[A4] The semiconductor device (1A to 1E) of any one of A1 to A3, wherein the second semiconductor region (59) has a concentration gradient that gradually decreases starting from the polysilicon (56).

[A5] The semiconductor device (1A to 1E) of any one of A1 to A4, wherein the trench structure (54) includes a second conductivity type (n-type) impurity region (57), which has a higher impurity concentration than the polysilicon (56), within the polysilicon (56).

[A6] The semiconductor device (1A to 1E) of A5, wherein the impurity region (57) is formed in a surface layer portion of the polysilicon (56) at an interval from a bottom wall of the trench (55).

[A7] The semiconductor device (1A to 1E) of A6, wherein the impurity region (57) is formed at an interval from a middle portion of a depth range of the trench (55) to an opening side of the trench (55).

[A8] The semiconductor device (1A to 1E) of any one of A5 to A7, wherein the impurity region (57) forms a concentration gradient that gradually decreases from an inner portion of the polysilicon (56) toward a peripheral portion of the polysilicon (56) within the trench (55).

[A9] The semiconductor device (1A to 1E) of any one of A5 to A8, wherein the impurity region (57) contains a second conductivity type impurity of a type different from a second conductivity type impurity of the polysilicon (56).

[A10] The semiconductor device (1A to 1E) of any one of A1 to A4, further including: an insulating film (33) covering the main surface (3); and a via electrode (62) electrically connected to the polysilicon (56) within the insulating film (33).

[A11] The semiconductor device (1A to 1E) of A10, wherein the via electrode (62) is mechanically and electrically connected to the polysilicon (56) at an interval from the second semiconductor region (59).

[A12] The semiconductor device (1A to 1E) of A10 or A11, wherein the via electrode (62) has no mechanical connection to the second semiconductor region (59).

[A13] The semiconductor device (1A to 1E) of any one of A10 to A12, wherein the trench structure (54) includes a second conductivity type (n-type) impurity region (57), which has a higher impurity concentration than the polysilicon (56), within the polysilicon (56).

[A14] The semiconductor device (1A to 1E) of A13, wherein the impurity region (57) is formed in a surface layer portion of the polysilicon (56), and the via electrode (62) forms ohmic contact with the impurity region (57).

[A15] The semiconductor device (1A to 1E) of any one of A10 to A14, further including: a wiring (64) electrically connected to the via electrode (62) on the insulating film (33).

[A16] The semiconductor device (1A to 1E) of any one of A1 to A15, further including: a second conductivity type (n-type) contact region (60) formed in a surface layer portion of the first semiconductor region (6) at an interval from the trench structure (54).

[A17] The semiconductor device (1A to 1E) of A16, wherein the contact region (60) extends in a strip shape along the trench structure (54) in plan view.

[A18] The semiconductor device (1A to 1E) of A16 or A17, wherein the contact region (60) is formed in an annular shape surrounding the trench structure (54) in plan view.

[A19] The semiconductor device (1A to 1E) of any one of A1 to A18, further including: a light receiving region (9, 9A to 9C) provided in the main surface (3); and a region isolation structure (50) that electrically isolates the light receiving region (9, 9A to 9C) from other regions, wherein the trench structure (54) is formed in the light receiving region (9, 9A to 9C), and the second semiconductor region (59) is formed along the wall surface of the trench structure (54) in the light receiving region (9, 9A to 9C).

[A20] The semiconductor device (1A to 1E) of any one of A1 to A18, further including: a plurality of light receiving regions (9, 9A to 9C) provided in the main surface (3), wherein the trench structure (54) is formed in each of the light receiving regions (9, 9A to 9C), and the second semiconductor region (59) is formed along the wall surface of the trench structure (54) in each of the light receiving regions (9, 9A to 9C).

[A21] The semiconductor device (1A to 1E) of any one of A1 to A18, further including: a transistor region (8, 8a, 8b) provided in the main surface (3); and a light receiving region (9, 9A to 9C) provided in the main surface (3), wherein the trench structure (54) is formed in the light receiving region (9, 9A to 9C), and the second semiconductor region (59) is formed along the wall surface of the trench structure (54) in the light receiving region (9, 9A to 9C).

[A22] The semiconductor device (1A to 1E) of A21, further including: a planar gate structure (25) arranged on the main surface (3) of the transistor region (8, 8a, 8b); a second conductivity type (n-type) drain region (29) formed in a region on one side of the planar gate structure (25) in the surface layer portion of the main surface (3) of the transistor region (8, 8a, 8b); and a second conductivity type (n type) source region (31) formed in a region on the other side of the planar gate structure (25) in the surface layer portion of the main surface (3) of the transistor region (8, 8a, 8b).

[A23] The semiconductor device (1A to 1E) of A22, wherein the polysilicon (56) has a second conductivity type impurity concentration lower than a second conductivity type impurity concentration of the drain region (29).

[A24] The semiconductor device (1A to 1E) of A22 or A23, wherein the second semiconductor region 59 has a second conductivity type impurity concentration lower than a second conductivity type impurity concentration of the drain region (29).

[A25] The semiconductor device (1A to 1E) of any one of A1 to A24, wherein the second semiconductor region (59) is formed along the wall surface of the trench structure (54) and does not include a portion drawn in a form of a layer in a horizontal direction along the main surface (3) in the surface layer portion of the main surface (3).

[B1] A method of manufacturing a semiconductor device (1A to 1E), including: preparing a wafer (80) including a main surface (81) and including a first conductivity type (p-type) first semiconductor region (6) at least in a surface layer portion of the main surface (81); forming a trench (55) in the main surface (81) to be located within the first semiconductor region (6); burying a second conductivity type (n-type) polysilicon (56, 88) in the trench (55) to be mechanically and electrically connected to the wafer (80); and forming a second conductivity type (n-type) second semiconductor region (59) forming a pn junction, as a photodiode, with the first semiconductor region (6) by diffusing a second conductivity type impurity into the first semiconductor region (6) using the polysilicon (56, 88) as a solid-phase diffusion source.

[B2] The method of manufacturing the semiconductor device (1A to 1E) of B1, wherein after the act of forming the second semiconductor region (59), the polysilicon (56, 88) remains as a polar electrode for the second semiconductor region (59).

[B3] The method of manufacturing the semiconductor device (1A to 1E) of B1 or B2, wherein the act of forming the second semiconductor region (59) includes forming the second semiconductor region (59) containing a second conductivity type impurity of the same type as a second conductivity type impurity of the polysilicon (56, 88).

[B4] The method of manufacturing the semiconductor device (1A to 1E) of any one of B1 to B3, wherein the act of forming the second semiconductor region (59) includes forming the second semiconductor region (59) having an impurity concentration lower than an impurity concentration of the polysilicon (56, 88).

[B5] The method of manufacturing the semiconductor device (1A to 1E) of any one of B1 to B4, wherein the act of forming the second semiconductor region (59) includes forming the second semiconductor region (59) having a concentration gradient that gradually decreases starting from the polysilicon (56, 88).

[B6] The method of manufacturing the semiconductor device (1A to 1E) of any one of B1 to B5, further including: after the act of forming the second semiconductor region (59), forming a second conductivity type (n-type) impurity region (57) within the polysilicon (56, 88) by introducing a second conductivity type impurity into the polysilicon (56, 88).

[B7] The method of manufacturing the semiconductor device (1A to 1E) of B6, wherein the act of forming the impurity region (57) includes forming the impurity region (57) in a surface layer portion of the polysilicon (56, 88) at an interval from a bottom wall of the trench (55).

[B8] The method of manufacturing the semiconductor device (1A to 1E) of B7, wherein the act of forming the impurity region (57) includes forming the impurity region (57) at a position at an interval from a middle portion of a depth range of the trench (55) to an opening side of the trench (55).

[B9] The method of manufacturing the semiconductor device (1A to 1E) of any one of B6 to B8, wherein the act of forming the impurity region (57) includes forming the impurity region (57) having a concentration gradient that gradually decreases from an inner portion of the polysilicon (56, 88) toward a peripheral portion of the polysilicon (56, 88).

[B10] The method of manufacturing the semiconductor device (1A to 1E) of any one of B6 to B9, wherein the act of forming the impurity region (57) includes introducing a second conductivity type impurity of a type different from a second conductivity type impurity of the polysilicon (56, 88) into the polysilicon (56, 88).

[B11] The method of manufacturing the semiconductor device (1A to 1E) of any one of B1 to B5, further including: forming an insulating film (33) covering the main surface (81); and burying a via electrode (62) in the insulating film (33) to be electrically connected to the polysilicon (56, 88).

[B12] The method of manufacturing the semiconductor device (1A to 1E) of B11, wherein the act of forming the via electrode (62) includes forming the via electrode (62) mechanically and electrically connected to the polysilicon (56, 88) at an interval from the second semiconductor region (59).

[B13] The method of manufacturing the semiconductor device (1A to 1E) of B11 or B12, wherein the act of forming the via electrode (62) includes forming the via electrode (62) having no mechanical connection to the second semiconductor region (59).

[B14] The method of manufacturing the semiconductor device (1A to 1E) of any one of B11 to B13, further including: after the act of forming the second semiconductor region (59) and before the act of forming the insulating film (33), forming a second conductivity type (n-type) impurity region (57) within the polysilicon (56, 88) by introducing a second conductivity type impurity into the polysilicon (56, 88).

[B15] The method of manufacturing the semiconductor device (1A to 1E) of B14, wherein the act of forming the impurity region (57) includes forming the impurity region (57) in the surface layer portion of the polysilicon (56, 88), and the act of forming the via electrode (62) includes forming the via electrode (62) forming ohmic contact with the impurity region (57).

[B16] The method of manufacturing the semiconductor device (1A to 1E) of any one of B11 to B15, further including: after the act of forming the via electrode (62), forming a wiring (64) on the insulating film (33) to be electrically connected to the via electrode (62).

[B17] The method of manufacturing the semiconductor device (1A to 1E) of any one of B1 to B16, further including: after the act of forming the trench (55), forming a first conductivity type (p-type) contact region (60) by introducing a first conductivity type impurity into a region at an interval from the trench (55) in the surface layer portion of the first semiconductor region (6).

[B18] The method of manufacturing the semiconductor device (1A to 1E) of B17, wherein the act of forming the contact region (60) includes forming the contact region (60) extending in a strip shape along the trench (55) in plan view.

[B19] The method of manufacturing the semiconductor device (1A to 1E) of B17 or B18, wherein the act of forming the contact region (60) includes forming the contact region (60) extending in an annular shape surrounding the trench (55) in plan view.

[B20] The method of manufacturing the semiconductor device (1A to 1E) of any one of B1 to B19, further including: setting a light receiving region (9, 9A to 9C) in the main surface (81); forming the trench (55) in the main surface (81) of the light receiving region (9, 9A to 9C); and forming a region isolation structure (50) electrically isolating the light receiving region (9, 9A to 9C) from other regions.

[B21] The method of manufacturing the semiconductor device (1A to 1E) of any one of B1 to B19, further including: setting a plurality of light receiving regions (9, 9A to 9C) in the main surface (81); and forming the trench (55) in each of the light receiving regions (9, 9A to 9C).

[B22] The method of manufacturing the semiconductor device (1A to 1E) of any one of B1 to B19, further including: before the act of forming the trench (55), setting a transistor region (8, 8a, 8b) and a light receiving region (9, 9A to 9C) in the main surface (81), wherein the act of forming the trench (55), the act of burying the polysilicon (56, 88), and the act of forming the second semiconductor region (59) are performed before performing a manufacturing process for the transistor region (8, 8a, 8b).

[B23] The method of manufacturing the semiconductor device (1A to 1E) of any one of B1 to B22, wherein the act of forming the second semiconductor region (59) includes forming the second semiconductor region (59) that does not include a portion drawn in a form of a layer in a horizontal direction along the main surface (81) in the surface layer portion of the main surface (81).

[B24] The method of manufacturing the semiconductor device (1A to 1E) of any one of B1 to B23, further including: before the act of forming the trench (55), forming a mask (84), which includes an opening (87) exposing the main surface (81), on the main surface (81), wherein the act of forming the trench (55) includes forming the trench (55) in a portion of the main surface (81) exposed from the opening (87) of the mask (84) by an etching method through the mask (84), and the act of burying the polysilicon (56, 88) includes forming a second conductivity type (n-type) polysilicon layer (88) filling the trench (55) to cover the mask (84). [B25] The method of manufacturing the semiconductor device (1A to 1E) of B24, further including: after the act of forming the second semiconductor region (59), removing a portion of the polysilicon layer (88) covering the mask (84), wherein the act of forming the second semiconductor region (59) is performed while the polysilicon layer (88) covers the mask (84).

[B26] The method of manufacturing the semiconductor device (1A to 1E) of B24, further including: before the act of forming the second semiconductor region (59), removing a portion of the polysilicon layer (88) covering the mask (84), wherein the act of forming the second semiconductor region (59) is performed while the polysilicon layer (88) exposes the mask (84).

Although the embodiments have been described in detail above, these embodiments are only specific examples that clarify the technical contents. Various technical ideas extracted from the present disclosure can be appropriately combined without being restricted by the order of description in the present disclosure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a chip including a main surface;
a first conductivity type first semiconductor region formed at least in a surface layer portion of the main surface;
a trench structure including a trench formed in the main surface to be located within the first semiconductor region, and a second conductivity type polysilicon mechanically and electrically connected to the chip and located within the trench; and
a second conductivity type second semiconductor region formed within the first semiconductor region along a wall surface of the trench structure and forming a pn junction, as a photodiode, with the first semiconductor region.

2. The semiconductor device of claim 1, wherein the second semiconductor region contains a second conductivity type impurity of a same type as a second conductivity type impurity of the polysilicon.

3. The semiconductor device of claim 1, wherein the second semiconductor region has an impurity concentration lower than an impurity concentration of the polysilicon.

4. The semiconductor device of claim 1, wherein the second semiconductor region has a concentration gradient that gradually decreases starting from the polysilicon.

5. The semiconductor device of claim 1, wherein the trench structure includes a second conductivity type impurity region, which has a higher impurity concentration than the polysilicon, within the polysilicon.

6. The semiconductor device of claim 5, wherein the impurity region is formed in a surface layer portion of the polysilicon at an interval from a bottom wall of the trench.

7. The semiconductor device of claim 6, wherein the impurity region is formed at an interval from a middle portion of a depth range of the trench to an opening side of the trench.

8. The semiconductor device of claim 5, wherein the impurity region forms a concentration gradient that gradually decreases from an inner portion of the polysilicon toward a peripheral portion of the polysilicon within the trench.

9. The semiconductor device of claim 5, wherein the impurity region contains a second conductivity type impurity of a type different from a second conductivity type impurity of the polysilicon.

10. The semiconductor device of claim 1, further comprising:
an insulating film covering the main surface; and
a via electrode electrically connected to the polysilicon within the insulating film.

11. The semiconductor device of claim 10, wherein the via electrode is mechanically and electrically connected to the polysilicon at an interval from the second semiconductor region.

12. The semiconductor device of claim 10, wherein the via electrode has no mechanical connection to the second semiconductor region.

13. The semiconductor device of claim 10, wherein the trench structure includes a second conductivity type impurity region, which has a higher impurity concentration than the polysilicon, within the polysilicon.

14. The semiconductor device of claim 13, wherein the impurity region is formed in a surface layer portion of the polysilicon, and
wherein the via electrode forms ohmic contact with the impurity region.

15. The semiconductor device of claim 10, further comprising: a wiring electrically connected to the via electrode on the insulating film.

16. The semiconductor device of claim 1, further comprising: a second conductivity type contact region formed in a surface layer portion of the first semiconductor region at an interval from the trench structure.

17. The semiconductor device of claim 1, further comprising:
a light receiving region provided in the main surface; and
a region isolation structure that electrically isolates the light receiving region from other regions,
wherein the trench structure is formed in the light receiving region, and
wherein the second semiconductor region is formed along the wall surface of the trench structure in the light receiving region.

18. The semiconductor device of claim 1, further comprising: a plurality of light receiving regions provided in the main surface,
wherein the trench structure is formed in each of the light receiving regions, and
wherein the second semiconductor region is formed along the wall surface of the trench structure in each of the light receiving regions.

19. A method of manufacturing a semiconductor device, comprising:
preparing a wafer including a main surface and including a first conductivity type first semiconductor region at least in a surface layer portion of the main surface;
forming a trench in the main surface to be located within the first semiconductor region;
burying a second conductivity type polysilicon in the trench to be mechanically and electrically connected to the wafer; and
forming a second conductivity type second semiconductor region forming a pn junction, as a photodiode, with the first semiconductor region by diffusing a second conductivity type impurity into the first semiconductor region using the polysilicon as a solid-phase diffusion source.

20. The method of claim 19, wherein the polysilicon remains as a polar electrode for the second semiconductor region after the act of forming the second semiconductor region.
